(19) United States
(12) Patent Application Publication
(10) Pub. No.: US 2026/0104639 A1
(43) Pub. Date: Apr. 16, 2026

(54) RADIATION-SENSITIVE COMPOSITION AND PATTERN FORMING METHOD

(71) Applicant: JSR CORPORATION, Tokyo (JP)

(72) Inventors: Kazuya KIRIYAMA, Tokyo (JP); Takuya OMIYA, Tokyo (JP)

(73) Assignee: JSR CORPORATION, Tokyo (JP)

(21) Appl. No.: 19/422,570

(22) Filed: Dec. 17, 2025

Related U.S. Application Data
(63) Continuation-in-part of application No. PCT/JP2024/018785, filed on May 22, 2024.

(30) Foreign Application Priority Data
Jun. 28, 2023 (JP) 2023-106132

(51) Int. Cl. G03F 7/004; G03F 7/00; G03F 7/039

(52) U.S. Cl. CPC G03F 7/0045; G03F 7/039; G03F 7/70033

(57) ABSTRACT

A radiation-sensitive composition includes: a polymer including a structural unit which includes an acid-dissociable group; a radiation-sensitive acid generator including a first organic acid anion and a first onium cation; an acid diffusion controlling agent which includes a second organic acid anion and a second onium cation and capable of generating an acid having a pKa higher than a pKa of an acid to be generated from the radiation-sensitive acid generator by irradiation with radiation; and a solvent. The first organic acid anion includes an acid anion moiety and an aromatic ring including a first substituent and a second substituent. The first substituent and the second substituent are each independently a hydroxy group, a sulfo group, or a sulfanyl group. At least one selected from the group consisting of the polymer, the radiation-sensitive acid generator, and the acid diffusion controlling agent includes an iodo group.

### CROSS-REFERENCE TO RELATED APPLICATIONS

The present application is a continuation-in-part application of International Patent Application No. PCT/JP2024/018785 filed May 22, 2024, which claims priority to Japanese Patent Application No. 2023-106132 filed Jun. 28, 2023. The contents of these applications are incorporated herein by reference in their entirety.

### BACKGROUND OF THE DISCLOSURE

### Technical Field

The present disclosure relates to a radiation-sensitive composition and a pattern forming method.

### Background Art

A photolithography technique performed using a resist composition has been utilized for formation of a fine circuit on a semiconductor device. As the representative procedure, for example, a resist pattern is formed on a substrate by generating an acid by irradiating the coating of the resist composition with radioactive ray through a mask pattern, and then generate a difference in solubility of polymer into an alkaline or organic developer between an exposed part and a non-exposed part through a reaction in the presence of the acid as a catalyst.

In the photolithography technique, pattern miniaturization is promoted by using short-wavelength radiation such as ArF excimer laser, or by combining such radiation with an immersion exposure method (liquid immersion lithography). As a next generation technique, the use of further shorter-wavelength radiation such as an electron beam, X-ray, and extreme ultraviolet (EUV) is being sought, and improvements in the performance of resist materials subjected to such radiation exposure are currently being investigated (JP-A-2020-075910).

### SUMMARY

According to an aspect of the present disclosure, a radiation-sensitive composition includes: a polymer including a structural unit which includes an acid-dissociable group; a radiation-sensitive acid generator including a first organic acid anion and a first onium cation; an acid diffusion controlling agent which includes a second organic acid anion and a second onium cation and capable of generating an acid having a pKa higher than a pKa of an acid to be generated from the radiation-sensitive acid generator by irradiation with radiation; and a solvent. The first organic acid anion includes an acid anion moiety and an aromatic ring including a first substituent and a second substituent. The first substituent and the second substituent are each independently a hydroxy group, a sulfo group, or a sulfanyl group. At least one selected from the group consisting of the polymer, the radiation-sensitive acid generator, and the acid diffusion controlling agent includes an iodo group.

According to another aspect of the present disclosure, A pattern formation method includes: applying the above-described radiation-sensitive composition directly or indirectly to a substrate to form a resist film; exposing the resist film to light; and developing the exposed resist film with a developer.

### DETAILED DESCRIPTION OF THE PREFERRED EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed.

Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In the above-described next-generation technology as well are required various resist performances equivalent to or higher than conventional performances in terms of, for example, sensitivity, critical dimension uniformity (CDU) performance, which is an index of uniformity of line width and hole diameter, and line width roughness (LWR) performance, which indicates variation in line width or a line width of a resist pattern.

The radiation-sensitive composition can exhibit superior sensitivity, CDU performance, and LWR performance in resist pattern formation. The reason for this is not clear, but can be presumed as follows. At least one selected from the group consisting of a polymer, a radiation-sensitive acid generator, and an acid diffusion controlling agent contains an iodo group. Owing to the fact that absorption of radiation such as EUV having a wavelength of 13.5 nm by iodo groups (iodine atoms) is large, the efficiency of photoelectron generation is increased, and the sensitivity of a resulting resist film is enhanced. Meanwhile, due to the employment of an iodo group, the radiation-sensitive composition is enhanced in hydrophobicity, and the solubility thereof in a developer may be lowered. In the radiation-sensitive composition, the first organic acid anion contains an acid anion moiety and an aromatic ring having at least both a first substituent and a second substituent, and the first substituent and the second substituent are each independently a hydroxy group, a sulfo group, or a sulfanyl group. By introducing the first substituent and the second substituent both having high polarity into the aromatic ring contained in the first organic acid anion, the radiation-sensitive composition is entirely made hydrophilic, and as a result, is improved in solubility in a developer, and can exhibit good CDU performance and LWR performance. In addition, the first substituent and the second substituent of the radiation-sensitive acid generator both high in polarity interact with polar portions in the polymer component (by hydrogen bonding, for example) to increase the glass transition temperature of both of them as a whole. As a result, the acid generated from the radiation-sensitive acid generator is moderately shortened in diffusion length, and the CDU performance and the LWR performance can be improved. It is presumed that the resist performances described above can be exhibited due to these combined actions.

By the pattern formation method of the present disclosure, a high-quality resist pattern can be efficiently formed because of the use of the radiation-sensitive composition capable of exhibiting superior sensitivity, CDU performance, and LWR performance in resist pattern formation, when a resist pattern is formed utilizing a next-generation technology.

Hereinafter, embodiments of the present invention will be described in detail, but the present invention is not limited to these embodiments. Combinations of preferred embodiments are also preferable.

### <<Radiation-Sensitive Composition>>

The radiation-sensitive composition (hereinafter also simply referred to as “composition”) according to the present embodiment contains a polymer (hereinafter also referred to as “base polymer”), a radiation-sensitive acid generator, and an acid diffusion controlling agent. The composition further contains a solvent. The composition may contain other optional components as long as the effects of the present disclosure are not impaired.

At least one selected from the group consisting of the polymer, the radiation-sensitive acid generator, and the acid diffusion controlling agent contains an iodo group. Owing to this, the sensitivity of a resulting resist film can be improved. The aspect of containing the iodo group is not particularly limited, but the iodo group is preferably contained in the form of an iodo group-containing aromatic ring structure. The iodo group-containing aromatic ring structure is a structure in which some or all of the hydrogen atoms of the aromatic ring are replaced by an iodo group. In particular, it is preferable that at least one selected from the group consisting of the acid-dissociable group, the first organic acid anion, and the second organic acid anion contains an iodo group-containing aromatic ring structure.

When the iodo group is contained in the base polymer, the radiation-sensitive acid generator, and the acid diffusion controlling agent, the radiation absorption efficiency is increased, and the secondary electron-generating efficiency is increased, so that the sensitivity can be improved.

The aromatic ring in the iodo group-containing aromatic ring structure is not particularly limited as long as the ring forms a ring structure having aromaticity. Examples of the aromatic ring include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, a triazine group, a carbazole ring, and a dibenzofuran ring, or combinations thereof. Among them, a benzene ring is preferable as the aromatic ring.

The number of the iodo groups in the iodo group-containing aromatic ring structure is not particularly limited, but is preferably 1 to 4, and more preferably 1, 2, or 3.

### <Polymer>

The polymer (namely, the base polymer) is an aggregate of polymerized chains containing a structural unit having an acid-dissociable group (hereinafter also referred to as “structural unit (I)”). The base polymer may contain a structural unit (II) having a phenolic hydroxy group, a structural unit (III) containing a lactone structure or the like, etc. in addition to the structural unit (I). The composition may contain one base polymer, or two or more base polymers. Each of the structural units will be described below.

### (Structural Unit (I))

The structural unit (I) is a structural unit having an acid-dissociable group. The structural unit (I) is not particularly limited as long as the structural unit (I) has an acid-dissociable group, and examples thereof include a structural unit having a tertiary alkyl ester moiety, a structural unit having a structure in which a hydrogen atom of a phenolic hydroxy group is replaced by a tertiary alkyl group, and a structural unit having an acetal linkage. In the base polymer, the acid-dissociable group preferably contains the above-described iodo group-containing aromatic ring structure. A structural unit represented by the following formula (3) (hereinafter also referred to as “structural unit (I-1)”) is preferable from the viewpoint of improvement in the patternability of the radiation-sensitive composition.

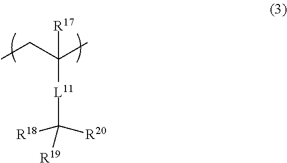

In the formula (3), R¹⁷ is a hydrogen atom, a fluorine atom, a methyl group, or a trifluoromethyl group. R¹⁸ is a substituted or unsubstituted monovalent hydrocarbon group having 1 to 20 carbon atoms. R¹⁹ and R²⁰ are each independently a substituted or unsubstituted monovalent chain hydrocarbon group having 1 to 10 carbon atoms or a substituted or unsubstituted monovalent alicyclic hydrocarbon group having 3 to 20 carbon atoms, or represent a divalent alicyclic group having 3 to 20 carbon atoms composed of R¹⁹ and R²⁰ combined with each other together with a carbon atom to which R¹⁹ and R²⁰ are bonded. L¹¹ represents *—COO— or *-L^{11a}COO—. L^{11a} is a substituted or unsubstituted arenediyl group. * is a bond to a carbon atom to which R¹⁷ is bonded.

As R¹⁷, a hydrogen atom and a methyl group are preferable from the viewpoint of the copolymerizability of a monomer that affords the structural unit (I-1), and a methyl group is more preferable.

Examples of the arenediyl group represented by L^{11a} include divalent aromatic hydrocarbon groups having 6 to 20 carbon atoms such as a benzenediyl group and a naphthalenediyl group. As L^{11a}, a benzenediyl group is preferable.

Examples of the substituent which the arenediyl group represented by L^{11a} can have include halogen atoms (a fluorine atom, a chlorine atom, a bromine atom, an iodine atom, etc.), a carboxy group, a cyano group, a nitro group, an alkyl group, a fluorinated alkyl group, an alkoxycarbonyloxy group, an acyl group, an acyloxy group, and an alkoxy group.

Examples of the alkyl group as a substituent of L^{11a} include linear or branched alkyl groups having 1 to 8 carbon atoms such as a methyl group, an ethyl group, and a propyl group. Examples of the fluorinated alkyl group include linear or branched fluorinated alkyl groups having 1 to 8 carbon atoms such as a trifluoromethyl group and a pentafluoroethyl group. Examples of the alkoxycarbonyloxy group include chain or alicyclic alkoxycarbonyloxy groups having 2 to 16 carbon atoms such as a methoxycarbonyloxy group, a butoxycarbonyloxy group, and an adamantylmethyloxycarbonyloxy group. Examples of the acyl group include aliphatic or aromatic acyl groups having 2 to 12 carbon atoms such as an acetyl group, a propionyl group, a benzoyl group, and an acryloyl group. Examples of the acyloxy group include aliphatic or aromatic acyloxy groups having 2 to 12 carbon atoms such as an acetyloxy group, a propionyloxy group, a benzoyloxy group, and an acryloyloxy group. Examples of the alkoxy group include linear or branched alkoxy groups having 1 to 8 carbon atoms such as a methoxy group, an ethoxy group, and a propoxy group.

Examples of the monovalent hydrocarbon group having 1 to 20 carbon atoms represented by R¹⁸ include a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the monovalent chain hydrocarbon group having 1 to 20 carbon atoms include alkyl groups such as a methyl group, an ethyl group, a n-propyl group, an i-propyl group, a n-butyl group, a sec-butyl group, an iso-butyl group, and a tert-butyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms include monocyclic alicyclic saturated hydrocarbon groups such as a cyclopentyl group, a cyclohexyl group, a cycloheptyl group, and a cyclooctyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; and polycyclic alicyclic unsaturated hydrocarbon groups such as a norbornenyl group, a tricyclodecenyl group, and a tetracyclododecenyl group.

Examples of the monovalent aromatic hydrocarbon group having 6 to 20 carbon atoms include aryl groups such as a phenyl group, a tolyl group, a xylyl group, a naphthyl group, and an anthryl group; and aralkyl groups such as a benzyl group, a phenethyl group, a naphthylmethyl group, and an anthrylmethyl group.

R¹⁸ is preferably a linear or branched saturated hydrocarbon group having 1 to 10 carbon atoms or an alicyclic hydrocarbon group having 3 to 20 carbon atoms.

Examples of the monovalent chain hydrocarbon group having 1 to 10 carbon atoms represented by R¹⁹ and R²⁰ include groups corresponding to 1 to 10 carbon atoms among the monovalent chain hydrocarbon groups having 1 to 20 carbon atoms as R¹⁸.

Examples of the monovalent alicyclic hydrocarbon group having 3 to 20 carbon atoms represented by R¹⁹ and R²⁰ include the monovalent alicyclic hydrocarbon groups having 3 to 20 carbon atoms as R¹⁸.

The divalent alicyclic group having 3 to 20 carbon atoms composed of R¹⁹ and R²⁰ combined with each other together with the carbon atom to which R¹⁹ and R²⁰ are bonded is not particularly limited as long as the divalent alicyclic group is a group obtained by removing two hydrogen atoms from an identical carbon atom constituting a carbon ring of a monocyclic or polycyclic alicyclic hydrocarbon having the aforementioned number of carbon atoms. The divalent alicyclic group may be either a monocyclic hydrocarbon group or a polycyclic hydrocarbon group, and the polycyclic hydrocarbon group may be either a bridged alicyclic hydrocarbon group or a fused alicyclic hydrocarbon group, and may be either a saturated hydrocarbon group or an unsaturated hydrocarbon group.

Among the monocyclic alicyclic hydrocarbon groups, a cyclopentanediyl group, a cyclohexanediyl group, a cycloheptanediyl group, a cyclooctanediyl group, and the like are preferable as saturated hydrocarbon groups, and a cyclopentenediyl group, a cyclohexenediyl group, a cycloheptenediyl group, a cyclooctenediyl group, a cyclodecenediyl group, and the like are preferable as unsaturated hydrocarbon groups. As the polycyclic alicyclic hydrocarbon group, bridged alicyclic saturated hydrocarbon groups are preferable, and for example, a bicyclo[2.2.1]heptane-2,2-diyl group (norbornane-2,2-diyl group), a bicyclo[2.2.2]octane-2,2-diyl group, and a tricyclo[3.3.1.1^{3,7}]decane-2,2-diyl group (adamantane-2,2-diyl group) are preferable.

Among them, it is preferable that R¹⁸ is an alkyl group having 1 to 4 carbon atoms, an alkenyl group, or a phenyl group, and the alicyclic structure constituted by R¹⁹ and R²¹ combined with each other and the carbon atom to which the R¹⁹ and R²⁰ are bonded is a polycyclic or monocyclic cycloalkane structure.

As the substituent which R¹⁸ to R²⁰ can have, a substituent which the arenediyl group represented by L^{11a} can have can be suitably employed.

Examples of the structural unit (I-1) include structural units represented by the following formulas (3-1) to (3-12) (hereinafter also referred to as “structural units (I-1-1) to (I-1-12)”).

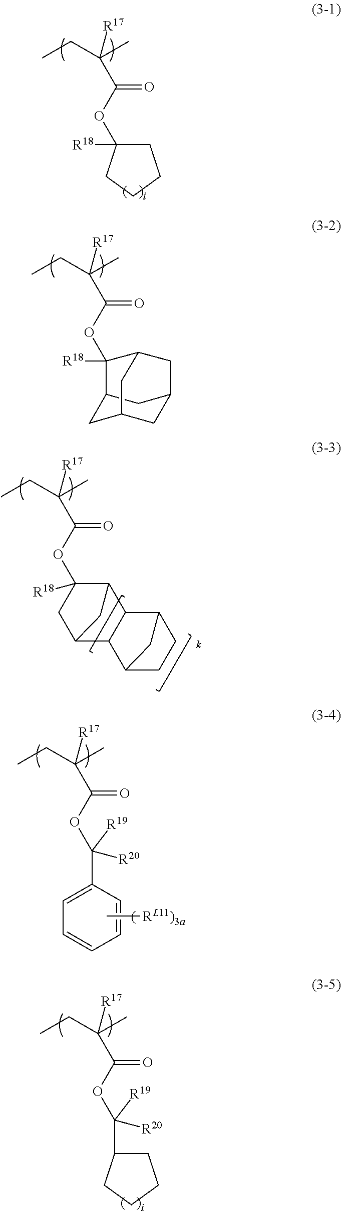

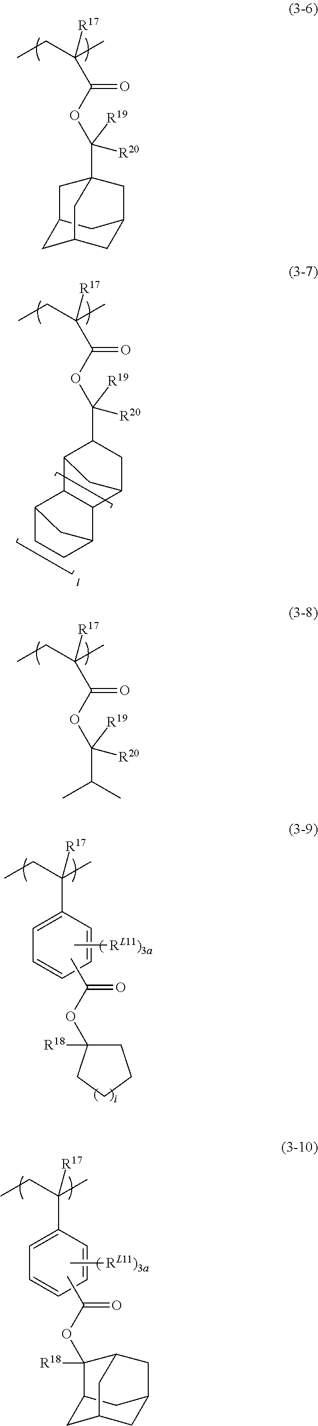

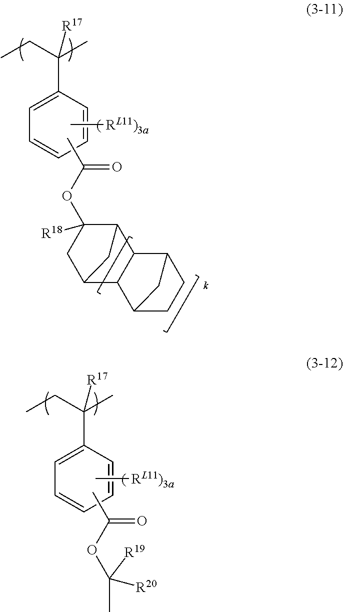

In the above formulas (3-1) to (3-12), R¹⁷ to R²⁰ have the same meaning as in the above formula (3). R^{L11} is a halogen atom, a carboxy group, a cyano group, a nitro group, an alkyl group, a fluorinated alkyl group, an alkoxycarbonyloxy group, an acyl group, an acyloxy group, or an alkoxy group. i and j are each independently an integer of 1 to 4. k and 1 are each 0 or 1. 3a is independently at each occurrence an integer of 0 to 3. When 3a is 2 or more, the plurality of R^{L11}s are the same or different from each other.

As i and j, 1 is preferable. As R¹⁸, a methyl group, an ethyl group, an isopropyl group, an ethenyl group, a phenyl group, and an iodophenyl group are preferable. As R¹⁹ and R²⁰, a methyl group, an ethyl group, and an isopropyl group are preferable. As R^{L11}, an iodine atom and an alkoxy group are preferable. By employing an iodine atom as R^{L11}, the iodo group-containing aromatic ring structure can be suitably introduced into the structural unit (I).

Furthermore, the polymer may contain structural units represented by the following formulas (1f) to (2f) as the structural unit (I).

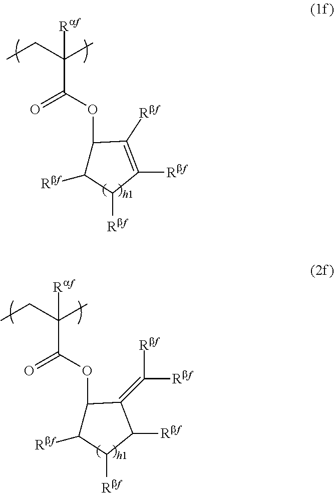

In the formulas (1f) to (2f), R^{αf}s are each independently a hydrogen atom, a fluorine atom, a methyl group, or a trifluoromethyl group. R^{βf}s are each independently a hydrogen atom or a chain alkyl group having 1 to 5 carbon atoms. h₁ is an integer of 1 to 4.

As the R, a hydrogen atom, a methyl group, or an ethyl group is preferable. h₁ is preferably 1 or 2.

When the base polymer contains the structural unit (I), the lower limit of the content of the structural unit (I) (the total content when a plurality of structural units (I) exist) is preferably 20 mol %, more preferably 25 mol %, still more preferably 30 mol % based on all structural units composing the base polymer. The upper limit of the content is preferably 80 mol %, more preferably 70 mol %, still more preferably 65 mol %. When the content of the structural unit (I) is adjusted to within the above range, the patternability of the radiation-sensitive composition can be further improved.

### (Structural Unit (II))

A structural unit (II) is a structural unit having a phenolic hydroxyl group. When the polymer contains the structural unit (II), the solubility into a developer can be more appropriately adjusted, and as a result, the sensitivity and the like of the radiation-sensitive composition can be further improved. When KrF excimer laser light, EUV, an electron beam, or the like is used as radiation to be applied in an exposure step in a resist pattern forming method, the structural unit (II) contributes to improvement in etching resistance and improvement in difference in solubility into a developer (dissolution contrast) between an exposed area and an unexposed area. In particular, the polymer containing the structural unit (II) can be suitably applied for pattern formation using exposure with radiation having a wavelength of 50 nm or less, such as an electron beam or EUV. The structural unit (II) is preferably represented by the following formula (2).

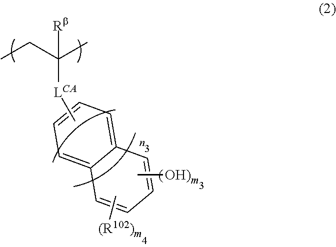

(In the formula (2),
R^{β} is a hydrogen atom, a fluorine atom, a methyl group, or a trifluoromethyl group.
L^{CA} is a single bond, —COO—*, or —O—*. * is a bond on the aromatic ring side.
R¹⁰² is a halogen atom, a cyano group, a nitro group, an alkyl group, a fluorinated alkyl group, an alkoxycarbonyloxy group, an acyl group, or an acyloxy group. When there are a plurality of R¹⁰²s, the plurality of R¹⁰²s are the same as or different from each other.
n₃ is an integer of 0 to 2, m₃ is an integer of 1 to 8, and m₄ is an integer of 0 to 8, provided that 1≤m₃+m₄≤2n₃+5 is satisfied.)

R^{β} is preferably a hydrogen atom or a methyl group from the viewpoint of the copolymerizability of a monomer that affords the structural unit (II).

L^{CA} is preferably a single bond or —COO—*.

As the halogen atom, the alkyl group, the fluorinated alkyl group, the alkoxycarbonyloxy group, the acyl group, or the acyloxy group as R¹⁰², the groups listed as the substituent of L^{11a} of the above formula (3) can be suitably employed. As the halogen atom as R¹⁰², an iodine atom is preferable.

The n₃ is more preferably 0 or 1, still more preferably 0.

m₃ is preferably an integer of 1 to 3, more preferably 1 or 2.

m₄ is preferably an integer of 0 to 3, more preferably an integer of 0 to 2.

As the structural unit (II), structural units represented by the following formulas (2-1) to (2-20) (hereinafter also referred to as “structural units (2-1) to (2-20)”) and the like are preferable.

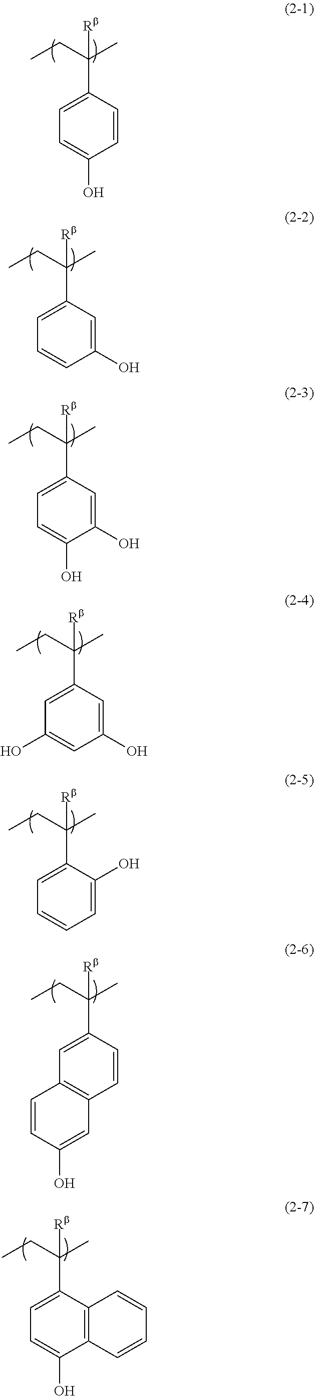

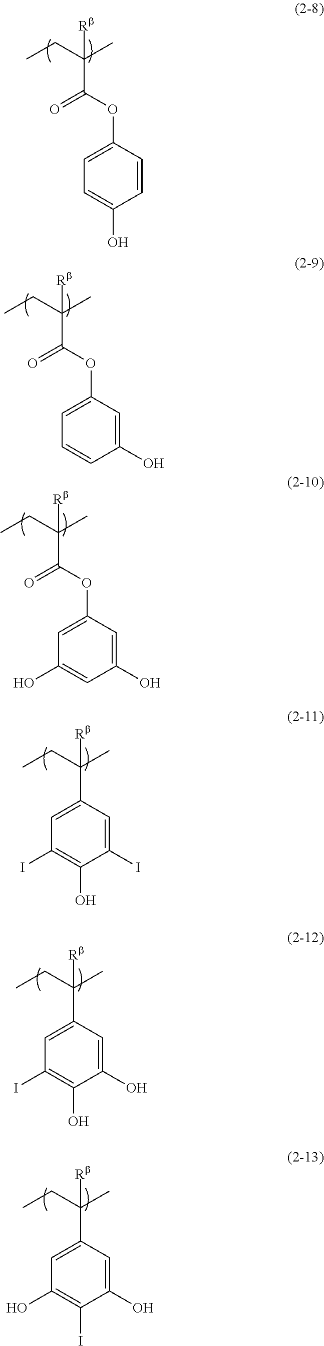

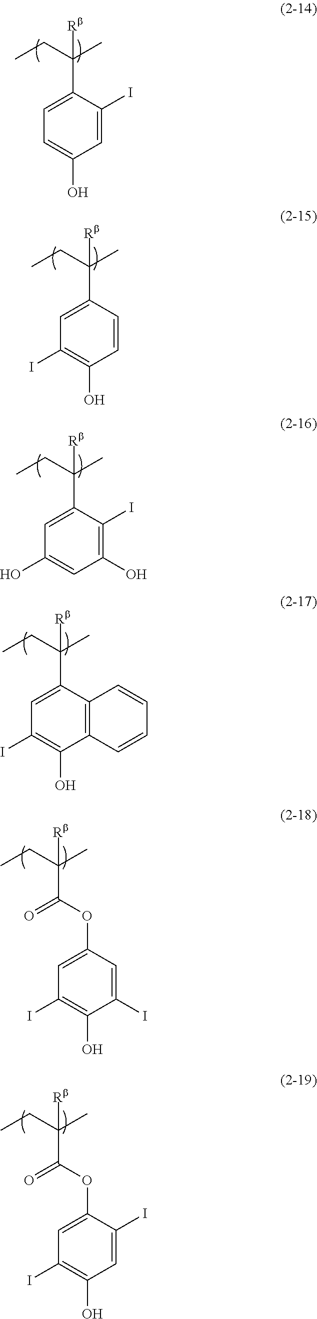

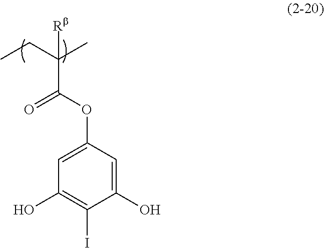

In the formulas (2-1) to (2-20), R is the same as in the formula (2).

The lower limit of the content ratio of the structural unit (II) (the total content ratio is used when a plurality of structural units (II) are present) is preferably 15 mol %, more preferably 25 mol %, and still more preferably 35 mol % based on all structural units constituting the base polymer. The upper limit of the content ratio is preferably 85 mol %, more preferably 75 mol %, and still more preferably 70 mol %. When the content ratio of the structural unit (II) is adjusted within the above range, the radiation-sensitive composition can further improve the sensitivity, CDU performance, and LWR performance.

In the case of polymerizing a monomer having a phenolic hydroxy group such as hydroxystyrene, it is preferable to polymerize the monomer with the phenolic hydroxy group protected by a protective group such as an alkali-dissociable group (for example, an acyl group), and then perform deprotection by hydrolysis to obtain a structural unit (II). The polymerization may be conducted without protecting a phenolic hydroxy group of hydroxystyrene or the like.

### (Structural Unit (III))

The structural unit (III) is a structural unit containing at least one structure selected from the group consisting of a lactone structure, a cyclic carbonate structure, and a sultone structure. When the base polymer further has the structural unit (III), the solubility of the base polymer in a developer can be adjusted, and as a result, the lithographic performance, such as resolution, of the radiation-sensitive composition can be improved. The adhesion between a resist pattern formed from the base polymer and a substrate can also be improved.

Examples of the structural unit (III) include structural units represented by the following formulas (T-1) to (T-11).

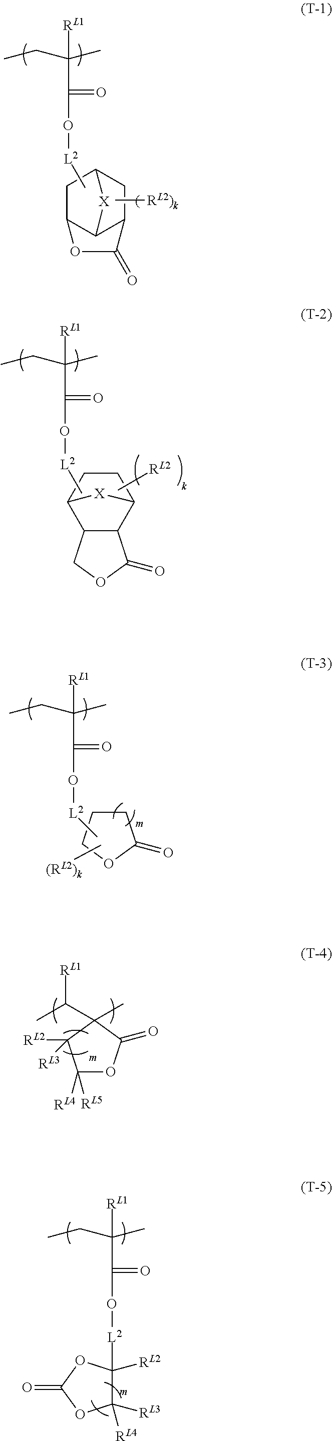

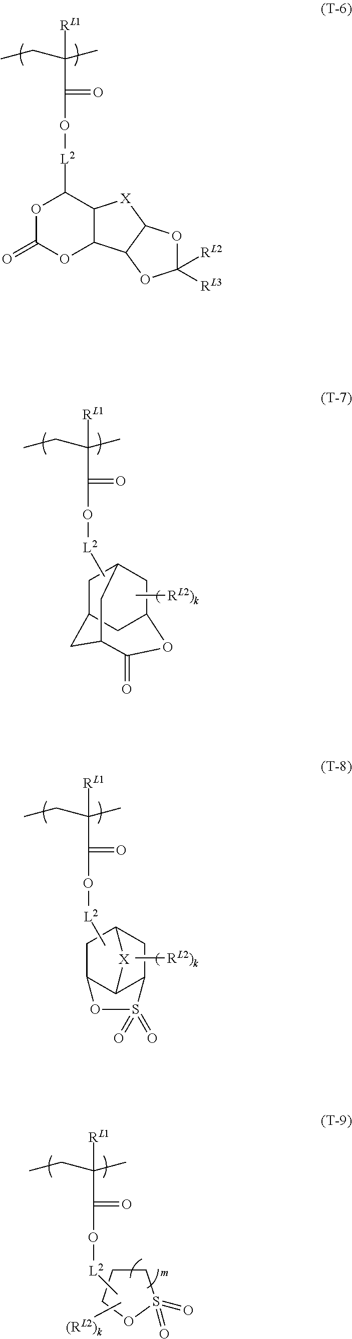

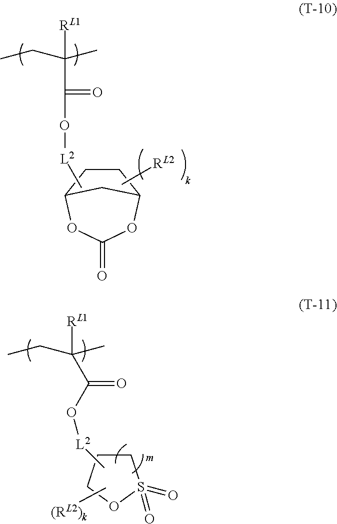

In the formulas, R^{L1} is a hydrogen atom, a fluorine atom, a methyl group, or a trifluoromethyl group. R^{L2} to R^{L5} are each independently a hydrogen atom, an alkyl group having 1 to 4 carbon atoms, a cyano group, a trifluoromethyl group, a methoxy group, a methoxycarbonyl group, a hydroxy group, a hydroxymethyl group, or a dimethylamino group. R^{L4} and R^{L5} may be combined with each other and constitute a divalent alicyclic group having 3 to 8 carbon atoms together with the carbon atom to which R^{L4} and R^{L5} are bonded. L² is a single bond or a divalent linking group. X is an oxygen atom or a methylene group. k is an integer of 0 to 3. m is an integer of 1 to 3.

As the divalent alicyclic group having 3 to 8 carbon atoms composed of R^{L4} and R^{L5} combined with each other together with a carbon atom to which R^{L4} and R^{L5} are bonded, a group corresponding to the structure having 3 to 8 carbon atoms can be suitably employed among the divalent alicyclic groups having 3 to 20 carbon atoms composed of R¹⁹ and R²⁰ combined with each other together with a carbon atom to which R¹⁹ and R²⁰ are bonded in the above formula (3). One or more hydrogen atoms on the alicyclic group may be replaced by a hydroxy group.

Examples of the divalent linking group represented by L² include a divalent linear or branched hydrocarbon group having 1 to 10 carbon atoms, a divalent alicyclic hydrocarbon group having 4 to 12 carbon atoms, and a group composed of one or more among these hydrocarbon groups and a group comprising at least one selected from the group consisting of —CO—, —O—, —NH—, and —S—.

Among them, a structural unit containing a lactone structure is preferable as the structural unit (III), a structural unit containing a norbornane lactone structure is more preferable, and a structural unit derived from norbornane lactone-yl (meth)acrylate is still more preferable.

The lower limit of the content ratio of the structural unit (III) is preferably 2 mol %, more preferably 5 mol %, and still more preferably 8 mol % based on all structural units constituting the base polymer. The upper limit of the content ratio is preferably 40 mol %, more preferably 35 mol %, and still more preferably 30 mol %. When the content ratio of the structural unit (III) is adjusted within the above range, the lithographic performance, such as resolution, of the radiation-sensitive composition and the adhesion between a resist pattern to be formed and a substrate can be further improved.

### (Structural Unit (IV))

The base polymer optionally has other structural units. Examples of the other structural units include a structural unit (IV) containing a polar group (excluding those corresponding to the structural unit (III)). When the base polymer further has the structural unit (IV), the solubility of the base polymer in a developer can be adjusted, and as a result, the lithographic performance, such as resolution, of the radiation-sensitive composition can be improved. Examples of the polar group include a hydroxy group, a carboxy group, a cyano group, a nitro group, and a sulfonamide group. Among them, a hydroxy group and a carboxy group are preferable, and a hydroxy group is more preferable.

Examples of the structural unit (IV) include structural units represented by the following formulas.

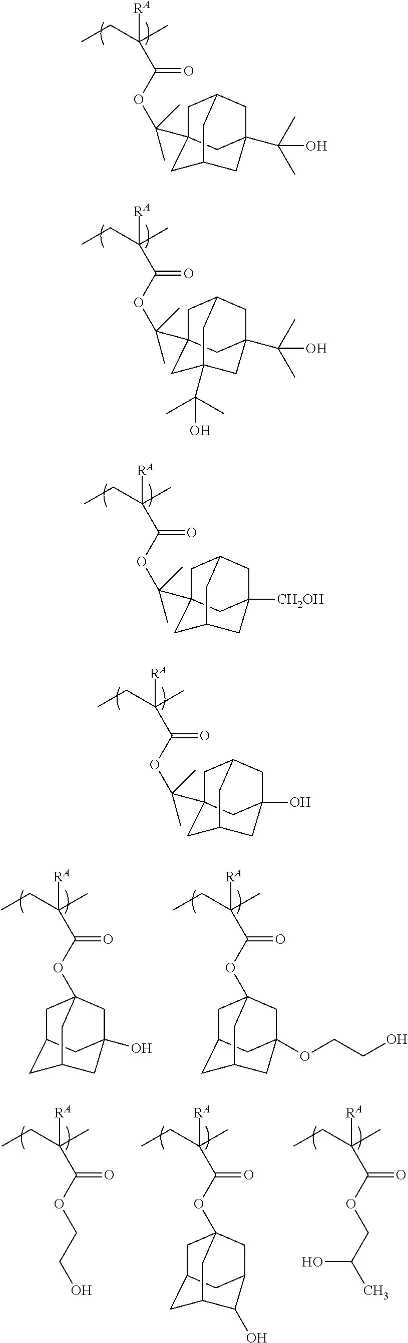

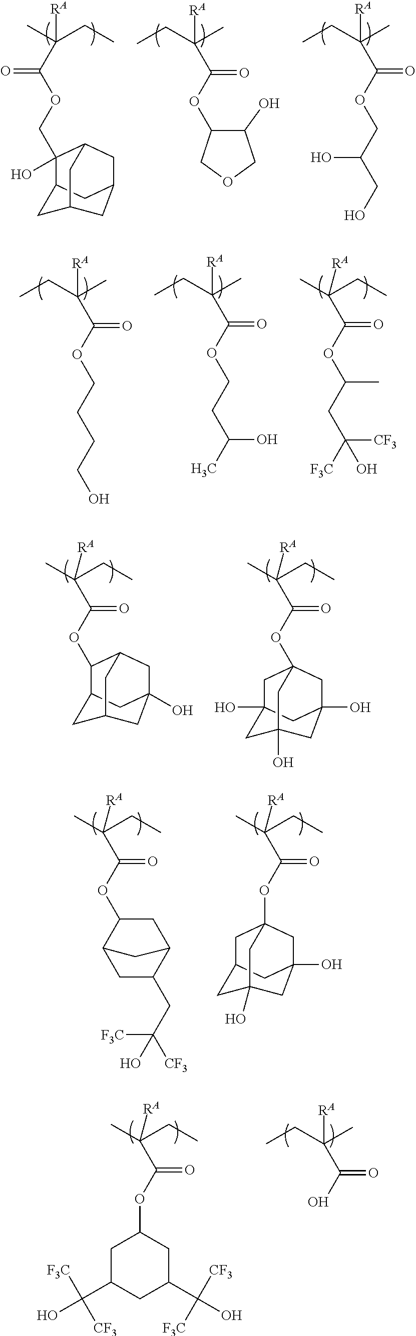

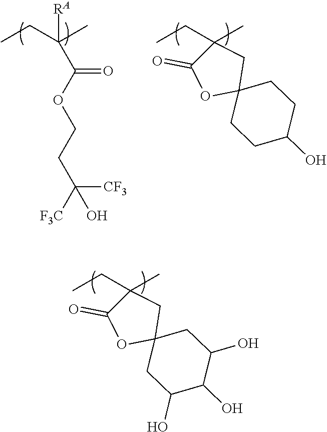

In the formulas, R^{A} is a hydrogen atom, a fluorine atom, a methyl group, or a trifluoromethyl group.

When the base polymer has the structural unit (IV) having a polar group, the lower limit of the content ratio of the structural unit (IV) is preferably 2 mol %, more preferably 5 mol %, and still more preferably 8 mol % based on all structural units constituting the base polymer. The upper limit of the content ratio is preferably 30 mol %, more preferably 20 mol %, and still more preferably 15 mol %. When the content ratio of the structural unit (IV) is adjusted within the above range, the lithographic performance, such as resolution, of the radiation-sensitive composition can further be improved.

### (Structural Unit (VII))

The base polymer may contain a structural unit (VII) having a third organic acid anion and a third onium cation and having a first acid generating structure that generates an acid that dissociates the acid-dissociable group through exposure to light. An onium salt structure formed of the third organic acid anion and the third onium cation (that is, the first acid generating structure) functions as a so-called radiation-sensitive acid generation structure.

When the base polymer contains the radiation-sensitive acid generating structure, the polarity of the base polymer of the exposed portion increases, and therefore when the developer is an aqueous alkaline solution, the base polymer is soluble, and on the other hand, when the developer is an organic solvent, the base polymer is hardly soluble in the developer.

The form of the third organic acid anion and the third onium cation contained in the structural unit (VII) of the base polymer is not particularly limited, and the base polymer may have the third organic acid anion as a side chain portion or may have the third onium cation as a side chain portion. Having as a side chain portion means that the corresponding first organic acid anion or first onium cation is bonded (covalently bonded) to the main chain as a side chain structure of the base polymer. When the third organic acid anion is bonded to the main chain as a side chain structure of the base polymer, the third onium cation is ionically bonded to the third organic acid anion as a counter ion of the third organic acid anion. On the other hand, when the third onium cation is bonded to the main chain as a side chain structure of the base polymer, the third organic acid anion is ionically bonded to the third onium cation as a counter ion of the third onium cation. From the viewpoint of controlling the acid diffusion length, the base polymer preferably has the third organic acid anion as a side chain portion.

The third organic acid anion preferably has at least one anion selected from the group consisting of a sulfonate anion, a carboxylate anion, and a sulfonimide anion as an acid anion moiety. Examples of the acid generated through exposure to light may include a sulfonic acid, a carboxylic acid, and a sulfonimide corresponding to the acid anion moiety.

The third organic acid anion preferably includes —O—, —CO—, a cyclic structure, or a combination thereof as a structure other than the acid anion moiety. The combination also includes a structure (heterocyclic structure) in which —O— or —CO— is incorporated as a moiety forming a ring in a cyclic structure.

In the first acid generating structure, it is preferable that the third organic acid anion have a sulfonate anion as an acid anion moiety, and an electron attractive group be bonded to a carbon atom at α-position or β-position to a sulfur atom in the sulfonate anion. As a result, the first acid generating structure can efficiently exhibit the above function. Examples of the electron attractive group include a fluorine atom, a fluorinated hydrocarbon group, a nitro group, and a cyano group. As the fluorinated hydrocarbon group, a perfluoroalkyl group having 1 to 5 carbon atoms is preferable.

The third organic acid anion preferably has an iodo group. The third organic acid anion preferably contains the iodo group-containing aromatic ring structure as an aspect of containing an iodo group.

Examples of the third onium cation include radiolytic onium cations. Examples of the radiolytic onium cation include a sulfonium cation, a tetrahydrothiophenium cation, and an iodonium cation. Among them, a sulfonium cation or an iodonium cation is preferable, and a sulfonium cation is more preferable.

The third onium cation preferably has a fluoro group or an iodo group. The fluoro group-containing aromatic ring structure is a structure in which some or all of hydrogen atoms of the aromatic ring are substituted with a fluoro group. As the aromatic ring in the fluoro group-containing aromatic ring structure, an aromatic ring in the iodo group-containing aromatic ring structure can be suitably employed. The third onium cation preferably has a fluoro group-containing aromatic ring structure as an aspect of containing a fluoro group. The third onium cation preferably contains the iodo group-containing aromatic ring structure as an aspect of containing an iodo group.

When the structural unit (VII) has the above structures in combination, the functions described above can be efficiently exerted.

The structural unit (VII) is preferably a structural unit represented by the following formula (a1) (hereinafter also referred to as “structural unit (VII-1)”).

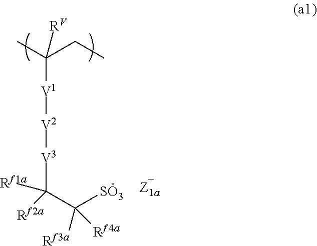

In the formulas, R^{V} is a hydrogen atom or a methyl group. V¹ is a single bond or an ester group. V² is a linear, branched or cyclic alkylene group having 1 to 12 carbon atoms, a cycloalkylene group having 3 to 12 carbon atoms, an arylene group having 6 to 10 carbon atoms, a combination thereof, or an amide bond, and a part of a methylene group composing the alkylene group, the cycloalkylene group, or the arylene group may be substituted with an ether group, an ester group, or a lactone ring-containing group. V³ is a single bond, an ether group, an ester group, a linear or branched alkylene group having 1 to 12 carbon atoms, or a cyclic cycloalkylene group having 3 to 12 carbon atoms, and a part of a methylene group composing the alkylene group may be substituted with an ether group or an ester group. Some or all of hydrogen atoms of V² and V³ may be substituted with a heteroatom or a monovalent hydrocarbon group having 1 to 20 carbon atoms optionally containing a heteroatom. Rf¹ to Rf⁴ are each independently a hydrogen atom, a fluorine atom, or a trifluoromethyl group, and at least one of Rf¹ to Rf⁴ is a fluorine atom or a fluorinated hydrocarbon group. Z₁⁺ is a sulfonium cation or an iodonium cation.

As the monovalent hydrocarbon group having 1 to 20 carbon atoms in V² and V³, an alkyl group having 1 to 12 carbon atoms, a cycloalkyl group having 3 to 12 carbon atoms, or an aryl group having 6 to 20 carbon atoms is preferable, and some or all of hydrogen atoms of these groups may be substituted with a heteroatom-containing group such as a hydroxy group, a carboxy group, a halogen atom, an oxo group, a cyano group, an amide group, a nitro group, a sultone group, a sulfone group or a sulfonium salt-containing group, an alkoxy group, or an alkoxycarbonyl group, and a part of a methylene group composing these groups may be substituted with an ether group, an ester group, a carbonyl group, a carbonate group, or a sulfonate ester group.

One preferable example of the structural unit (IV-1) is a structural unit represented by the following formula (a1-1).

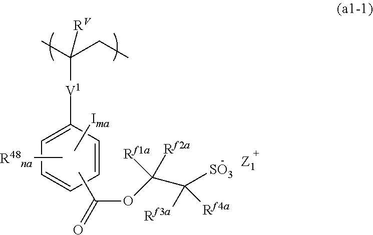

In the formulas, R^{V}, Rf^{1a} to Rf^{4a}, V¹ and Z₁⁺ have the same meanings as in the formula (a1). R⁴⁸ is a linear, branched or cyclic alkyl group having 1 to 4 carbon atoms, a halogen atom other than iodine, a hydroxy group, a linear, branched or cyclic alkoxy group having 1 to 4 carbon atoms, or a linear, branched or cyclic alkoxycarbonyl group having 2 to 5 carbon atoms. ma is an integer of 0 to 4. na is an integer of 0 to 3.

Examples of the third organic acid anion of the monomer that affords the structural unit (VII) (including the structural unit (IV-1)) include, but are not limited to, those shown below. In the following, the iodo group of the iodo group-containing aromatic ring structure may be replaced by a hydrogen atom, a substituent described for L¹¹ of the above formula (3), or the like. In the following formulas, R^{V} has the same meaning as described above.

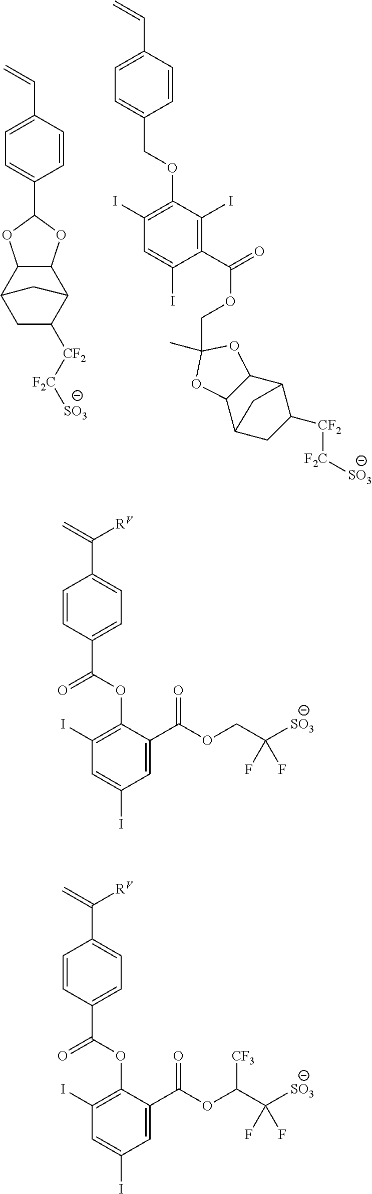

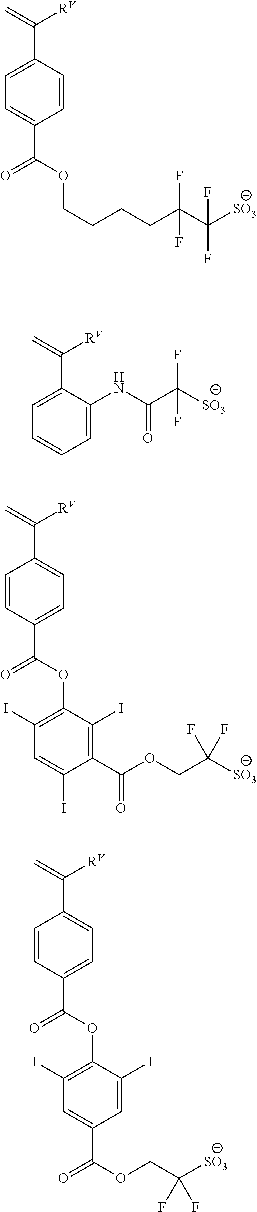

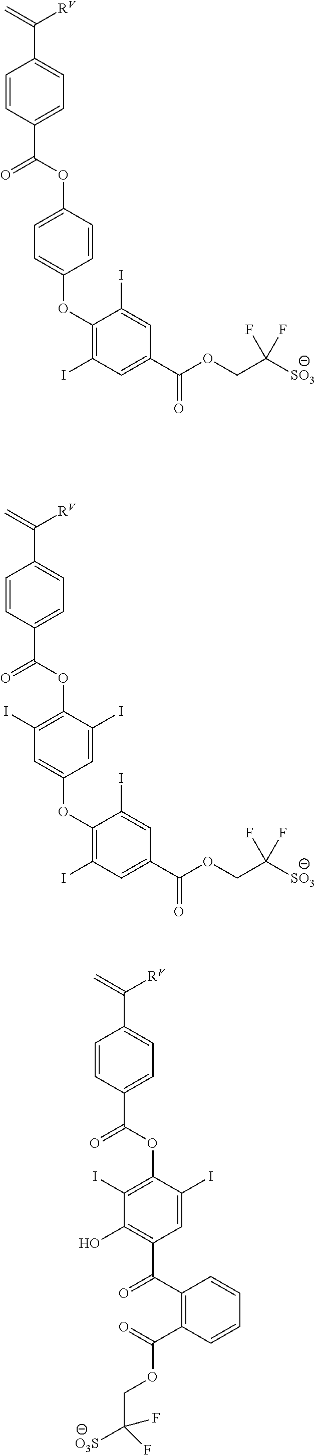

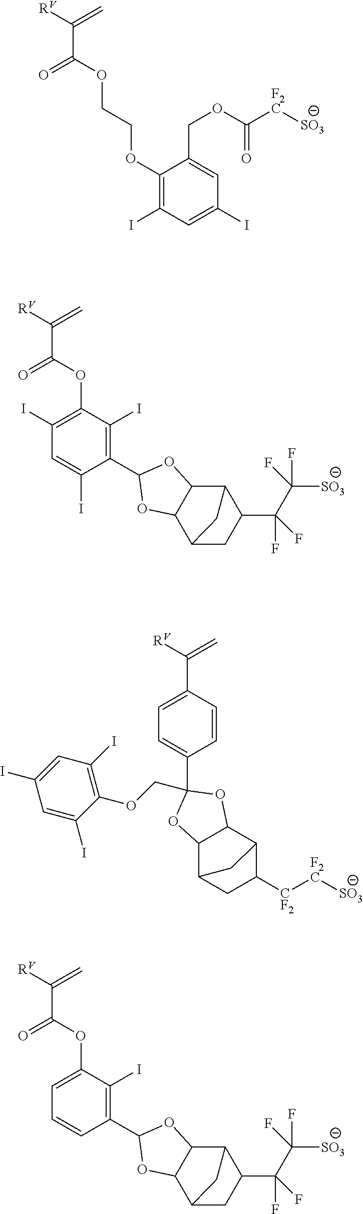

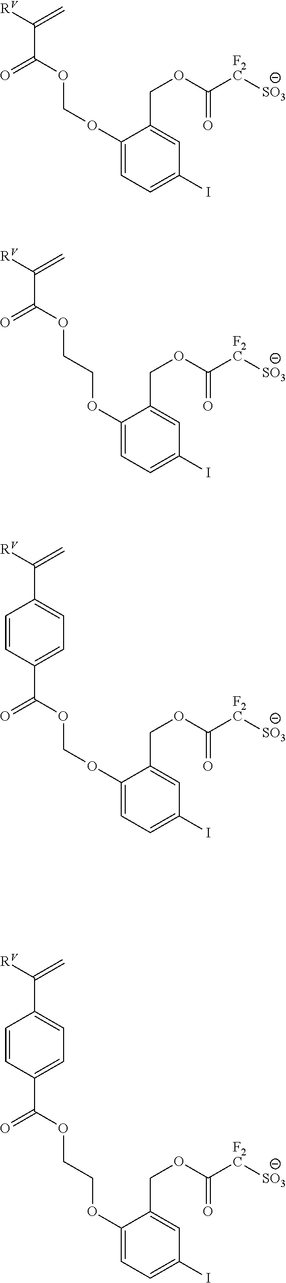

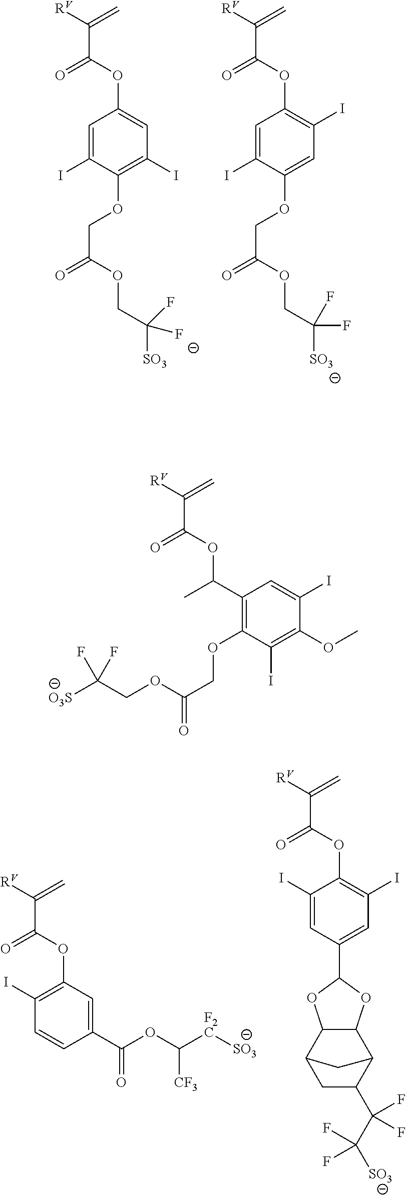

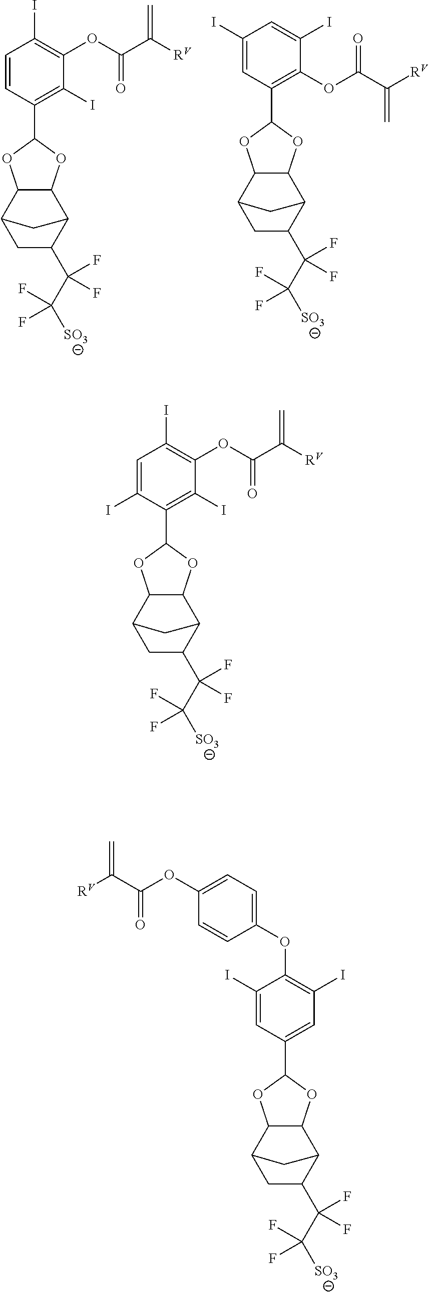

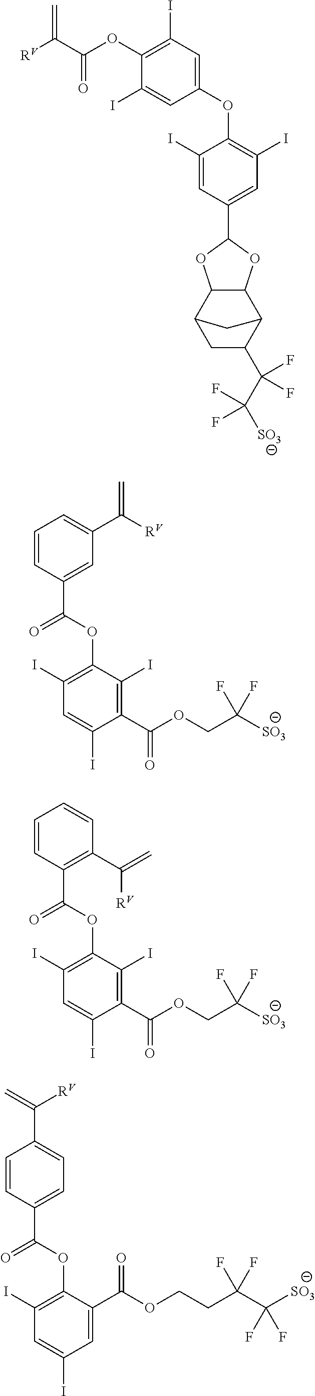

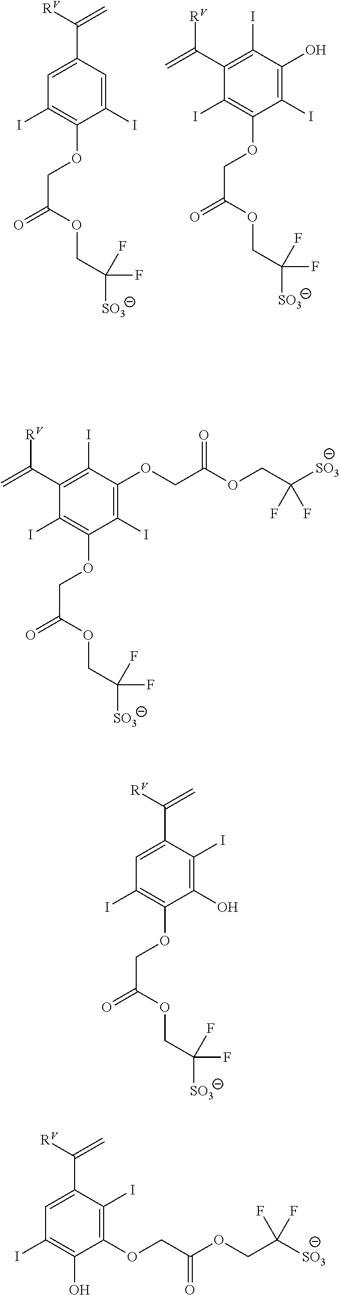

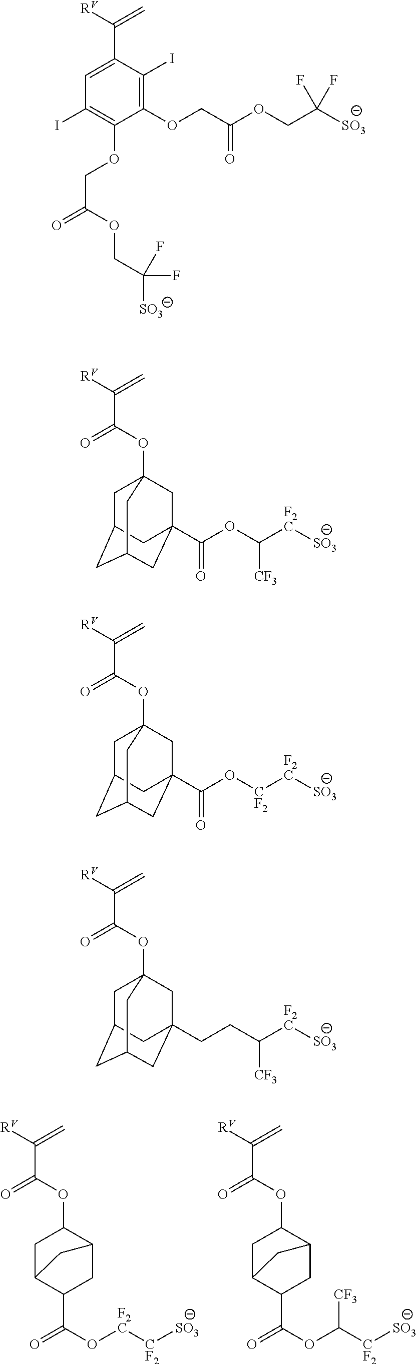

As Z₁ₐ_{⁺} in the formula (a1), a first onium cation in the radiation-sensitive acid generator described later can be suitably employed.

As a side chain structure of the base polymer, an aspect can also be suitably employed in which the third onium cation is bonded to the main chain, and the third organic acid anion is ionically bonded to the third onium cation as a counter ion of the third onium cation. In this case, it is preferable that the third onium cation be bonded to the main chain via a divalent linking group or a single bond, and a structure from V² to SO₃⁻ in the formula (a1) be ionically bonded to the third onium cation as a counter ion. As the divalent linking group, a group represented by L¹¹ of the formula (3) can be suitably employed.

When the base polymer has the structural unit (VII), the lower limit of the content ratio of the structural unit (VII) (the total content ratio is used when a plurality of structural units (VII) are contained) is preferably 5 mol %, more preferably 10 mol %, and still more preferably 15 mol % based on all structural units constituting the base polymer. The upper limit of the content ratio is preferably 40 mol %, more preferably 30 mol %, and still more preferably 25 mol %. When the content ratio of the structural unit (VII) is adjusted within the above range, the function as an acid generating structure can be sufficiently exhibited, and the various resist properties can be exhibited.

The monomer that affords the structural unit (VII-1) can be synthesized, for example, by the same method as that for a sulfonium salt having a polymerizable anion described in Japan Patent No. 5201363.

### (Structural Unit (VIII))

The base polymer may contain a structural unit (VIII) having a second organic acid anion and a fourth onium cation and having a fourth acid generating structure that generates an acid that does not dissociate the acid-dissociable group through exposure to light. An onium salt structure formed of the fourth organic acid anion and the fourth onium cation (that is, the fourth acid generating structure) functions as an acid diffusion controlling structure. Specifically, the fourth acid generating structure has a function of suppressing, by salt exchange, the diffusion of an acid generated from the first acid generating structure or a radiation-sensitive acid generator in the unexposed portion without substantially dissociate the acid-dissociable group of the structural unit (I) under a pattern forming condition using the radiation-sensitive composition. The acid generated from the fourth acid generating structure can be said to be a relatively weaker acid (acid having a higher pKa) than the acid generated from the first acid generating structure. Whether the onium salt structure functions as a radiation-sensitive acid generating structure or an acid diffusion controlling structure depends on the energy required for dissociating the acid-dissociable group of the base polymer, and the acidity of the onium salt structure or the generated acid.

The form of the fourth organic acid anion and the fourth onium cation contained in the structural unit (VIII) of the base polymer is not particularly limited, but the base polymer may have the fourth organic acid anion as a side chain portion or may have the fourth onium cation as a side chain portion. Having as a side chain portion means that the corresponding second organic acid anion or second onium cation is bonded (covalently bonded) to the main chain as a side chain structure of the base polymer. When the fourth organic acid anion is bonded to the main chain as a side chain structure of the base polymer, the fourth onium cation is ionically bonded to the fourth organic acid anion as a counter ion of the fourth organic acid anion. On the other hand, when the fourth onium cation is bonded to the main chain as a side chain structure of the base polymer, the fourth organic acid anion is ionically bonded to the fourth onium cation as a counter ion of the fourth onium cation. From the viewpoint of development contrast, the base polymer preferably has the fourth organic acid anion as a side chain portion.

The fourth organic acid anion preferably has a sulfonate anion or a carboxylate anion as an acid anion moiety, more preferably has a carboxylate anion, provided that when the fourth organic acid anion has the sulfonate anion, no electron-withdrawing group is bonded to the carbon atom at the α- or β-position relative to the sulfur atom in the sulfonate anion.. Examples of the electron attractive group include electron attractive groups that can be possessed by the third organic acid anion in the first acid generating structure. The acid generated through exposure to light is a carboxylic acid or a sulfonic acid corresponding to the acid anion moiety.

The fourth organic acid anion preferably includes —O—, —CO—, a cyclic structure, or a combination thereof as a structure in addition to the acid anion moiety. As such a structure, the structure represented by the first organic acid anion can be suitably employed.

The fourth organic acid anion preferably has an iodo group or a hydroxy group. The fourth organic acid anion preferably contains the iodo group-containing aromatic ring structure as an aspect of containing an iodo group.

Examples of the fourth onium cation include a radiolytic or non-radiolytic onium cation. Examples of the radiolytic or non-radiolytic onium cation include a sulfonium cation, a tetrahydrothiophenium cation, an iodonium cation, and an ammonium cation. Among them, a sulfonium cation or an iodonium cation is preferable, and a sulfonium cation is more preferable.

The fourth onium cation preferably has a fluoro group or an iodo group. The fourth onium cation preferably contains the fluoro group containing aromatic ring structure or the iodo group-containing aromatic ring structure as an aspect of containing a fluoro group or an iodo group.

When the structural unit (VIII) has the above structures in combination, the above functions can be efficiently exhibited.

The structural unit (VIII) is preferably a structural unit represented by the following formula (p1) (hereinafter, also referred to as a “structural unit (VIII-1)”).

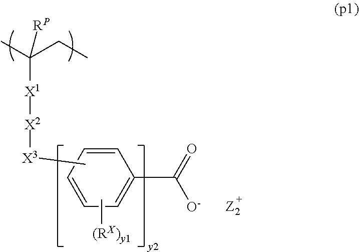

In the formula (p1), R^{P} is a hydrogen atom or a methyl group.

In the formula (p1), X¹ is a single bond, an ester bond, an ether bond, a phenylene group, or a naphthylene group.

In the formula (p1), X² is a single bond, a saturated hydrocarbylene group having 1 to 12 carbon atoms, or a phenylene group, and the saturated hydrocarbylene group may contain an ether bond, an ester bond, an amide bond, a lactone ring, or a sultone ring. The hydrocarbylene group represented by X² may be linear, branched, or cyclic, and specific examples thereof include a methylene group, an ethane-1,1-diyl group, an ethane-1,2-diyl group, a propane-1,2-diyl group, a propane-1,3-diyl group, a propane-2,2-diyl group, a butane-1,2-diyl group, a butane-1,3-diyl group, a butane-1,4-diyl group, a butane-2,2-diyl group, a butane-2,3-diyl group, a 2-methylpropane-1,3-diyl group, a pentane-1,5-diyl group, a hexane-1,6-diyl group, a heptane-1,7-diyl group, an octane-1,8-diyl group, a nonane-1,9-diyl group, alkanediyl groups having 1 to 12 carbon atoms such as a decane-1,10-diyl group; cyclic saturated hydrocarbylene groups having 3 to 12 carbon atoms such as a cyclopentanediyl group, a cyclohexanediyl group, a norbornanediyl group, or an adamantanediyl group; and groups obtained by combining them.

In the formula (p1), X³ is a single bond, an ester bond, or an ether bond.

In the formula (p1), RX is a linear, branched or cyclic alkyl group having 1 to 5 carbon atoms, a halogen atom, a hydroxy group, a linear, branched or cyclic alkoxy group having 1 to 4 carbon atoms, or a linear, branched or cyclic alkoxycarbonyl group having 2 to 5 carbon atoms.

In the formula (p1), Z₂_{⁺} has the same meaning as Z₁ₐ_{⁺} in the formula (a1).

In the formula (p1), y1 is an integer of 0 to 3. When x1 is 2 or more, the plurality of R^{X}s are the same as or different from each other.

In formula (p1), y2 is 0 or 1.

Examples of the fourth organic acid anion of the monomer that affords the structural unit (VIII) include, but are not limited to, those shown below. The iodo groups or the hydroxy groups in the following formulas may be replaced by a hydrogen atom, a substituent described for L¹¹ of the above formula (3), or the like. In the following formulas, RP is the same as described above. The fourth organic acid anion preferably has a carboxylic acid anion and a hydroxy group. In this case, the carboxylic acid anion and the hydroxy group are preferably bonded to the same aromatic ring in the fourth organic acid anion, and in the same aromatic ring, a carbon atom to which the carboxylic acid anion is bonded and a carbon atom to which the hydroxy group is bonded are more preferably directly bonded to each other.

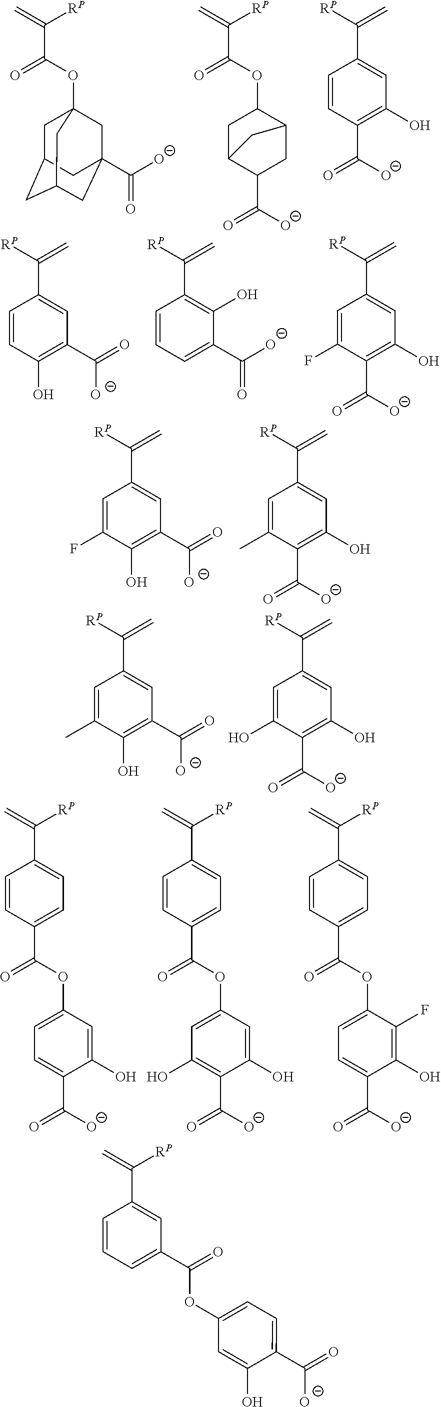

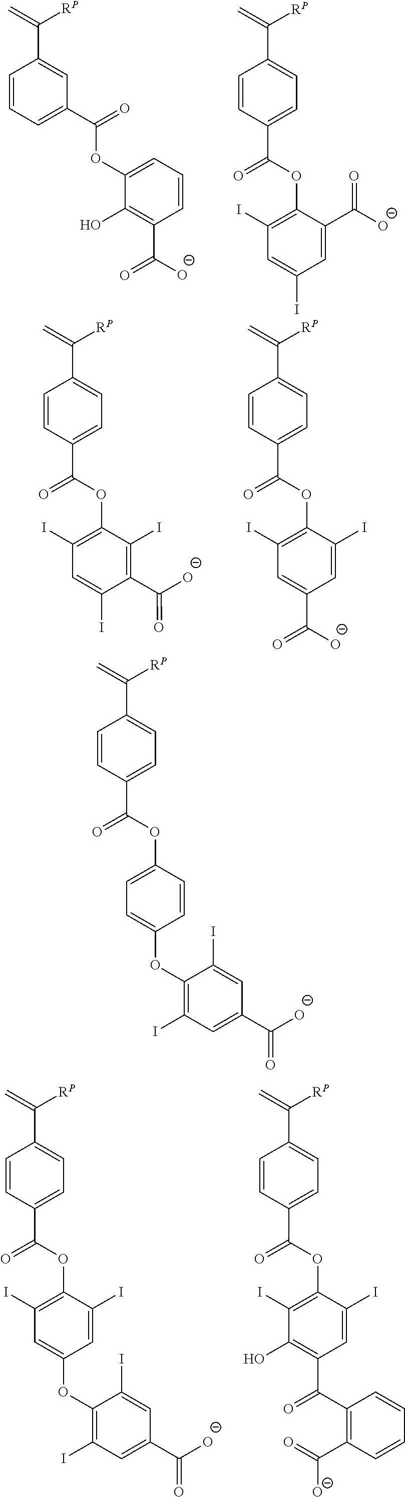

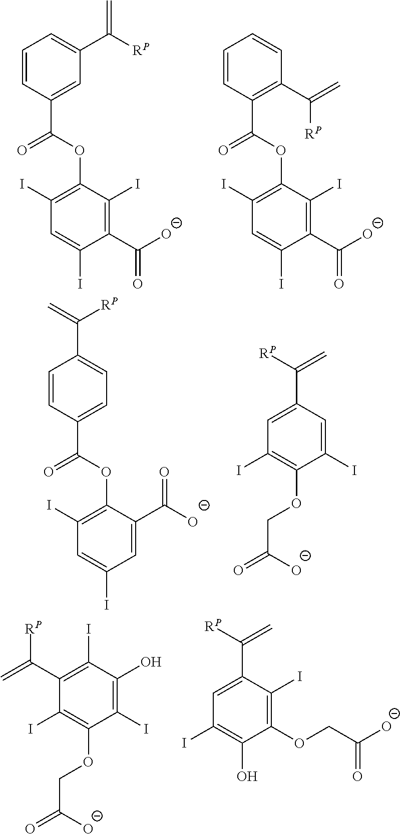

As a side chain structure of the base polymer, an aspect can also be suitably employed in which the fourth onium cation is bonded to the main chain, and the fourth organic acid anion is ionically bonded to the fourth onium cation as a counter ion of the fourth onium cation. In this case, it is preferable that the fourth onium cation be bonded to the main chain via a divalent linking group or a single bond, and a structure from X¹ to COO⁻ in the formula (p1) be ionically bonded to the fourth onium cation as a counter ion. As the divalent linking group, the group represented by L1 of the formula (3) can be suitably employed.

When the base polymer contains the structural unit (VIII), the lower limit of the content of the structural unit (VIII) (the total content when a plurality of structural units (VIII) are contained) is preferably 5 mol %, more preferably 10 mol %, still more preferably 15 mol % based on all structural units composing the base polymer. The upper limit of the content is preferably 40 mol %, more preferably 30 mol %, still more preferably 25 mol %. When the acid diffusion controlling agent, which is an optional component, is contained, it is sufficient that the total amount of the monomer that affords the structural unit (VIII) and the acid diffusion controlling agent is within the above range. When the content ratio of the structural unit (VIII) is adjusted within the above range, the function as an acid diffusion controlling structure can be sufficiently exhibited.

When the base polymer contains the structural unit (VII) and the structural unit (VIII), a single polymerized chain may contain both the structural unit (VII) and the structural unit (VIII), or alternatively, one polymerized chain may contain the structural unit (VII), and another polymerized chain may contain the structural unit (VIII). It is sufficient that the polymer chain aggregate contains the structural unit (VII) and the structural unit (VIII).

### (Method for Synthesizing Base Polymer)

The base polymer can be synthesized by, for example, polymerizing monomers that will afford respective structural units in an appropriate solvent using a radical polymerization initiator or the like.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), and dimethyl 2,2′-azobisisobutyrate; and peroxide radical initiators, such as benzoyl peroxide, t-butyl hydroperoxide, and cumene hydroperoxide. Among them, AIBN and dimethyl 2,2′-azobisisobutyrate are preferable, and AIBN is more preferable. These radical initiators can be used singly or in mixture of two or more thereof.

Examples of the solvent to be used in the polymerization include:
alkanes such as n-pentane, n-hexane, n-heptane, n-octane, n-nonane, and n-decane;
cycloalkanes such as cyclohexane, cycloheptane, cyclooctane, decalin, and norbornane;
aromatic hydrocarbons such as benzene, toluene, xylene, ethylbenzene, and cumene;
halogenated hydrocarbons such as chlorobutanes, bromohexanes, dichloroethanes, hexamethylene dibromide, and chlorobenzene;
saturated carboxylic acid esters such as ethyl acetate, n-butyl acetate, i-butyl acetate, and methyl propionate;
ketones such as acetone, methyl ethyl ketone, 2-butanone, 4-methyl-2-pentanone, and 2-heptanone;
ethers such as tetrahydrofuran, dimethoxyethanes, and diethoxyethanes; and
alcohols such as methanol, ethanol, 1-propanol, 2-propanol, 1-methoxy-2-propanol, and 4-methyl-2-pentanol. The solvents to be used in the polymerization may be used singly, or two or more thereof may be used in combination.

The reaction temperature in the polymerization is usually 40° C. to 150° C., preferably 50° C. to 120° C. The reaction time is usually 1 hour to 48 hours, preferably 1 hour to 24 hours.

The molecular weight of the base polymer is not particularly limited, but the lower limit of the weight average molecular weight (Mw) as determined by Gel Permeation Chromatography (GPC) relative to standard polystyrene is preferably 2,000, more preferably 3,000, still more preferably 4,000, particularly preferably 4,500. The upper limit of the Mw is preferably 20,000, more preferably 10,000, still more preferably 8,000, particularly preferably 7,000. When the Mw of the base polymer is adjusted to within the above range, the resulting resist film can exhibit good heat resistance and developability.

The ratio (Mw/Mn) of the Mw to the number average molecular weight (Mn) of the base polymer as determined by GPC relative to standard polystyrene is usually 1 or more and 5 or less, preferably 1 or more and 3 or less, more preferably 1 or more and 2 or less.

The method for measuring Mw and Mn of a polymer in the specification is as described in Examples.

The lower limit of the content ratio of the base polymer is preferably 40% by mass, more preferably 50% by mass, and still more preferably 55% by mass based on the total solid content of the radiation-sensitive composition. The upper limit of the content ratio is preferably 80% by mass, more preferably 75% by mass, and still more preferably 70% by mass.

### (Other Polymers)

The radiation-sensitive composition according to the present embodiment may contain, as another polymer, a polymer having a content by mass of fluorine atoms higher than that of the base polymer (hereinafter also referred to as “high fluorine-content polymer”). When the radiation-sensitive composition contains the high fluorine-content polymer, the radiation-sensitive composition can be localized on the surface layer of a resist film relative to the base polymer, and as a result, the surface modification of a resist film at the time of EUV exposure, and the control of distribution of a composition in the film can be achieved.

The high fluorine-content polymer preferably has, for example, a structural unit represented by the following formula (5) (hereinafter also referred to as “structural unit (V)”), and may have the structural unit (I) or the structural unit (IV) in the base polymer, as necessary.

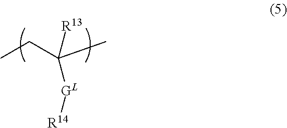

In the above formula (5), R¹³ is a hydrogen atom, a methyl group, or a trifluoromethyl group. G^{L} is a single bond, an alkanediyl group having 1 to 5 carbon atoms, an oxygen atom, a sulfur atom, —COO—, —SO₂ONH—, —CONH—, —OCONH—, or a combination thereof. R¹⁴ is a monovalent fluorinated chain hydrocarbon group having 1 to 20 carbon atoms or a monovalent fluorinated alicyclic hydrocarbon group having 3 to 20 carbon atoms.

As R¹³, a hydrogen atom and a methyl group are preferable from the viewpoint of the copolymerizability of a monomer that affords the structural unit (V), and a methyl group is more preferable.

As the G^{L}, a single bond and —COO— are preferable from the viewpoint of the copolymerizability of a monomer that affords the structural unit (V), and —COO— is more preferable.

Examples of the monovalent fluorinated chain hydrocarbon group having 1 to 20 carbon atoms represented by R¹⁴ include groups in which some or all of the hydrogen atoms in the linear or branched chain alkyl group having 1 to 20 carbon atoms are replaced by fluorine atoms.

Examples of the monovalent fluorinated alicyclic hydrocarbon group having 3 to 20 carbon atoms represented by R¹⁴ include monovalent fluorinated alicyclic hydrocarbon groups having 3 to 20 carbon atoms in which some or all of the hydrogen atoms of a mono- or polycyclic hydrocarbon group are replaced by fluorine atoms.

As R¹⁴, fluorinated chain hydrocarbon groups are preferable, fluorinated alkyl groups are more preferable, and a 2,2,2-trifluoroethyl group, a 2,2,3,3,3-pentafluoropropyl group, a 1,1,1,3,3,3-hexafluoropropan-2-yl group, and a 5,5,5-trifluoro-1,1-diethylpentyl group are still more preferable.

When the high fluorine-content polymer has the structural unit (V), the lower limit of the content ratio of the structural unit (V) is preferably 2 mol %, more preferably 5 mol %, and still more preferably 8 mol % based on all structural units constituting the high fluorine-content polymer. The upper limit of the content ratio is preferably 30 mol %, more preferably 20 mol %, and still more preferably 15 mol %. When the content ratio of the structural unit (V) is adjusted within the above range, the content by mass of fluorine atoms of the high fluorine-content polymer can more appropriately be adjusted to further promote the localization of the high fluorine-content polymer in the surface layer of a resist film and, as a result, the surface modification property, the component distribution controllability, and the water repellency of the resist film can be further improved.

The high fluorine-content polymer may have a fluorine atom-containing structural unit represented by the following formula (f-2) (hereinafter also referred to as structural unit (VI)) in addition to the structural unit (V) or instead of the structural unit (V). Due to the fact that the high fluorine-content polymer has the structural unit (VI), the solubility in an alkaline developer is improved, and the occurrence of development defects can be suppressed.

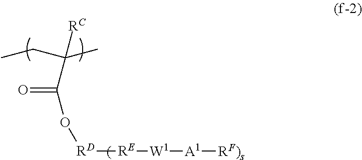

The structural unit (VI) is roughly divided into two cases: a case where the structural unit (VI) has (x) an alkali-soluble group, and a case where the structural unit (VI) has (y) a group that is dissociated by the action of an alkali to increase the solubility in an alkaline developer (hereinafter also simply referred to as “alkali-dissociable group”). Commonly in (x) and (y), in the above formula (f-2), R^{C} is a hydrogen atom, a fluorine atom, a methyl group, or a trifluoromethyl group. R^{D} is a single bond, a hydrocarbon group having 1 to 20 carbon atoms with the valency of (s+1), a structure in which an oxygen atom, a sulfur atom, —NR^{dd}—, a carbonyl group, —COO—, —OCO—, or —CONH— is connected to the terminal on R^{E} side of the hydrocarbon group, or a structure in which some of the hydrogen atoms in the hydrocarbon group are replaced by organic groups having a heteroatom. R^{dd} is a hydrogen atom or a monovalent hydrocarbon group having 1 to 10 carbon atoms. s is an integer of 1 to 3.

When the structural unit (VI) has (x) an alkali-soluble group, RF is a hydrogen atom, and A¹ is an oxygen atom, —COO—* or —SO₂O—*. * indicates a site that bonds to RF. W¹ is a single bond, a hydrocarbon group having 1 to 20 carbon atoms, or a divalent fluorinated hydrocarbon group. When A¹ is an oxygen atom, W¹ is a fluorinated hydrocarbon group having a fluorine atom or a fluoroalkyl group on the carbon atom to which A¹ is bonded. R^{E} is a single bond or a divalent organic group having 1 to 20 carbon atoms. When s is 2 or 3, the plurality of R^{E}s, W¹s, A¹s, and RFs may be the same or different, respectively. When the structural unit (VI) has (x) an alkali-soluble group, affinity to an alkaline developer can be increased, and development defects can be suppressed. As the structural unit (VI) having (x) an alkali-soluble group, a case where A¹ is an oxygen atom and W¹ is a 1,1,1,3,3,3-hexafluoro-2,2-methanediyl group is particularly preferable.

When the structural unit (VI) has (y) an alkali-dissociable group, RF is a monovalent organic group having 1 to 30 carbon atoms, and A¹ is an oxygen atom, —NR^{aa}, —COO—*, —OCO—*, or —SO₂O—*. R^{aa} is a hydrogen atom or a monovalent hydrocarbon group having 1 to 10 carbon atoms. * indicates a site that bonds to RF. W¹ is a single bond or a divalent fluorinated hydrocarbon group having 1 to 20 carbon atoms. R^{E}is a single bond or a divalent organic group having 1 to 20 carbon atoms. When A¹ is —COO—*, —OCO—*, or —SO₂O—*, W¹ or RF has a fluorine atom on a carbon atom bonded to A¹ or on a carbon atom adjacent thereto. When A¹ is an oxygen atom, W¹ and R^{E} are single bonds, R^{D} is a structure in which a carbonyl group is bonded to a terminal on the R^{E} side of a hydrocarbon group having 1 to 20 carbon atoms, and RF is an organic group having a fluorine atom. When s is 2 or 3, the plurality of R^{E}s, W's, Als, and RFs may be the same or different, respectively. When the structural unit (VI) has (y) an alkali-dissociable group, the surface of a resist film changes from hydrophobic to hydrophilic in an alkali development step. As a result, the affinity to a developer can be greatly increased, and development defects can be more efficiently suppressed. As the structural unit (VI) having (y) an alkali-dissociable group, a structural unit in which A¹ is —COO—*, and RF, W¹, or both of them have a fluorine atom is particularly preferable.

As R^{C}, a hydrogen atom and a methyl group are preferable from the viewpoint of the copolymerizability of a monomer that affords the structural unit (VI), and a methyl group is more preferable.

When R^{E} is a divalent organic group, a group having a lactone structure is preferable, a group having a polycyclic lactone structure is more preferable, and a group having a norbornanelactone structure is still more preferable.

When the high fluorine-content polymer has the structural unit (VI), the lower limit of the content ratio of the structural unit (VI) is preferably 40 mol %, more preferably 50 mol %, and still more preferably 55 mol % based on all structural units constituting the high fluorine-content polymer. The upper limit of the content ratio is preferably 95 mol %, more preferably 90 mol %, and still more preferably 85 mol %. When the content ratio of the structural unit (VI) is adjusted within the above range, the solubility in an alkaline developer can be improved to suppress the occurrence of development defects.

### (Other Structural Units)

The high fluorine-content polymer may contain the structural unit (I) and the structural unit (IV) in the base polymer as structural units other than the structural units listed above. When the high fluorine-content polymer contains the structural unit (IV), a structure containing a fluorine atom is preferable as the structural unit (IV).

When the high fluorine-content polymer contains the structural unit (I), the content ratio described for the base polymer can be suitably employed as the content ratio of the structural unit (I) in the high fluorine-content polymer.

When the high fluorine-content polymer contains the structural unit (IV), the lower limit of the content ratio of the structural unit (IV) based on all structural units constituting the high fluorine-content polymer is preferably 50 mol %, more preferably 60 mol %, and still more preferably 65 mol %. The upper limit of the content ratio is preferably 99 mol %, more preferably 98 mol %, and still more preferably 95 mol %.

The lower limit of the Mw of the high fluorine-content polymer is preferably 2,000, more preferably 3,000, still more preferably 4,000. The upper limit of the Mw is preferably 20,000, more preferably 10,000, still more preferably 7,000.

The lower limit of the Mw/Mn of the high fluorine-content polymer is usually 1, more preferably 1.1. The upper limit of the Mw/Mn is usually 5, preferably 3, more preferably 2.

When the radiation-sensitive composition contains the high fluorine-content polymer, the content of the high fluorine-content polymer is preferably 1 part by mass or more, more preferably 3 parts by mass or more, and still more preferably 5 parts by mass or more based on 100 parts by mass of the base polymer. The content is preferably 15 parts by mass or less, more preferably 10 parts by mass or less, and still more preferably 8 parts by mass or less.

When the content of the high fluorine-content polymer is adjusted to within the above range, the high fluorine-content polymer can be more effectively localized on the surface layer of a resist film, and as a result, the surface modification of the resist film at the time of EUV exposure and the control of distribution of a composition in the film can be achieved. The radiation-sensitive composition may contain one second polymer, or two or more high fluorine-content polymers.

(Method for synthesizing a high fluorine-content polymer) The high fluorine-content polymer can be synthesized by the same method as the method described above for synthesizing the base polymer.

### <Radiation-Sensitive Acid Generator>

The radiation-sensitive acid generator contains a first organic acid anion and a first onium cation, and forms the onium salt structure. The radiation-sensitive acid generator is a component that generates an acid through exposure to light. The acid generated through exposure to light has a function of dissociating the acid-dissociable group of the base polymer to generate a carboxy group or the like. The form of the radiation-sensitive acid generator contained in the radiation-sensitive composition may be a form in which the onium salt structure is present alone as a compound (released from a polymer), a form in which the onium salt structure is incorporated as a part of a polymer, or both of these forms. The form of the radiation-sensitive acid generator contained in the radiation-sensitive composition is preferably a form in which the onium salt structure is present alone as a (low molecular weight) compound.

In the specification, the “dissociation” of the acid-dissociable group refers to dissociation that occurs when post-exposure baking is performed at 110° C. for 60 seconds.

When the radiation-sensitive composition contains the radiation-sensitive acid generator, the polarity of the polymer in an exposed area increases, and as a result, the polymer in the exposed area is soluble in a developer in the case of development with an alkaline aqueous solution, whereas the polymer in the exposed area is hardly soluble in a developer in the case of development with an organic solvent.

The first organic acid anion contains an acid anion moiety and an aromatic ring having at least both a first substituent and a second substituent (hereinafter, the aromatic ring serving as a mother skeleton is also referred to as a “specific aromatic ring”). The first substituent and the second substituent are each independently a hydroxy group, a sulfo group, or a sulfanyl group.

The acid anion moiety is preferably a sulfonate anion or a sulfonimide anion, and more preferably a sulfonate anion.

As the specific aromatic ring, an aromatic ring in the iodo group-containing aromatic ring structure can be suitably employed. The specific aromatic ring may be either a polycyclic ring or a monocyclic ring, but is preferably a monocyclic ring, and more preferably a benzene ring. The number of specific aromatic rings in the radiation-sensitive acid generator is not particularly limited, but is preferably 1, 2 or 3, and more preferably 1 or 2 from the viewpoint of solubility.

Preferably, at least one of the first substituent and the second substituent is a hydroxy group. It is more preferable that both the first substituent and the second substituent are hydroxy groups from the viewpoint of solubility in a developer, CDU performance, and LWR performance.

Although the positions of the first substituent and the second substituent in the specific aromatic ring are not specified, it is preferable that the first substituent and the second substituent exist at ortho positions (the carbon atom to which the first substituent is bonded and the carbon atom to which the second substituent is bonded are adjacent). Owing to this configuration, an intramolecular hydrogen bond is formed, so that the acidity is relatively increased, the solubility of the radiation-sensitive acid generator is increased, and increase in the glass transition temperature due to the interaction with the polymer is caused. As a result, improvement in the CDU performance and the LWR performance by shortening of diffusion can be attained.

The specific aromatic ring may have either one substituent or a plurality of substituents other than the first substituent and the second substituent. Examples of the other substituent include a halogen atom, a carboxy group, a cyano group, a nitro group, an alkyl group, a fluorinated alkyl group, an alkoxycarbonyloxy group, an acyl group, an acyloxy group, and an alkoxy group. As the other substituent, a substituent which the arenediyl group represented by L^{11a} of the above formula (3) can have can be suitably employed.

The first organic acid anion preferably contains the iodo group-containing aromatic ring structure from the viewpoint of improvement in sensitivity. The specific aromatic ring may have an iodine atom as the substituent other than the first substituent and the second substituent to form the iodo group-containing aromatic ring structure. The first organic acid anion may contain the iodo group-containing aromatic ring structure besides the specific aromatic ring.

The first organic acid anion preferably contains —O—, —CO—, a cyclic structure, or a combination thereof. The combination also includes a structure (heterocyclic structure) in which —O— or —CO— is incorporated as a moiety forming a ring in a cyclic structure.

The cyclic structure may be any of a monocyclic structure, a polycyclic structure, or a combination thereof. The cyclic structure may be any of an alicyclic structure, an aromatic ring structure, a heterocyclic structure, or a combination thereof. In the case of the combination, the ring structure may be a structure in which ring structures are bonded by a chain structure, or two or more ring structures may form a fused ring structure, a bridged ring structure, or a spiro ring structure. A divalent heteroatom-containing group may be present between carbons forming the skeleton of the cyclic structure or the chain structure, and some or all of hydrogen atoms on carbon atoms of the cyclic structure or the chain structure may be replaced by another substituent.

As the alicyclic structure, a structure corresponding to the monovalent alicyclic hydrocarbon group having 3 to 20 carbon atoms in R¹⁸ of the formula (3) can be suitably employed.

As the aromatic ring structure, the aromatic rings (including aromatic hydrocarbon rings and heteroaromatic rings) described for the iodo group-containing aromatic ring structure can be suitably employed.

Examples of the heterocyclic structure include:
oxygen atom-containing aliphatic heterocyclic structures such as oxirane, tetrahydrofuran, tetrahydropyran, dioxolane, and dioxane;
nitrogen atom-containing aliphatic heterocyclic structures such as aziridine, pyrrolidine, piperidine, and piperazine;
sulfur atom-containing aliphatic heterocyclic structures such as thietane, thiolane, and thiane;
aliphatic heterocyclic structures containing multiple types of heteroatoms such as morpholine, 1,2-oxathiolane, and 1,3-oxathiolane;
oxygen atom-containing aromatic heterocyclic structures such as furan and benzofuran;
nitrogen atom-containing aromatic heterocyclic structures such as pyrrole, pyrazole, and triazine;
sulfur atom-containing aromatic heterocyclic structures such as thiophene; and
aromatic heterocyclic structures containing multiple types of heteroatoms such as oxazole, isothiazole, and thiazine.

The heterocyclic structure includes a lactone structure, a cyclic carbonate structure, a sultone structure, a cyclic acetal, or a combination thereof. Examples of such structures include structures represented by the following formulas (H-1) to (H-11).

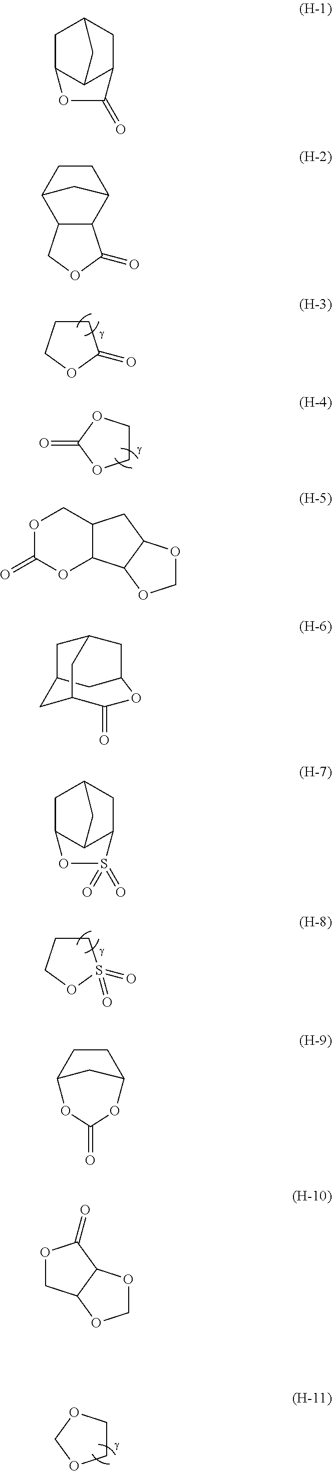

In the formulas, y is an integer of 1 to 3.

Examples of the divalent heteroatom-containing group include —CO—, —CS—, —NR′—, —O—, —S—, —SO₂—, or a divalent group obtained by combining them. R′ is a hydrogen atom or a hydrocarbon group having 1 to 10 carbon atoms.

Preferably, in the radiation-sensitive acid generator, the acid anion moiety is a sulfonate anion, and a fluorine atom or a fluorinated hydrocarbon group is bonded to the carbon atom adjacent to the sulfur atom of the sulfonate anion.. Thereby, the radiation-sensitive acid generator can efficiently exert the function described above.

The radiation-sensitive acid generator is preferably represented by the following formula (G-1).

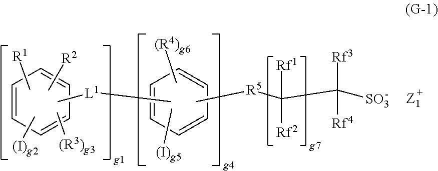

In the formula (G-1), L1 is a single bond, an ether linkage, an ester linkage, or an alkylene group having 1 to 6 carbon atoms optionally containing an ether linkage or an ester linkage. The alkylene group may be any of linear, branched, and cyclic.

R¹ and R² are each independently a hydroxy group, a sulfo group, or a sulfanyl group.

R³ and R⁴ are each independently a hydroxy group, a carboxy group, a fluorine atom, a chlorine atom, a bromine atom, or an amino group; or are each independently an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, or an alkylsulfonyloxy group having 1 to 20 carbon atoms, each optionally containing a fluorine atom, a chlorine atom, a bromine atom, a hydroxy group, an amino group, or an alkoxy group having 1 to 10 carbon atoms; or are each independently —NR⁸—C(═O)—R⁹ or —NR⁸—C(═O)—O—R⁹, wherein R⁸ is a hydrogen atom or an alkyl group having 1 to 6 carbon atoms and optionally containing a halogen atom, a hydroxy group, an alkoxy group having 1 to 6 carbon atoms, an acyl group having 2 to 6 carbon atoms, or an acyloxy group having 2 to 6 carbon atoms, and R⁹ is an alkyl group having 1 to 16 carbon atoms, an alkenyl group having 2 to 16 carbon atoms, or an aryl group having 6 to 12 carbon atoms and optionally contains a halogen atom, a hydroxy group, an alkoxy group having 1 to 6 carbon atoms, an acyl group having 2 to 6 carbon atoms, or an acyloxy group having 2 to 6 carbon atoms. The alkyl group, alkoxy group, alkoxycarbonyl group, acyloxy group, acyl group, and alkenyl group may be any of linear, branched, and cyclic.

Among them, a hydroxy group, —NR⁸—C(═O)—R⁹, a fluorine atom, a chlorine atom, a bromine atom, a methyl group, a methoxy group, and the like are preferable as R³. R⁵ is a single bond or a divalent linking group having 1 to 20 carbon atoms when g₄ is 1, and is a (g₁+1)-valent linking group having 1 to 20 carbon atoms when g₄ is 0. Examples of the linking group include a monovalent hydrocarbon group having 1 to 20 carbon atoms represented by R¹⁸ of the formula (3), a group containing the divalent heteroatom-containing group between carbon atoms of the foregoing hydrocarbon group (between adjacent or non-adjacent two carbon atoms), a group obtained by replacing some or all of the hydrogen atoms of the foregoing hydrocarbon group by a monovalent heteroatom-containing group, and a group obtained by combining them. Examples of the monovalent heteroatom-containing group include a hydroxy group, a carboxy group, a sulfanyl group, a cyano group, a nitro group, and halogen atoms. The linking group preferably contains —O—, —S—, —NR^{LL}—, —CO—, a cyclic structure, or a combination thereof. R^{LL} is a hydrogen atom or a monovalent hydrocarbon group having 1 to 10 carbon atoms.

Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may be combined to form a carbonyl group. In particular, it is preferable that both Rf³ and Rf⁴ are fluorine atoms.

g₁ is an integer of 1 to 3. g₂ and g₃ are each independently an integer of 0 to 2. g₄ is 0 or 1. g₅ is an integer of 0 to 3. g₆ is an integer of 0 to 2. g₇ is 0 or 1. g₂+g₅ is preferably an integer of 1 to 5, and more preferably an integer of 1 to 3. When g₄ is 0, g₂ is preferably 1 or 2. When g₄ is 1, g₂ is preferably 0, and g₅ is preferably an integer of 1 to 3.

Examples of the first organic acid anion of the radiation-sensitive acid generator represented by the formula (G-1) include, but are not limited to, those shown below. Instead of the first organic acid anion having the iodo group-containing aromatic ring structure, as the first organic acid anion having no iodo group-containing aromatic ring structure, a structure in which the iodo group in the following formula is replaced by a hydrogen atom or an atom or a group other than an iodo group, such as another substituent can be suitably employed.

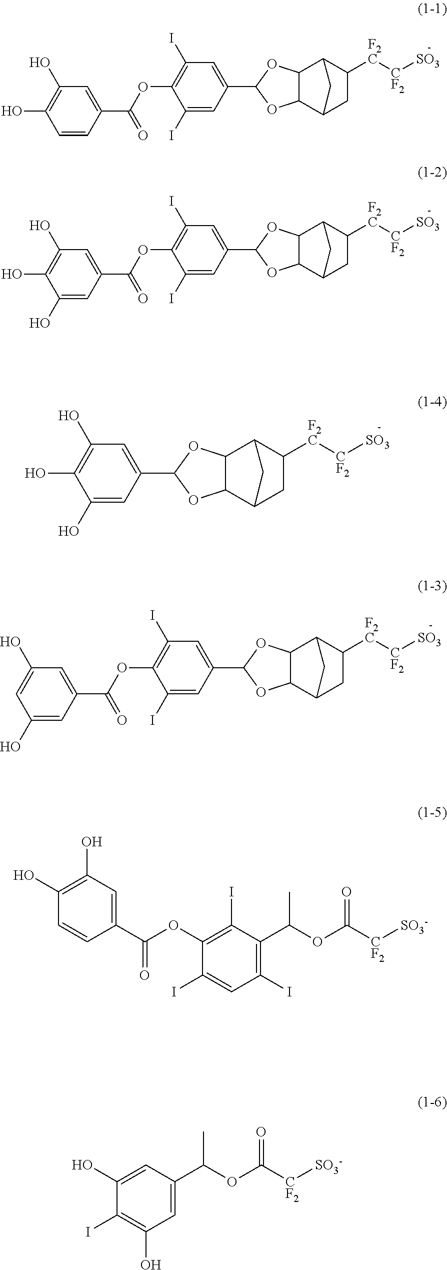

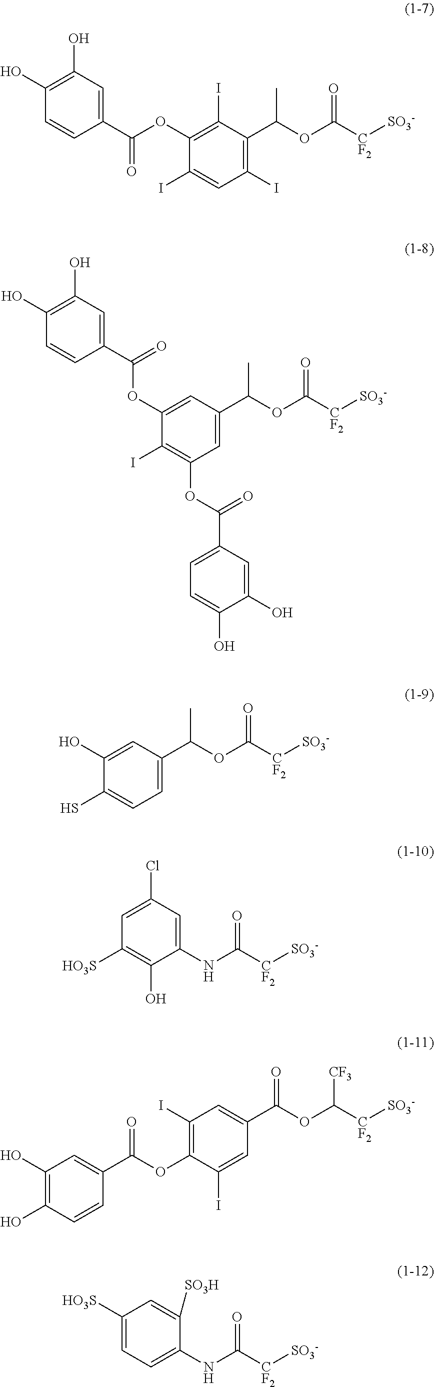

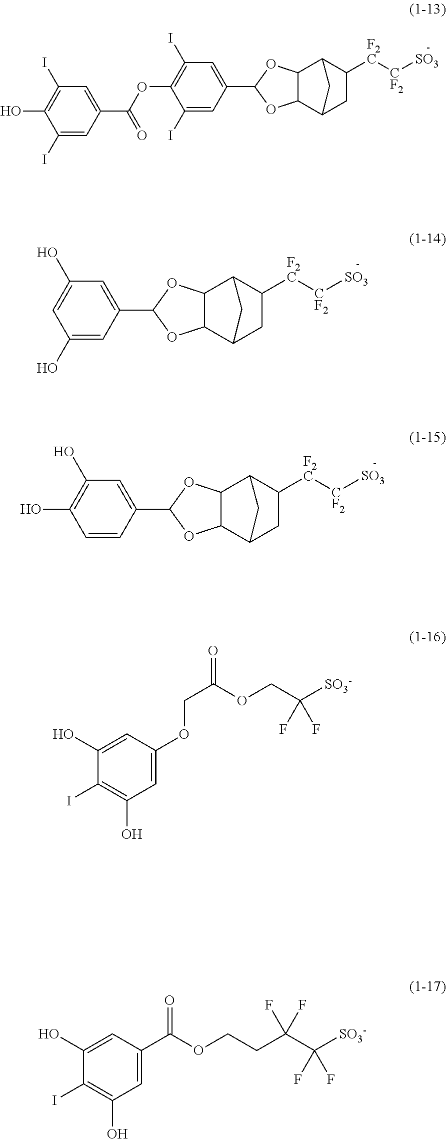

Z₁⁺ is a first onium cation. The first onium cation preferably contains at least one of a fluoro group and an iodo group. The first onium cation preferably contains an aromatic ring having a fluoro group (hereinafter also referred to as “fluoro group-containing aromatic ring structure”). The fluoro group-containing aromatic ring structure includes not only a structure in which a fluoro group is directly bonded to an aromatic ring, but also includes a structure in which a fluoro group is bonded to an aromatic ring with another structure interposed therebetween. As the aromatic ring in the fluoro group-containing aromatic ring structure, an aromatic ring in the iodo group-containing aromatic ring structure can be suitably employed.

The number of fluoro groups in the fluoro group-containing aromatic ring structure is not particularly limited, but is preferably 1, 2, 3, 4, or 5, and more preferably 1, 2, 3, or 4.

The first onium cation more preferably contains the iodo group-containing aromatic ring structure as an aspect of containing an iodo group.

The first onium cation is preferably a sulfonium cation or an iodonium cation, and more preferably a sulfonium cation.

The first onium cation is preferably represented by the following formula (Q-1).

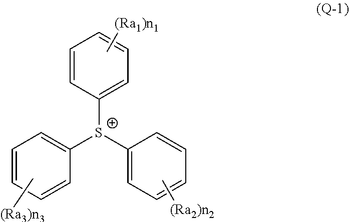

In the formula (Q-1), Ra1 and Ra2 each independently represent a substituent. n1 represents an integer of 0 to 5, and when n1 is 2 or more, the plurality of Ra1's may be the same as or different from each other. n2 represents an integer of 0 to 5, and when n2 is 2 or more, the plurality of Ra2's may be the same as or different from each other. n3 represents an integer of 0 to 5, and when n3 is 2 or more, the plurality of Ra3's may be the same as or different from each other. Ra3 represents a substituent. Ra1 and Ra2 may be linked to each other to form a ring. When n1 is 2 or more, the plurality of Ra1's may be linked to each other to form a ring. When n2 is 2 or more, the plurality of Ra2's may be linked to each other to form a ring.

As the substituents represented by Ra1, Ra2 and Ra3, an alkyl group, a cycloalkyl group, an alkoxy group, a cycloalkyloxy group, an alkoxycarbonyl group, an alkylsulfonyl group, a hydroxy group, a halogen atom, and a halogenated hydrocarbon group are preferable.

The alkyl group as Ra1 and Ra2 may be either a linear alkyl group or a branched alkyl group. As the alkyl group, those having 1 to 10 carbon atoms are preferable, and examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, and an n-decyl group. Among them, a methyl group, an ethyl group, an n-butyl group, and a t-butyl group are particularly preferable.

Examples of the cycloalkyl group as Ra1 and Ra2 include monocyclic or polycyclic cycloalkyl groups (preferably cycloalkyl groups having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among them, a cyclopropyl group, a cyclopentyl group, a cyclohexyl group, a cycloheptyl group, and a cyclooctyl group are particularly preferable.

Examples of the alkyl group moiety of the alkoxy group as Ra1 and Ra2 include those listed above as the alkyl group as Ra1 and Ra2. As the alkoxy group, a methoxy group, an ethoxy group, an n-propoxy group, and an n-butoxy group are particularly preferable.

Examples of the cycloalkyl group moiety of the cycloalkyloxy group as Ra1 and Ra2 include those listed above as the cycloalkyl group as Ra1 and Ra2. As the cycloalkyloxy group, a cyclopentyloxy group and a cyclohexyloxy group are particularly preferable.

Examples of the alkoxy group moiety of the alkoxycarbonyl group as Ra1 and Ra2 include those listed above as the alkoxy group as Ra1 and Ra2. As the alkoxycarbonyl group, a methoxycarbonyl group, an ethoxycarbonyl group, and an n-butoxycarbonyl group are particularly preferable. Examples of the alkyl group moiety of the alkylsulfonyl group as Ra1 and Ra2 include those listed above as the alkyl group as Ra1 and Ra2. Examples of the cycloalkyl group moiety of the cycloalkylsulfonyl group as Ra1 and Ra2 include those listed above as the cycloalkyl group as Ra1 and Ra2. As the alkylsulfonyl group or the cycloalkylsulfonyl group, a methanesulfonyl group, an ethanesulfonyl group, an n-propanesulfonyl group, an n-butanesulfonyl group, a cyclopentanesulfonyl group, and a cyclohexanesulfonyl group are particularly preferable.

Each of the groups Ra1 and Ra2 may further have a substituent. Examples of the substituent include a halogeno group such as a fluoro group (preferably a fluoro group), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

Examples of the halogen atom (halogeno group) as Ra1 and Ra2 include a fluorine atom (fluoro group), a chlorine atom (chloro group), a bromine atom (bromo group), and an iodine atom (iodo group), and a fluoro group and an iodo group are preferable.

As the halogenated hydrocarbon group as Ra1 and Ra2, a halogenated alkyl group is preferable. Examples of the alkyl group and the halogen atom composing the halogenated alkyl group include those described above. Among them, a fluorinated alkyl group is preferable, and CF₃ is more preferable.

As described above, Ra1 and Ra2 may be linked to each other to form a ring (namely, a heterocyclic ring containing a sulfur atom). In this case, it is preferable that Ra1 and Ra2 be bonded to each other to form a single bond or a divalent linking group. Examples of the divalent linking group include —COO—, —OCO—, —CO—, —O—, —S—, —SO—, —SO₂—, an alkylene group, a cycloalkylene group, an alkenylene group, and combinations of two or more thereof, and those having 20 or less carbon atoms in total are preferable. When Ra1 and Ra2 are linked to each other to form a ring, it is preferable that Ra1 and Ra2 be bonded to each other to form —COO—, —OCO—, —CO—, —O—, —S—, —SO—, —SO₂—, or a single bond. Among them, it is more preferable to form —O—, —S—, or a single bond, and it is particularly preferable to form a single bond. When n1 is 2 or more, the plurality of Ra1's may be linked to each other to form a ring, and when n2 is 2 or more, the plurality of Ra2's may be linked to each other to form a ring. Examples thereof include an aspect in which two Ra1's are linked to each other to form a naphthalene ring together with a benzene ring to which two Ra1's are bonded.

Ra3 is preferably a fluoro group or a group having one or more fluoro groups. Examples of the group having a fluoro group may include groups in which the alkyl group, the cycloalkyl group, the alkoxy group, the cycloalkyloxy group, the alkoxycarbonyl group, and the alkylsulfonyl group as Ra1 and Ra2 are each substituted with a fluoro group. Among them, fluorinated alkyl groups are suitable, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ are more suitable, and CF₃ is particularly suitable.

Ra3 is preferably a fluoro group or CF₃, and more preferably a fluoro group.

n1 and n2 are each independently preferably an integer of 0 to 3, and more preferably an integer of 0 to 2.

n3 is preferably an integer of 1 to 3, and more preferably 1 or 2.

(n1+n2+n3) is preferably an integer of 1 to 15, more preferably an integer of 1 to 9, still more preferably an integer of 2 to 6, and particularly preferably an integer of 3 to 6. When (n1+n2+n3) is 1, it is preferable that n3=1, and Ra3 be a fluoro group or CF₃. When (n1+n2+n3) is 2, a combination in which n1=n3=1, and Ra1 and Ra3 are each independently a fluoro group or CF₃, and a combination in which n3=2, and Ra3 is a fluoro group or CF₃ are preferable. When (n1+n2+n3) is 3, a combination in which n1=n2=n3=1, and Ra1 to Ra3 are each independently a fluoro group or CF₃ is preferable. When (n1+n2+n3) is 4, a combination in which n1=n3=2, and Ra1 and Ra3 are each independently a fluoro group or CF₃ is preferable. When (n1+n2+n3) is 5, a combination in which n1=n2=1 and n3=3, and Ra1 to Ra3 are each independently a fluoro group or CF₃, a combination in which n1=n2=2 and n3=1, and Ra1 to Ra3 are each independently a fluoro group or CF₃, and a combination in which n3=5, and Ra3s are each independently a fluoro group or CF₃ are preferable. When (n1+n2+n3) is 6, a combination in which n1=n2=n3=2, and Ra1 to Ra3 are each independently a fluoro group or CF₃ is preferable.

Examples of such an onium cation represented by the above formula (Q-1) include those shown below. The iodo group or the fluoro group in the following onium cations may be replaced by a hydrogen atom or another substituent.

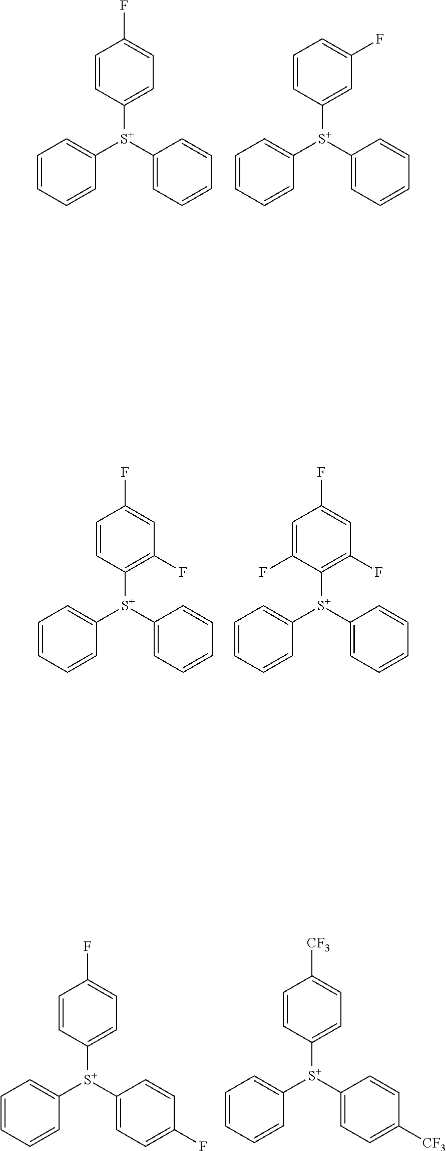 [SMILES: Fc1ccc([S+](c2ccccc2)c2ccccc2)cc1 ; Fc1cccc([S+](c2ccccc2)c2ccccc2)c1 ; Fc1ccc([S+](c2ccccc2)c2ccccc2)c(F)c1 ; Fc1cc(F)c([S+](c2ccccc2)c2ccccc2)c(F)c1 ; Fc1ccc([S+](c2ccccc2)c2ccc(F)cc2)cc1 ; FC(F)(F)c1ccc([S+](c2ccccc2)c2ccc(C(F)(F)F)cc2)cc1]

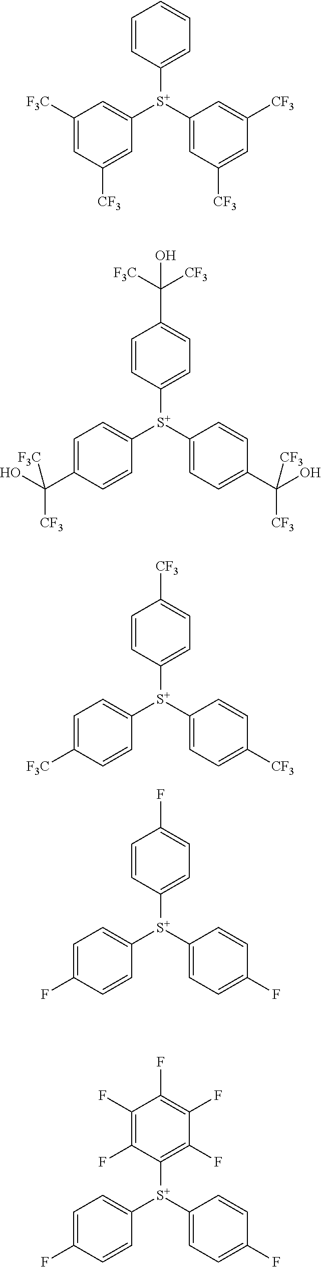 [SMILES: FC(F)(F)c1cc([S+](c2ccccc2)c2cc(C(F)(F)F)cc(C(F)(F)F)c2)cc(C(F)(F)F)c1 ; OC(c1ccc([S+](c2ccc(C(O)(C(F)(F)F)C(F)(F)F)cc2)c2ccc(C(O)(C(F)(F)F)C(F)(F)F)cc2)cc1)(C(F)(F)F)C(F)(F)F ; FC(F)(F)c1ccc([S+](c2ccc(C(F)(F)F)cc2)c2ccc(C(F)(F)F)cc2)cc1 ; Fc1ccc([S+](c2ccc(F)cc2)c2ccc(F)cc2)cc1 ; Fc1ccc([S+](c2ccc(F)cc2)c2c(F)c(F)c(F)c(F)c2F)cc1]

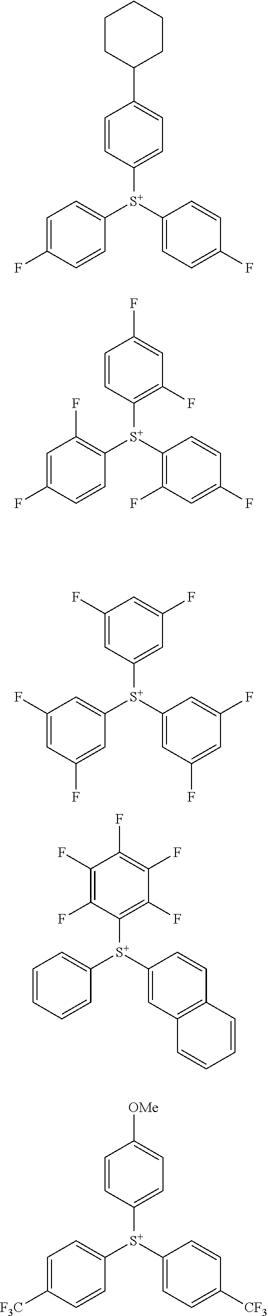 [SMILES: Fc1ccc([S+](c2ccc(F)cc2)c2ccc(C3CCCCC3)cc2)cc1 ; Fc1ccc([S+](c2ccc(F)cc2F)c2ccc(F)cc2F)c(F)c1 ; Fc1cc(F)cc([S+](c2cc(F)cc(F)c2)c2cc(F)cc(F)c2)c1 ; Fc1c(F)c(F)c([S+](c2ccccc2)c2ccc3ccccc3c2)c(F)c1F ; COc1ccc([S+](c2ccc(C(F)(F)F)cc2)c2ccc(C(F)(F)F)cc2)cc1]

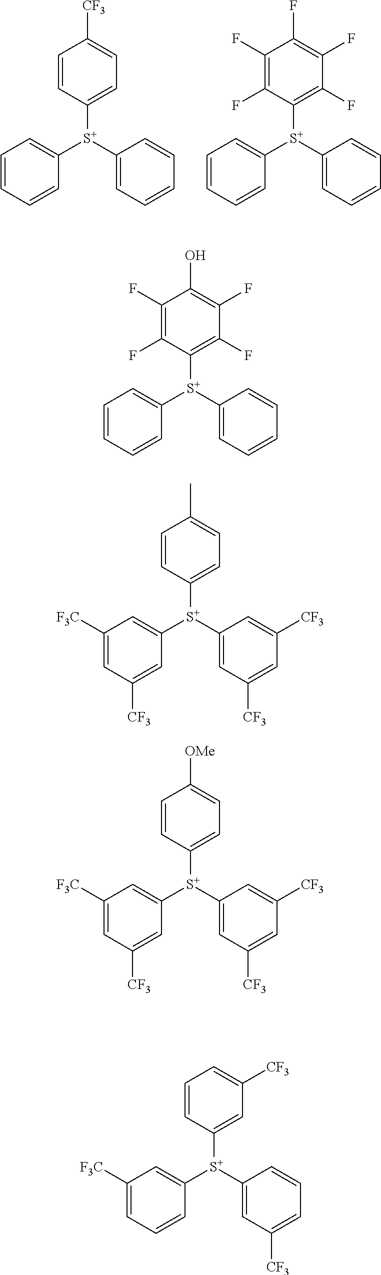 [SMILES: FC(F)(F)c1ccc([S+](c2ccccc2)c2ccccc2)cc1 ; Fc1c(F)c(F)c([S+](c2ccccc2)c2ccccc2)c(F)c1F ; Oc1c(F)c(F)c([S+](c2ccccc2)c2ccccc2)c(F)c1F ; Cc1ccc([S+](c2cc(C(F)(F)F)cc(C(F)(F)F)c2)c2cc(C(F)(F)F)cc(C(F)(F)F)c2)cc1 ; COc1ccc([S+](c2cc(C(F)(F)F)cc(C(F)(F)F)c2)c2cc(C(F)(F)F)cc(C(F)(F)F)c2)cc1 ; FC(F)(F)c1cccc([S+](c2cccc(C(F)(F)F)c2)c2cccc(C(F)(F)F)c2)c1]

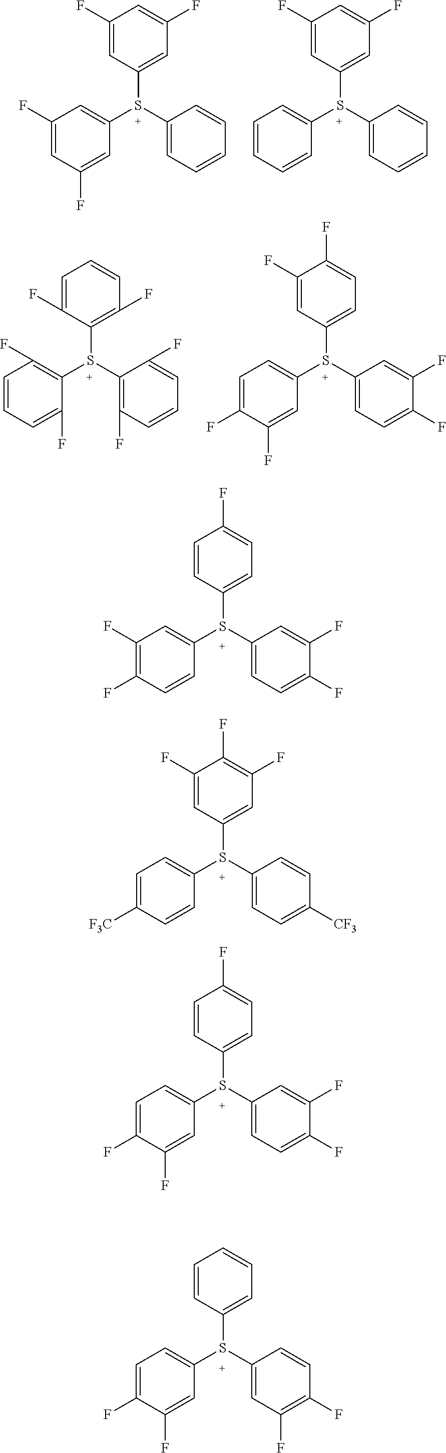

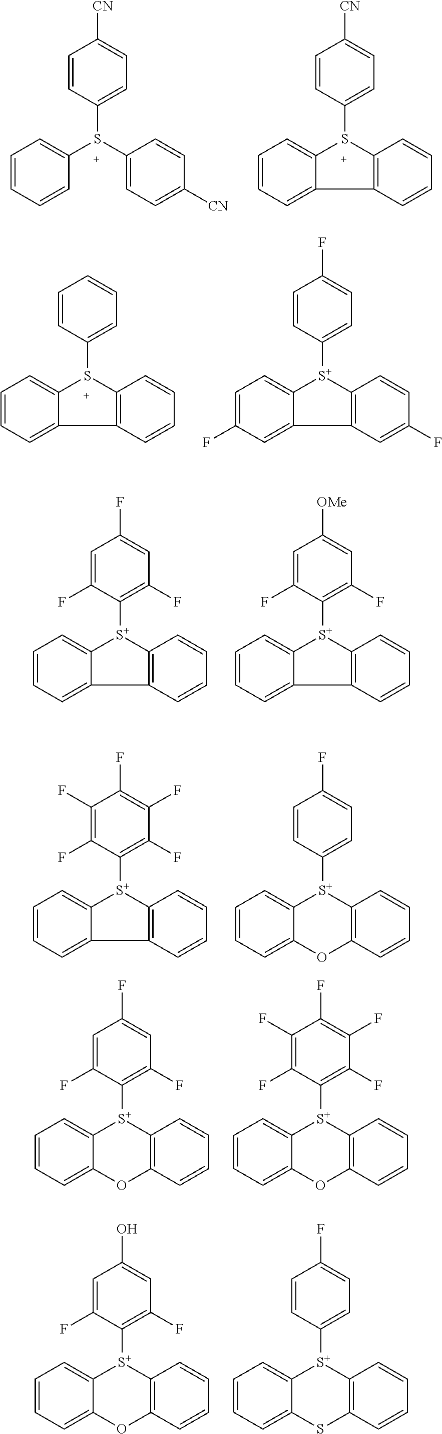

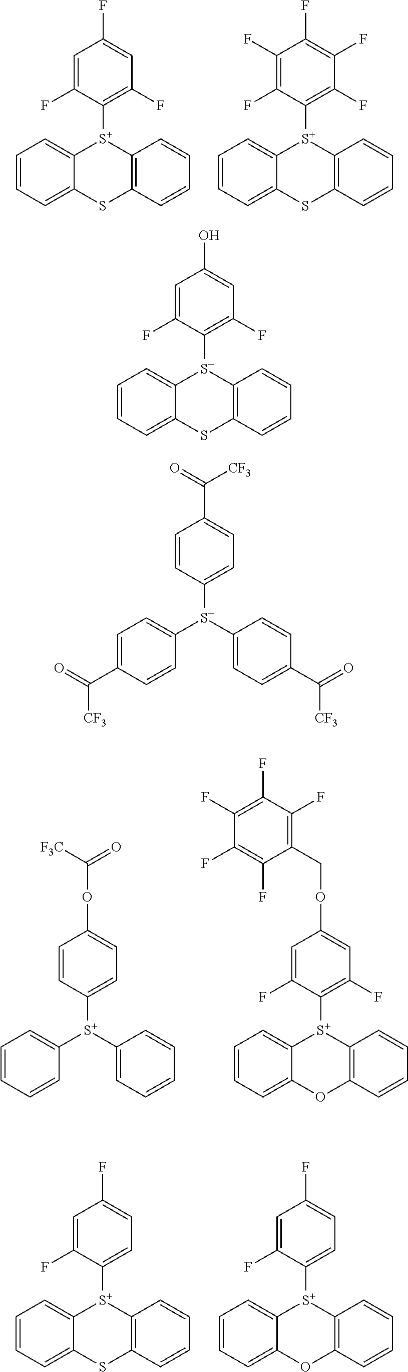

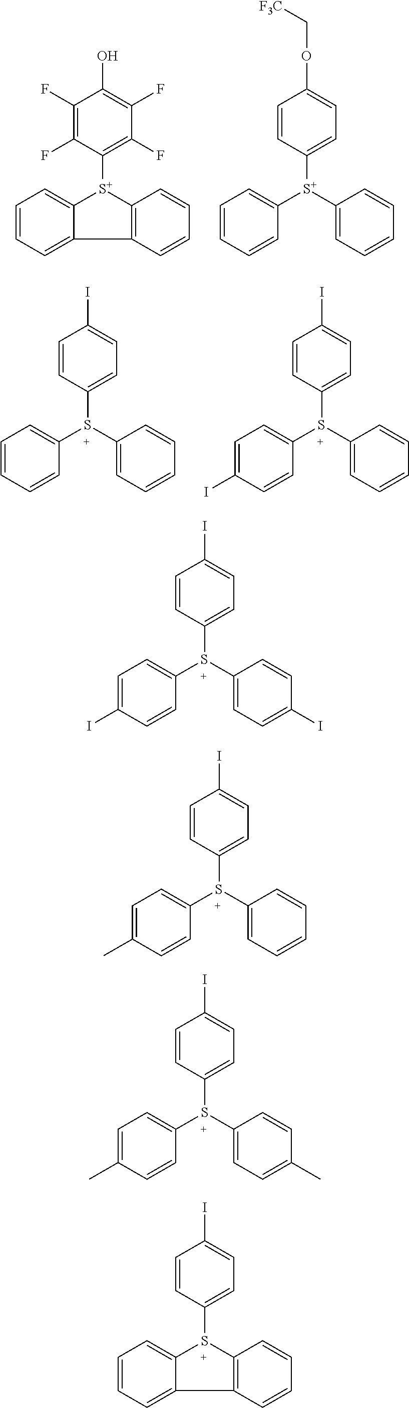

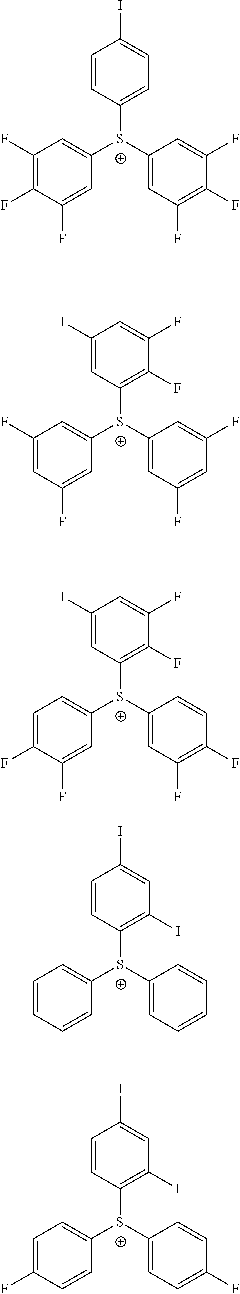 [SMILES: Fc1cc([S+](c2ccc(I)cc2)c2cc(F)c(F)c(F)c2)cc(F)c1F ; Fc1cc(F)cc([S+](c2cc(F)cc(F)c2)c2cc(I)cc(F)c2F)c1 ; Fc1ccc([S+](c2ccc(F)c(F)c2)c2cc(I)cc(F)c2F)cc1F ; Ic1ccc([S+](c2ccccc2)c2ccccc2)c(I)c1 ; Fc1ccc([S+](c2ccc(F)cc2)c2ccc(I)cc2I)cc1]

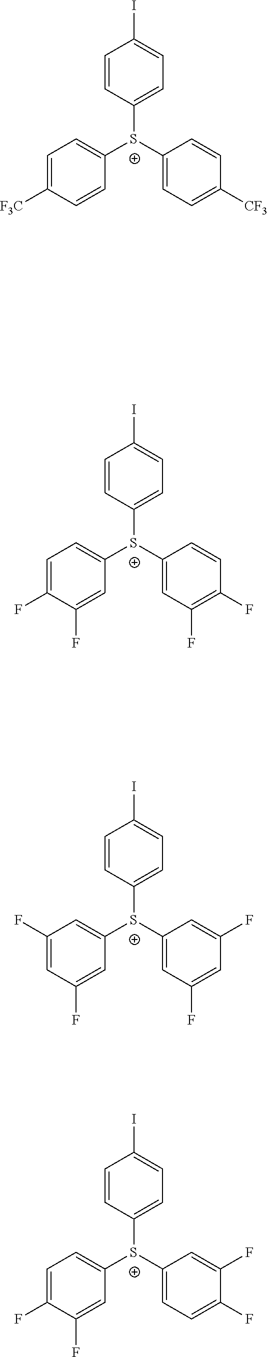 [SMILES: FC(F)(F)c1ccc([S+](c2ccc(I)cc2)c2ccc(C(F)(F)F)cc2)cc1 ; Fc1ccc([S+](c2ccc(I)cc2)c2ccc(F)c(F)c2)cc1F ; Fc1cc(F)cc([S+](c2ccc(I)cc2)c2cc(F)cc(F)c2)c1 ; Fc1ccc([S+](c2ccc(I)cc2)c2ccc(F)c(F)c2)cc1F]

When the first onium cation is an iodonium cation, the iodonium cation is preferably a diaryliodonium cation. The diaryliodonium cation more preferably has one or more fluoro groups or iodo groups.

The radiation-sensitive acid generator represented by the above formula (G-1) can also be synthesized by a publicly known method, particularly by a salt exchange reaction. A publicly known radiation-sensitive acid generator may also be used as long as the effects of the present disclosure are not impaired.

These radiation-sensitive acid generators may be used singly, or two or more thereof may be used in combination. The lower limit of the content of the radiation-sensitive acid generator (the total content is used in the case of a plurality of radiation-sensitive acid generators) is preferably 10 parts by mass, more preferably 20 parts by mass, and still more preferably 25 parts by mass based on 100 parts by mass of the base polymer. The upper limit of the content is preferably 100 parts by mass, more preferably 90 parts by mass, and still more preferably 80 parts by mass. When the base polymer contains the structural unit (VII), the lower limit of the content of the radiation-sensitive acid generator (the total content is used in the case of a plurality of radiation-sensitive acid generators) is preferably 2 parts by mass, more preferably 5 parts by mass, and still more preferably 8 parts by mass based on 100 parts by mass of the base polymer. The upper limit of the content is preferably 30 parts by mass, more preferably 20 parts by mass, and still more preferably 15 parts by mass. As a result, superior sensitivity, CDU performance, and LWR performance can be exhibited in resist pattern formation.

### <Acid Diffusion Controlling Agent>

The acid diffusion controlling agent contains a second organic acid anion and a second onium cation, and generates an acid having a higher pKa than that of an acid generated from the radiation-sensitive acid generator through irradiation with radiation. The acid diffusion controlling agent has a function of suppressing, by salt exchange, the diffusion of an acid generated from the radiation-sensitive acid generator in the unexposed portion without substantially dissociating the acid-dissociable group of the base polymer under a pattern forming condition using the radiation-sensitive composition.

When the radiation-sensitive composition contains the acid diffusion controlling agent, the diffusion of an acid in the unexposed portion can be suppressed, and a resist pattern excellent in CDU and LWR performances can be formed.

Although the structure of the second organic acid anion is not specified, it is preferable to include —O—, —CO—, a cyclic structure, or a combination thereof. As the cyclic structure, a cyclic structure in the radiation-sensitive acid generator can be suitably employed.

The second organic acid anion preferably contains the iodo group-containing aromatic ring structure.

In the acid diffusion controlling agent, the second organic anion preferably has a sulfonate anion or a carboxylate anion as the acid anion moiety (provided that when the second organic acid anion has the sulfonate anion, neither a fluorine atom nor a fluorinated hydrocarbon group is bonded to a carbon atom adjacent to a sulfur atom of the sulfonate anion). As a result, the acid diffusion controlling agent can efficiently exhibit the above function.

Examples of the acid diffusion controlling agent include a sulfonium salt compound represented by the following formula (8-1) and an iodonium salt compound represented by the following formula (8-2). In addition, examples thereof include a compound containing a sulfonium cation and an anion in the same molecule represented by the following formula (8-3) and a compound containing an iodonium cation and an anion in the same molecule represented by the following formula (8-4).

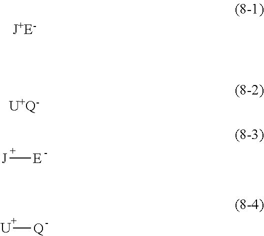

In the above formulas (8-1) to (8-4), J⁺ is a sulfonium cation, and U⁺ is an iodonium cation. E⁻ and Q⁻ are each independently the second organic acid anion represented by OH⁻, R^{α}—COO⁻, or R^{α}—SO₃⁻. In the formulas (8-1) to (8-2), R^{α} is a monovalent organic group having 1 to 30 carbon atoms. In the formulas (8-3) to (8-4), R^{α} is a single bond or a divalent organic group having 1 to 30 carbon atoms. Examples of the organic group include a monovalent hydrocarbon group having 1 to 20 carbon atoms, a group having a divalent hetero atom-containing group between carbon and carbon or at a carbon chain end of the hydrocarbon group, a group obtained by substituting some or all of hydrogen atoms of the hydrocarbon group with a monovalent hetero atom-containing group, or a combination thereof.

As the monovalent hydrocarbon group having 1 to 20 carbon atoms in the organic group, a monovalent hydrocarbon group having 1 to 20 carbon atoms represented by R¹⁸ of the formula (3) can be suitably employed. As the divalent heteroatom-containing group and the monovalent heteroatom-containing group, the divalent heteroatom-containing group and the monovalent heteroatom-containing group in the radiation-sensitive acid generator can be suitably employed.

Examples of the second organic acid anion of the acid diffusion controlling agent include, but are not limited to, those shown below. A compound containing an iodonium cation and an anion in the same molecule and a compound containing a sulfonium cation and an anion in the same molecule are also exemplified. As the organic acid anion having no iodo group-containing aromatic ring structure, a structure in which an iodo group in the following formula is substituted with an atom or a group other than the iodo group such as a hydrogen atom or another substituent can be suitably employed.

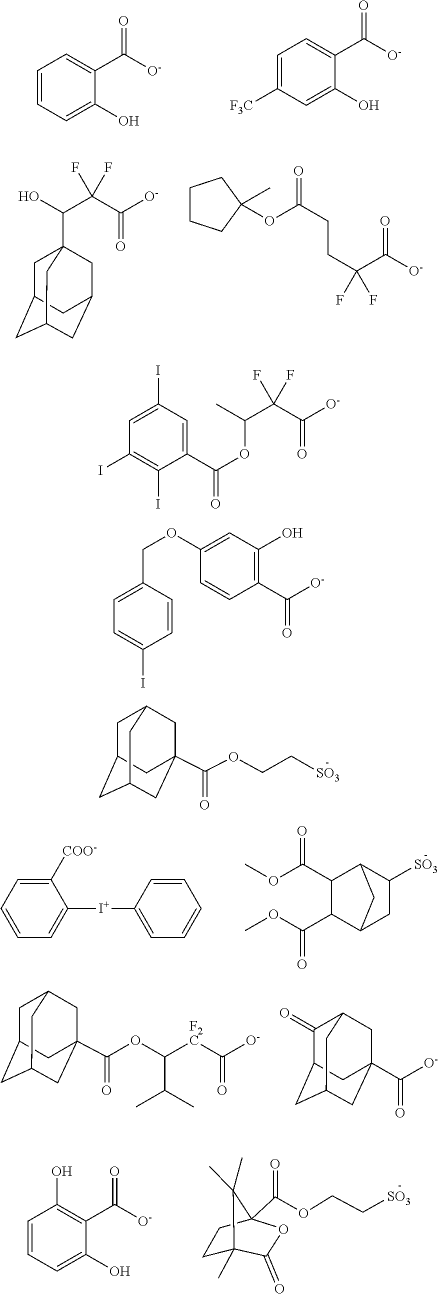

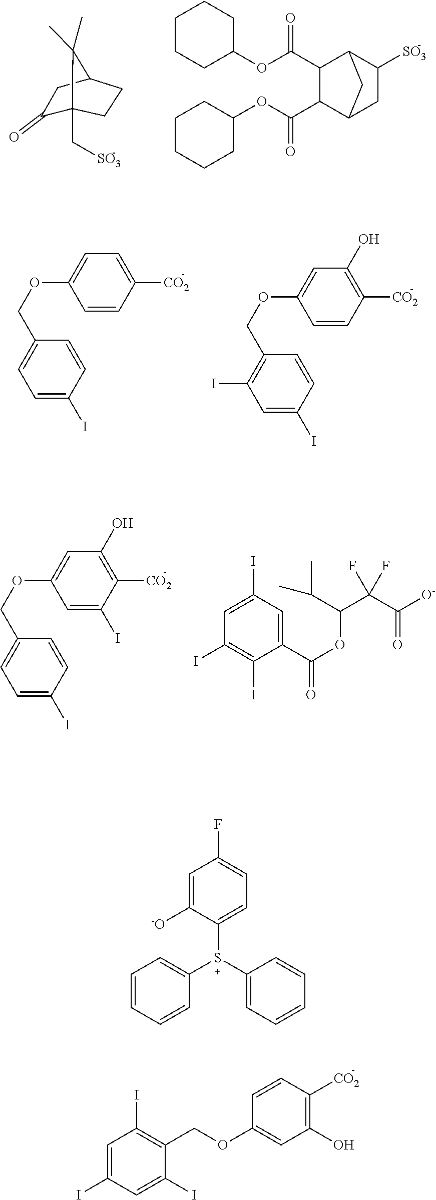

The second onium cation is preferably a sulfonium cation or an iodonium cation, and more preferably a sulfonium cation.

It is preferable that the second onium cations each independently contain at least one of a fluoro group and an iodo group. The second onium cation more preferably contains the fluoro group-containing aromatic ring structure as an aspect containing a fluoro group. The second onium cation more preferably contains the iodo group-containing aromatic ring structure as an aspect of containing an iodo group.

As the second onium cation in the acid diffusion controlling agent, the first onium cation in the radiation-sensitive acid generator can be suitably employed.

When the second onium cation is an iodonium cation, the iodonium cation is preferably a diaryliodonium cation. The diaryliodonium cation more preferably has one or more fluoro groups.

The acid diffusion controlling agents can also be synthesized by a publicly known method, particularly by a salt exchange reaction. A publicly known acid diffusion controlling agent may be used as long as the effects of the present disclosure are not impaired.

These acid diffusion controlling agents may be used singly, or two or more thereof may be used in combination. The lower limit of the content of the acid diffusion controlling agent (the total content is used in the case of a plurality of acid diffusion controlling agents) is preferably 2 parts by mass, more preferably 5 parts by mass, and still more preferably 8 parts by mass based on 100 parts by mass of the base polymer. The upper limit of the content is preferably 40 parts by mass, more preferably 30 parts by mass, and still more preferably 25 parts by mass. When the base polymer contains the structural unit (VIII), the composition may not contain the acid diffusion controlling agent. As a result, superior sensitivity, CDU performance, and LWR performance can be exhibited in resist pattern formation.

### <Solvent>

The radiation-sensitive composition according to the present embodiment contains a solvent. The solvent is not particularly limited as long as the solvent is one capable of dissolving or dispersing the base polymer, the radiation-sensitive acid generator, the acid diffusion controlling agent, and additives or the like contained as desired.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
monoalcohol-based solvents having 1 to 18 carbon atoms, such as iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
polyhydric alcohol-based solvents having 2 to 18 carbon atoms, such as ethylene glycol, 1,2-propylene glycol, 2-methyl-2,4-pentanediol, 2,5-hexanediol, diethylene glycol, dipropylene glycol, triethylene glycol, and tripropylene glycol; and
partially etherized polyhydric alcohol-based solvents obtained by etherifying some of hydroxy groups of the polyhydric alcohol-based solvent.

In the present embodiment, alcohol acid ester-based solvents such as methyl lactate, ethyl lactate, propyl lactate, butyl lactate, methyl 2-hydroxyisobutyrate, i-propyl 2-hydroxyisobutyrate, i-butyl 2-hydroxyisobutyrate, and n-butyl 2-hydroxyisobutyrate are also included in the alcohol-based solvent.

Examples of the ether-based solvent include:
dialkyl ether-based solvents, such as diethyl ether, dipropyl ether, and dibutyl ether;
cyclic ether-based solvents, such as tetrahydrofuran and tetrahydropyran;
aromatic ring-containing ether-based solvents, such as diphenyl ether and anisole (methyl phenyl ether); and
etherized polyhydric alcohol-based solvents obtained by etherifying a hydroxy group of the polyhydric alcohol-based solvent.

Examples of the ketone-based solvent include chain ketone-based solvents, such as acetone, butanone, and methyl-iso-butyl ketone;
cyclic ketone-based solvents, such as cyclopentanone, cyclohexanone, and methylcyclohexanone; and
2,4-pentanedione, acetonylacetone, and acetophenone.

Examples of the amide-based solvent include cyclic amide-based solvents, such as N,N′-dimethylimidazolidinone and N-methylpyrrolidone; and
chain amide-based solvents, such as N-methylformamide, N,N-dimethylformamide, N,N-diethylformamide, acetamide, N-methylacetamide, N,N-dimethylacetamide, and N-methylpropionamide.

Examples of the ester-based solvent include:
monocarboxylic acid ester-based solvents, such as n-butyl acetate;
partially etherized polyhydric alcohol acetate-based solvents, such as diethylene glycol mono-n-butyl ether acetate, propylene glycol monomethyl ether acetate, and dipropylene glycol monomethyl ether acetate;
lactone-based solvents, such as γ-butyrolactone and valerolactone;
carbonate-based solvents, such as diethyl carbonate, ethylene carbonate, and propylene carbonate; and
polyvalent carboxylic acid diester-based solvents, such as propylene glycol diacetate, methoxytriglycol acetate, diethyl oxalate, ethyl acetoacetate, and diethyl phthalate.

Examples of the hydrocarbon-based solvent include:
aliphatic hydrocarbon-based solvents, such as n-hexane, cyclohexane, and methylcyclohexane; and
aromatic hydrocarbon-based solvents, such as benzene, toluene, di-iso-propylbenzene, and n-amylnaphthalene.

Among them, an ester-based solvent, and an ether-based solvent are preferable, a partially etherized polyhydric alcohol acetate-based solvent, and a partially etherized polyhydric alcohol-based solvent are more preferable, and propylene glycol monomethyl ether acetate, and propylene glycol monomethyl ether, are still more preferable. The radiation-sensitive composition may contain one solvent, or two or more solvents.

### <Other Optional Components>

The radiation-sensitive composition may contain, in addition to the components, other optional components. Examples of other optional components may include a cross-linking agent, a localization enhancing agent, a surfactant, an alicyclic backbone-containing compound, and a sensitizer. These other optional components may be used singly, or two or more thereof may be used in combination.

### <Method for Preparing Radiation-Sensitive Composition>

The radiation-sensitive composition can be prepared, for example, by mixing the base polymer, the radiation-sensitive acid generator, acid diffusion controlling agent, and the solvent, and if necessary, the optional component at a prescribed ratio. The radiation-sensitive composition is, after the mixing, preferably filtered through, for example, a filter having a pore size of approximately 0.05 μm to 0.4 μm. The solid matter concentration of the radiation-sensitive composition is usually 0.1% by mass to 50% by mass, preferably 0.5% by mass to 30% by mass, more preferably 1% by mass to 20% by mass.

### <Pattern Forming Method>

A pattern forming method according to the present disclosure includes:
a step (1) of applying the radiation-sensitive composition directly or indirectly on a substrate to form a resist film (hereinafter also referred to as “resist film forming step”);
a step (2) of exposing the resist film to light (hereinafter also referred to as “exposure step”); and
a step (3) of developing the exposed resist film with a developer (hereinafter also referred to as “development step”).

According to the pattern forming method, the radiation-sensitive composition capable of exerting excellent sensitivity, CDU performance, and LWR performance in pattern formation is used, so that a high-quality resist pattern can be formed. Hereinbelow, each of the steps will be described.

### [Resist Film Forming Step]

In this step (the step (1)), a resist film is formed from the radiation-sensitive composition. Examples of the substrate on which the resist film is formed may include those traditionally known in the art, including a silicon wafer, silicon dioxide, and a wafer coated with aluminum. An organic or inorganic antireflective film disclosed in, for example, JP-B-6-12452 or JP-A-59-93448 may be formed on the substrate. Examples of an applicating method may include a rotary coating (spin coating), flow casting, and roll coating. After the application, prebaking (PB) may be performed to volatilize the solvent in the coating film, as necessary. The temperature of PB is usually from 60° C. to 160° C., preferably from 80° C. to 140° C. The duration of PB is usually from 5 seconds to 600 seconds, preferably from 10 seconds to 300 seconds. The thickness of the resist film formed is preferably from 10 nm to 1,000 nm, more preferably from 10 nm to 500 nm.

Furthermore, when the subsequent exposure step is carried out using radiation having a wavelength of 50 nm or less, it is preferable to use a polymer having at least one of the structural units (I) and (II) as the base polymer in the composition.

### [Exposure Step]

In this step (the step (2)), the resist film formed in the resist film forming step as the step (1) is exposed by irradiating with radiation through a photomask. Examples of the radiation to be used for the exposure may include an electromagnetic wave including visible ray, ultraviolet ray, far ultraviolet ray, extreme ultraviolet ray (EUV), X ray, and y ray; and charged particle radiation such as an electron beam and a ray. Among them, far ultraviolet ray, an electron beam, or EUV is preferable. ArF excimer laser light (wavelength is 193 nm), KrF excimer laser light (wavelength is 248 nm), an electron beam, or EUV is more preferable. An electron beam having a wavelength of 50 nm or less, which is identified as the next generation exposing technology, or EUV is further preferable.

After the exposure, post exposure bake (PEB) is preferably performed to promote the dissociation of the acid-dissociable group of the polymer by an acid generated from the radiation-sensitive acid generator through exposure to light in the exposed part of the resist film. As a result of the PEB, there is generated a difference in solubility into a developer between the exposed area and the unexposed area. The temperature of PEB is usually from 50° C. to 180° C., preferably from 80° C. to 150° C. The duration of PEB is usually from 5 seconds to 600 seconds, preferably from 10 seconds to 300 seconds.

### [Development Step]

In this step (the step (3)), the resist film exposed in the exposure step as the step (2) is developed with a developer. By this step, the predetermined resist pattern can be formed. After the development, the resist pattern is generally washed with a rinse solution such as water or alcohol, and then dried.

Examples of the developer used for the development may include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferable, and a 2.38% by mass aqueous TMAH solution is more preferable.

In the case of organic solvent development, examples of the solvent may include organic solvents such as hydrocarbon-based solvents, ether-based solvents, ester-based solvents, ketone-based solvents, and alcohol-based solvents, and solvents containing an organic solvent. Examples of the organic solvent may include one, two or more solvents listed as the solvent for the radiation-sensitive composition. Among them, ester-based solvents and ketone-based solvents are preferable. As the ester-based solvents, acetate-based solvents are preferable, and n-butyl acetate and amyl acetate are more preferable. As the ketone-based solvents, chain ketones are preferable, and 2-heptanone is more preferable. The content of the organic solvent in a developer is preferably 80% by mass or more, more preferably 90% by mass or more, still more preferably 95% by mass or more, particularly preferably 99% by mass or more. Examples of the component other than the organic solvent in the developer may include water and silicone oil.

Examples of the developing method may include a method including dipping a substrate in a tank filled with a developer for a given time (dipping method); a developing method including raising a developer on the surface of a substrate due to surface tension and leaving the raised developer for a given time (paddling method); a method including spraying a developer on the surface of a substrate (spraying method); and a method including injecting a developer on a substrate rolling at a constant rate while scanning a developer injection nozzle at a constant rate (dynamic dispensing method).

### EXAMPLES

Hereinafter, the present invention will be specifically described with reference to Examples, but the present invention is not limited to these Examples. The methods for measuring physical property values are described below.

### [Measurement of Weight Average Molecular Weight (Mw), Number Average Molecular Weight (Mn), and Dispersity (Mw/Mn)]

Measurement was conducted by gel permeation chromatography (GPC) with monodisperse polystyrene standards using GPC columns (“G2000HXL” ×2, “G3000HXL” ×1, and “G4000HXL” ×1) manufactured by Tosoh Corporation under the following analysis conditions: flow rate: 1.0 mL/min; elution solvent: tetrahydrofuran; column temperature: 40° C.

[¹H-NMR Analysis and 1³C-NMR Analysis]

Measurement was performed with use of “JNM-Delta 400” manufactured by JEOL Ltd.

### <Synthesis of Polymer>

The monomers used for the synthesis of the respective polymers in the respective Examples and Comparative Examples are shown below. In the following synthesis examples, unless otherwise specified, “parts by mass” means a value taken when the total mass of the monomers used is 100 parts by mass, and “mol %” means a value taken when the total number of moles of the monomers used is 100 mol %. In addition, the present disclosure is not limited to the following structural units.

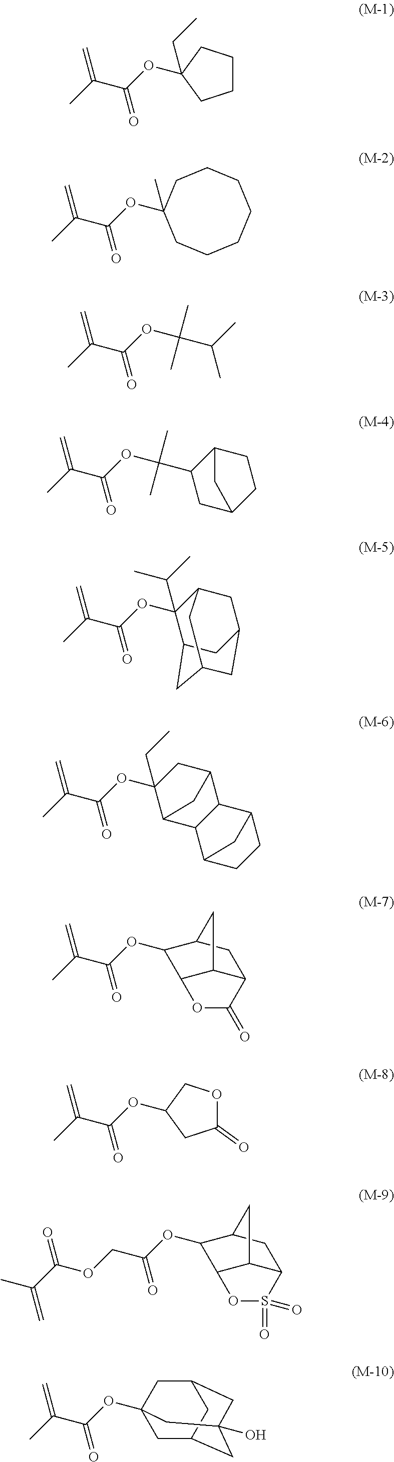

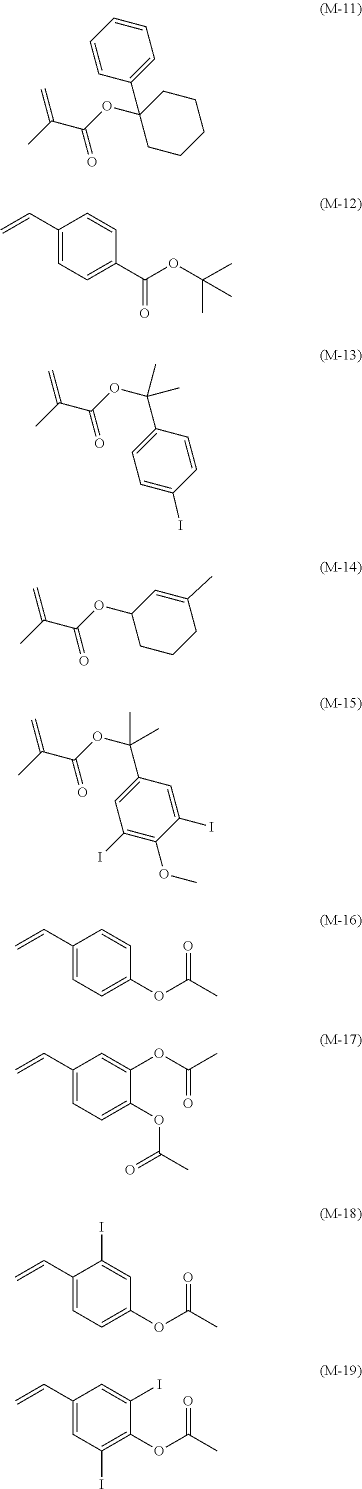

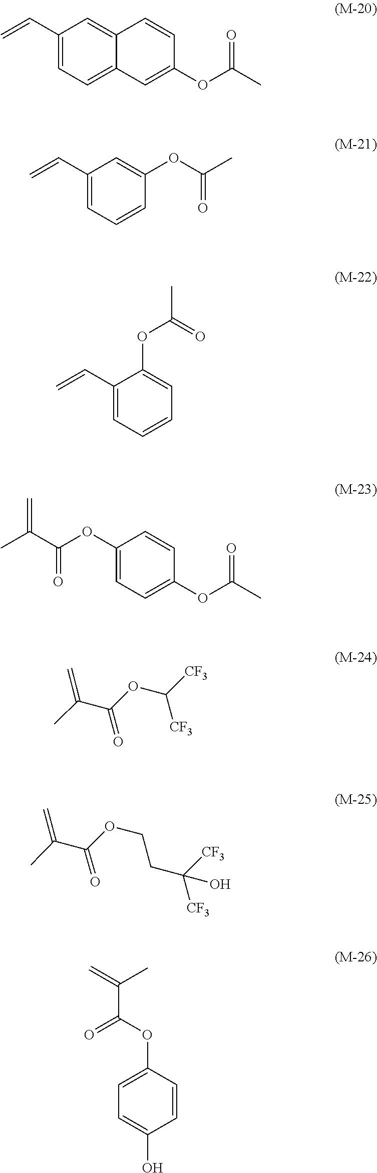

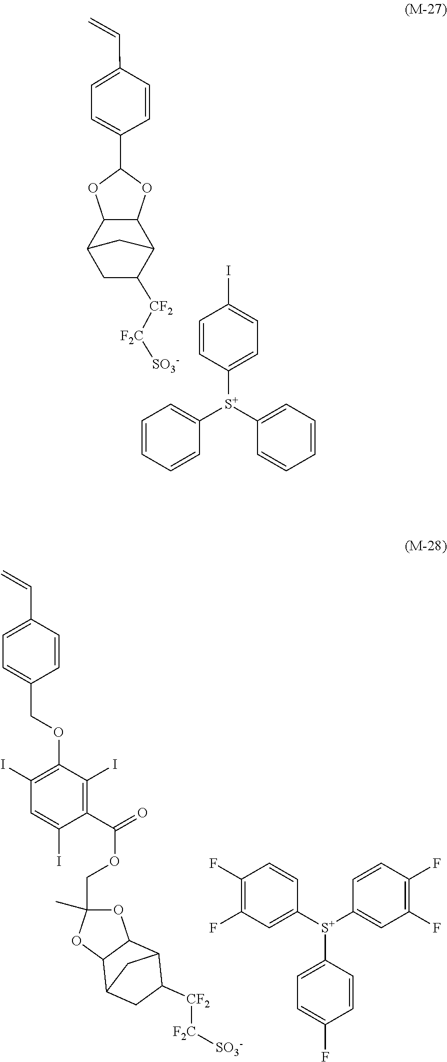

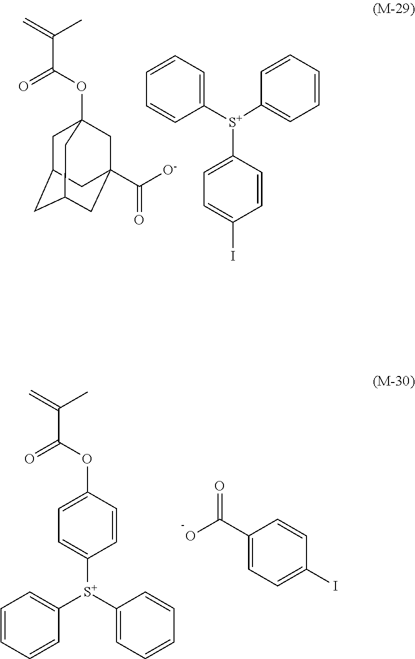

### [Method for Synthesizing Polymer]

### [Synthesis Example 1](Synthesis of Polymer (P-1))

Compound (M-1) and compound (M-16) as monomers were dissolved in 1-methoxy-2-propanol (200 parts by mass based on the total amount of the monomers) to have a molar ratio of 45/55. Next, azobisisobutyronitrile (4 mol %) was added as an initiator, and thus a monomer solution was prepared. Meanwhile, 1-methoxy-2-propanol (100 parts by mass based on the total amount of monomers) was added to an empty reaction vessel, and was heated to 85° C. with stirring. Next, the monomer solution prepared above was added dropwise over 3 hours, and then the mixture was further heated at 85° C. for 3 hours to perform a polymerization reaction for 6 hours in total. After completion of the polymerization reaction, the polymerization solution was cooled to room temperature. The cooled polymerization solution was charged into hexane (500 parts by mass with respect to the polymerization solution), and a precipitated white powder was separated by filtration. The white powder separated by filtration was washed twice with 100 parts by mass of hexane based on the polymerization solution, then separated by filtration, and dissolved in 1-methoxy-2-propanol (300 parts by mass). Next, methanol (500 parts by mass), triethylamine (50 parts by mass), and ultrapure water (10 parts by mass) were added, and a hydrolysis reaction was performed at 70° C. for 6 hours with stirring. After completion of the reaction, the remaining solvent was distilled off, and the obtained solid was dissolved in acetone (100 parts by mass). The resulting solution was added dropwise into 500 parts by mass of water to permit the coagulation of the polymer. The resulting solid was separated by filtration. The resulting solid was dried at 50° C. for 12 hours to yield a white powdery polymer (P-1). The resulting polymer (P-1) had an Mw of 5102 and an Mw/Mn of 1.57. As a result of ¹³C-NMR analysis, the content of a structural unit derived from the compound (M-1): a structural unit derived from the compound (M-16) was 43:57 (mol %).

### [Synthesis Examples 2 to 17](Synthesis of Polymers (P-2) to (P-17))

Polymers (P-2) to (P-17) in which prescribed amounts of monomers of the types shown in Table 1 were blended were obtained in the same manner as in Synthesis Example 1. The Mw, Mw/Mn, yield (%) of each of the resulting polymers, and the content ratio of the structural unit derived from each of the monomers in each of the polymers are shown together in Table 1.

### [Synthesis Example 18](Synthesis of Polymer (P-18))

Compound (M-1), compound (M-26), and compound (M-27) as monomers were dissolved in 2-butanone (200 parts by mass based on the total amount of the monomers) to have a molar ratio of 50/30/20. Azobisisobutyronitrile (AIBN) was added as an initiator in an amount of 6 mol % based on all the monomers, and thus a monomer solution was prepared. Meanwhile, 2-butanone (100 parts by mass) was added to an empty reaction vessel, and was heated to 80° C. while being stirred. Next, the monomer solution prepared above was added dropwise over 3 hours. Thereafter, the mixture was further heated at 80° C. for 3 hours. After completion of the polymerization reaction, the polymerization solution was cooled to room temperature. Acetonitrile (100 parts by mass) and hexane (600 parts by mass) were added to the obtained polymerization solution, and the mixture was stirred. After collecting the lower layer, the solvent was removed, affording polymer (P-18). The resulting polymer (P-18) had an Mw of 6201 and an Mw/Mn of 1.46. As a result of ¹³C-NMR analysis, the content of a structural unit derived from the compound (M-1): a structural unit derived from the compound (M-26): a structural unit derived from the compound (M-27) was 48:32:20 (mol %).

### [Synthesis Examples 19 to 21](Synthesis of Polymers (P-19) to (P-21))

Polymers (P-19) to (P-21) in which prescribed amounts of monomers of the types shown in Table 1 were blended were obtained in the same manner as in Synthesis Example 18. The Mw, Mw/Mn, yield (%) of each of the resulting polymers, and the content ratio of the structural unit derived from each of the monomers in each of the polymers are shown together in Table 1.

TABLE 1-1

| | | BLENDING RATIO OF MONOMER (mol %) | | | | | |
|---|---|---|---|---|---|---|---|
| | | MONOMER THAT | | MONOMER THAT | | MONOMER THAT | |
| | | AFFORDS | | AFFORDS | | AFFORDS | |
| | | STRUCTURAL | | STRUCTURAL | | STRUCTURAL | |
| | | UNIT (I) | | UNIT (II) | | UNIT (III) | |
| | | | BLENDING | | BLENDING | | BLENDING |
| | POLYMER | TYPE | RATIO | TYPE | RATIO | TYPE | RATIO |
| SYNTHESIS | P-1 | M-1 | 45 | M-16 | 55 | — | — |
| EXAMPLE 1 | | | | | | | |
| SYNTHESIS | P-2 | M-1/M-2 | 35/20 | M-16 | 45 | — | — |
| EXAMPLE 2 | | | | | | | |
| SYNTHESIS | P-3 | M-3 | 45 | M-16 | 55 | — | — |
| EXAMPLE 3 | | | | | | | |
| SYNTHESIS | P-4 | M-1/M-4 | 35/10 | M-21 | 55 | — | — |
| EXAMPLE 4 | | | | | | | |
| SYNTHESIS | P-5 | M-1/M-5 | 30/20 | M-17/M-22 | 10/40 | — | — |
| EXAMPLE 5 | | | | | | | |
| SYNTHESIS | P-6 | M-1/M-6 | 35/25 | M-22 | 50 | — | — |
| EXAMPLE 6 | | | | | | | |
| SYNTHESIS | P-7 | M-11 | 45 | M-16 | 30 | M-9 | 25 |
| EXAMPLE 7 | | | | | | | |
| SYNTHESIS | P-8 | M-1/M-12 | 35/15 | M-16 | 40 | M-7 | 10 |
| EXAMPLE 8 | | | | | | | |
| SYNTHESIS | P-9 | M-1/M-11 | 20/35 | M-16 | 35 | M-8 | 10 |
| EXAMPLE 9 | | | | | | | |
| SYNTHESIS | P-10 | M-1 | 40 | M-16 | 50 | — | — |
| EXAMPLE 10 | | | | | | | |
| SYNTHESIS | P-11 | M-11 | 35 | M-22 | 65 | — | — |
| EXAMPLE 11 | | | | | | | |
| SYNTHESIS | P-12 | M-1/M-13 | 30/25 | M-16 | 45 | — | — |
| EXAMPLE 12 | | | | | | | |
| SYNTHESIS | P-13 | M-13 | 55 | M-21/M-23 | 35/10 | — | — |
| EXAMPLE 13 | | | | | | | |
| SYNTHESIS | P-14 | M-1M-13 | 35/15 | M-16/M-20 | 40/10 | — | — |
| EXAMPLE 14 | | | | | | | |
| SYNTHESIS | P-15 | M-14/M-15 | 40/10 | M-16 | 50 | — | — |
| EXAMPLE 15 | | | | | | | |
| SYNTHESIS | P-16 | M-13/M-14 | 35/25 | M-16/M-18 | 30/10 | — | — |
| EXAMPLE 16 | | | | | | | |
| SYNTHESIS | P-17 | M-1/M-14 | 20/40 | M-16/M-19 | 30/10 | — | — |
| EXAMPLE 17 | | | | | | | |
| SYNTHESIS | P-18 | M-1 | 50 | M-26 | 30 | — | — |
| EXAMPLE 18 | | | | | | | |
| SYNTHESIS | P-19 | M-1 | 50 | M-26 | 30 | — | — |
| EXAMPLE 19 | | | | | | | |
| SYNTHESIS | P-20 | M-1 | 50 | M-26 | 30 | — | — |
| EXAMPLE 20 | | | | | | | |
| SYNTHESIS | P-21 | M-1 | 50 | M-26 | 30 | — | — |
| EXAMPLE 21 | | | | | | | |

| | BLENDING RATIO OF MONOMER (mol %) | | | | | |
|---|---|---|---|---|---|---|
| | MONOMER THAT | | MONOMER THAT | | MONOMER THAT | |
| | AFFORDS | | AFFORDS | | AFFORDS | |
| | STRUCTURAL | | STRUCTURAL | | STRUCTURAL | |
| | UNIT (IV) | | UNIT (VII) | | UNIT (VIII) | |
| | | BLENDING | | BLENDING | | BLENDING |
| | TYPE | RATIO | TYPE | RATIO | TYPE | RATIO |
| SYNTHESIS | — | — | — | — | — | — |
| EXAMPLE 1 | | | | | | |
| SYNTHESIS | — | — | — | — | — | — |
| EXAMPLE 2 | | | | | | |
| SYNTHESIS | — | — | — | — | — | — |
| EXAMPLE 3 | | | | | | |
| SYNTHESIS | — | — | — | — | — | — |
| EXAMPLE 4 | | | | | | |
| SYNTHESIS | — | — | — | — | — | — |
| EXAMPLE 5 | | | | | | |
| SYNTHESIS | — | — | — | — | — | — |
| EXAMPLE 6 | | | | | | |
| SYNTHESIS | — | — | — | — | — | — |
| EXAMPLE 7 | | | | | | |
| SYNTHESIS | — | — | — | — | — | — |
| EXAMPLE 8 | | | | | | |
| SYNTHESIS | — | — | — | — | — | — |
| EXAMPLE 9 | | | | | | |
| SYNTHESIS | M-10 | 10 | — | — | — | — |
| EXAMPLE 10 | | | | | | |
| SYNTHESIS | — | — | — | — | — | — |
| EXAMPLE 11 | | | | | | |
| SYNTHESIS | — | — | — | — | — | — |
| EXAMPLE 12 | | | | | | |
| SYNTHESIS | — | — | — | — | — | — |
| EXAMPLE 13 | | | | | | |
| SYNTHESIS | — | — | — | — | — | — |
| EXAMPLE 14 | | | | | | |
| SYNTHESIS | — | — | — | — | — | — |
| EXAMPLE 15 | | | | | | |
| SYNTHESIS | — | — | — | — | — | — |
| EXAMPLE 16 | | | | | | |
| SYNTHESIS | — | — | — | — | — | — |
| EXAMPLE 17 | | | | | | |
| SYNTHESIS | — | — | M-27 | 20 | — | — |
| EXAMPLE 18 | | | | | | |
| SYNTHESIS | — | — | M-28 | 20 | — | — |
| EXAMPLE 19 | | | | | | |
| SYNTHESIS | — | — | — | — | M-29 | 20 |
| EXAMPLE 20 | | | | | | |
| SYNTHESIS | — | — | — | — | M-30 | 20 |
| EXAMPLE 21 | | | | | | |

TABLE 1-2

| | | CONTENT RATIO OF EACH STRUCTURAL UNIT (mol %) | | | | | | | | |
|---|---|---|---|---|---|---|---|---|---|---|
| | | STRUC- | STRUC- | STRUC- | STRUC- | STRUC- | STRUC- | | PHYSICAL | |
| | | TURAL | TURAL | TURAL | TURAL | TURAL | TURAL | | PROPERTY VALUE | |
| | | UNIT | UNIT | UNIT | UNIT | UNIT | UNIT | YIELD | | Mw/ |
| | POLYMER | (I) | (II) | (III) | (IV) | (VII) | (VIII) | (%) | Mw | Mn |
| SYNTHESIS | P-1 | 43 | 57 | — | — | — | — | 67 | 5102 | 1.57 |
| EXAMPLE 1 | | | | | | | | | | |
| SYNTHESIS | P-2 | 34/18 | 48 | — | — | — | — | 66 | 5086 | 1.56 |
| EXAMPLE 2 | | | | | | | | | | |
| SYNTHESIS | P-3 | 43 | 57 | — | — | — | — | 65 | 5183 | 1.65 |
| EXAMPLE 3 | | | | | | | | | | |
| SYNTHESIS | P-4 | 34/9 | 57 | — | — | — | — | 69 | 5251 | 1.40 |
| EXAMPLE 4 | | | | | | | | | | |
| SYNTHESIS | P-5 | 29/17 | 11/43 | — | | — | — | 65 | 4908 | 1.46 |
| EXAMPLE 5 | | | | | | | | | | |
| SYNTHESIS | P-6 | 34/24 | 52 | — | — | — | — | 78 | 5034 | 1.30 |
| EXAMPLE 6 | | | | | | | | | | |
| SYNTHESIS | P-7 | 42 | 31 | 27 | — | — | — | 79 | 5008 | 1.53 |
| EXAMPLE 7 | | | | | | | | | | |
| SYNTHESIS | P-8 | 33/16 | 41 | 10 | — | — | — | 74 | 5011 | 1.52 |
| EXAMPLE 8 | | | | | | | | | | |
| SYNTHESIS | P-9 | 19/33 | 38 | 10 | — | — | — | 65 | 4883 | 1.38 |
| EXAMPLE 9 | | | | | | | | | | |
| SYNTHESIS | P-10 | 39 | 51 | — | 10 | — | — | 66 | 4825 | 1.35 |
| EXAMPLE 10 | | | | | | | | | | |
| SYNTHESIS | P-11 | 34 | 66 | — | — | — | — | 68 | 5033 | 1.31 |
| EXAMPLE 11 | | | | | | | | | | |
| SYNTHESIS | P-12 | 29/25 | 46 | — | — | — | — | 70 | 4742 | 1.28 |
| EXAMPLE 12 | | | | | | | | | | |
| SYNTHESIS | P-13 | 55 | 34/11 | — | — | — | — | 71 | 5083 | 1.31 |
| EXAMPLE 13 | | | | | | | | | | |
| SYNTHESIS | P-14 | 34/15 | 41/10 | — | — | — | — | 65 | 4900 | 1.32 |
| EXAMPLE 14 | | | | | | | | | | |
| SYNTHESIS | P-15 | 40/9 | 51 | — | — | — | — | 66 | 4808 | 1.38 |
| EXAMPLE 15 | | | | | | | | | | |
| SYNTHESIS | P-16 | 34/25 | 32/9 | — | — | — | — | 69 | 4933 | 1.37 |
| EXAMPLE 16 | | | | | | | | | | |
| SYNTHESIS | P-17 | 19/29 | 30/13 | — | — | — | — | 71 | 5258 | 1.45 |
| EXAMPLE 17 | | | | | | | | | | |
| SYNTHESIS | P-18 | 48 | 32 | — | — | 20 | — | 61 | 6201 | 1.46 |
| EXAMPLE 18 | | | | | | | | | | |
| SYNTHESIS | P-19 | 47 | 32 | — | — | 21 | — | 63 | 6432 | 1.48 |
| EXAMPLE 19 | | | | | | | | | | |
| SYNTHESIS | P-20 | 49 | 31 | — | — | — | 20 | 61 | 6485 | 1.49 |
| EXAMPLE 20 | | | | | | | | | | |
| SYNTHESIS | P-21 | 48 | 32 | — | — | — | 20 | 64 | 6146 | 1.44 |
| EXAMPLE 21 | | | | | | | | | | |

### [Synthesis of High Fluorine-Content Polymer]

### [Synthesis Example 22](Synthesis of Polymer (E-1))

Compounds (M-24) and (M-25) as monomers were dissolved in 2-butanone (200 parts by mass) to have a molar ratio of 10/90. Next, AIBN (5 mol % based on all monomers) as an initiator was added hereto, and thus a monomer solution was prepared. 2-Butanone (100 parts by mass) was placed in a reaction vessel, and purged with nitrogen for 30 minutes. The temperature in the reaction vessel was adjusted to 80° C., and the monomer solution was added dropwise thereto over 3 hours with stirring. A polymerization reaction was performed for 6 hours with the start of the dropwise addition regarded as the start time of the polymerization reaction. After the completion of the polymerization reaction, the polymerization solution was cooled with water to 30° C. or lower. The solvent was replaced with acetonitrile (400 parts by mass). Hexane (100 parts by mass) was then added, followed by stirring, and an acetonitrile layer was collected. The operation was repeated three times. By replacing the solvent with propylene glycol monomethyl ether acetate, a solution of polymer (E-1) was obtained in a good yield. As a result of ¹³C-NMR analysis, the content of a structural unit derived from the compound (M-24): a structural unit derived from the compound (M-25) was 9:91 (mol %).

### [Synthesis Example 23](Synthesis of Polymer (E-2))

Polymer (E-2) in which prescribed amounts of monomers of the types shown in Table 2 were blended was obtained in the same manner as in Synthesis Example 22. The Mw, Mw/Mn, yield (%) of each of the resulting polymers, and the content of the structural unit derived from each of the monomers in each of the polymers are shown together in Table 2.

TABLE 2

| | | BLENDING RATIO OF MONOMER (mol %) | | | | | | | | | | | |
|---|---|---|---|---|---|---|---|---|---|---|---|---|---|
| | | MONOMER THAT | | MONOMER THAT | | MONOMER THAT | | CONTENT RATIO OF | | | | | |
| | | AFFORDS | | AFFORDS | | AFFORDS | | EACH STRUCTURAL | | | | | |
| | | STRUCTURAL | | STRUCTURAL | | STRUCTURAL | | UNIT (mol %) | | | | PHYSICAL | |
| | HIGH | UNIT (I) | | UNIT (IV) | | UNIT (V) | | STRUC- | STRUC- | STRUC- | | PROPERTY | |
| | FLUORINE- | | BLEND- | | BLEND- | | BLEND- | TURAL | TURAL | TURAL | | VALUE | |
| | CONTENT | | ING | | ING | | ING | UNIT | UNIT | UNIT | YIELD | | Mw/ |
| | POLYMER | TYPE | RATIO | TYPE | RATIO | TYPE | RATIO | (I) | (IV) | (V) | (%) | Mw | Mn |
| SYNTHE- | E-1 | — | — | M-25 | 90 | M-24 | 10 | — | 91 | 9 | 87 | 5332 | 1.71 |
| SIS | | | | | | | | | | | | | |
| EXAM- | | | | | | | | | | | | | |
| PLE 22 | | | | | | | | | | | | | |
| SYNTHE- | E-2 | M-1 | 30 | M-25 | 70 | — | — | 28 | 72 | — | 79 | 4900 | 1.59 |
| SIS | | | | | | | | | | | | | |
| EXAM- | | | | | | | | | | | | | |
| PLE 23 | | | | | | | | | | | | | |

### <Preparation of Radiation-Sensitive Composition>

The radiation-sensitive acid generator, the acid diffusion controlling agent, and the solvent constituting the radiation-sensitive composition are described below.

### [Radiation-Sensitive Acid Generator]

A-1 to A-17: Compounds represented by the following formulas (A-1) to (A-17)

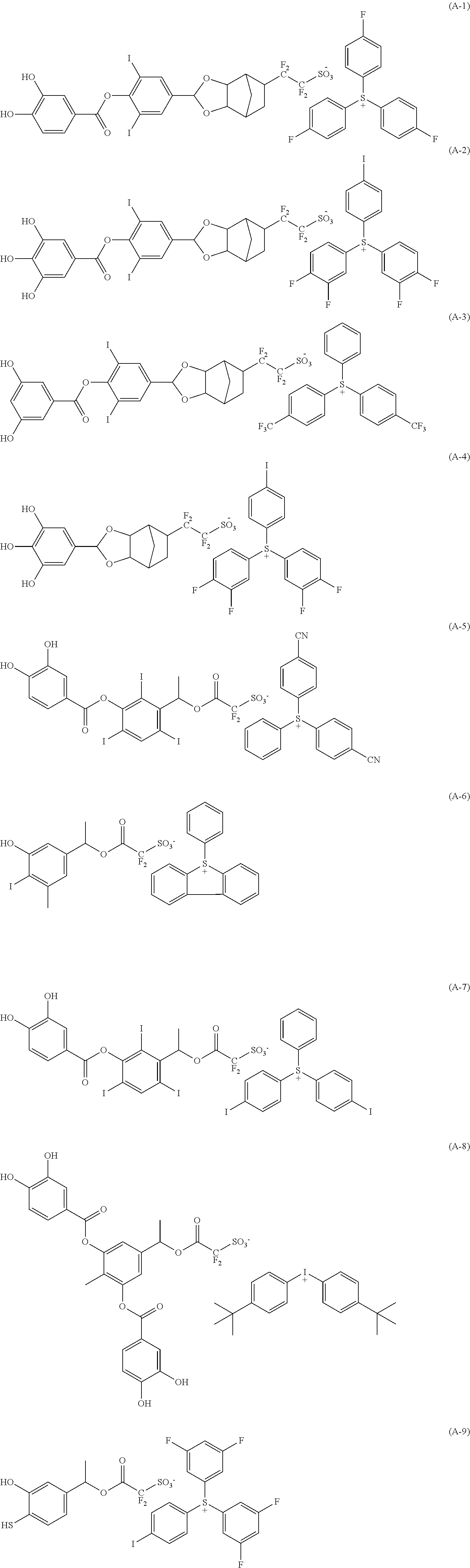

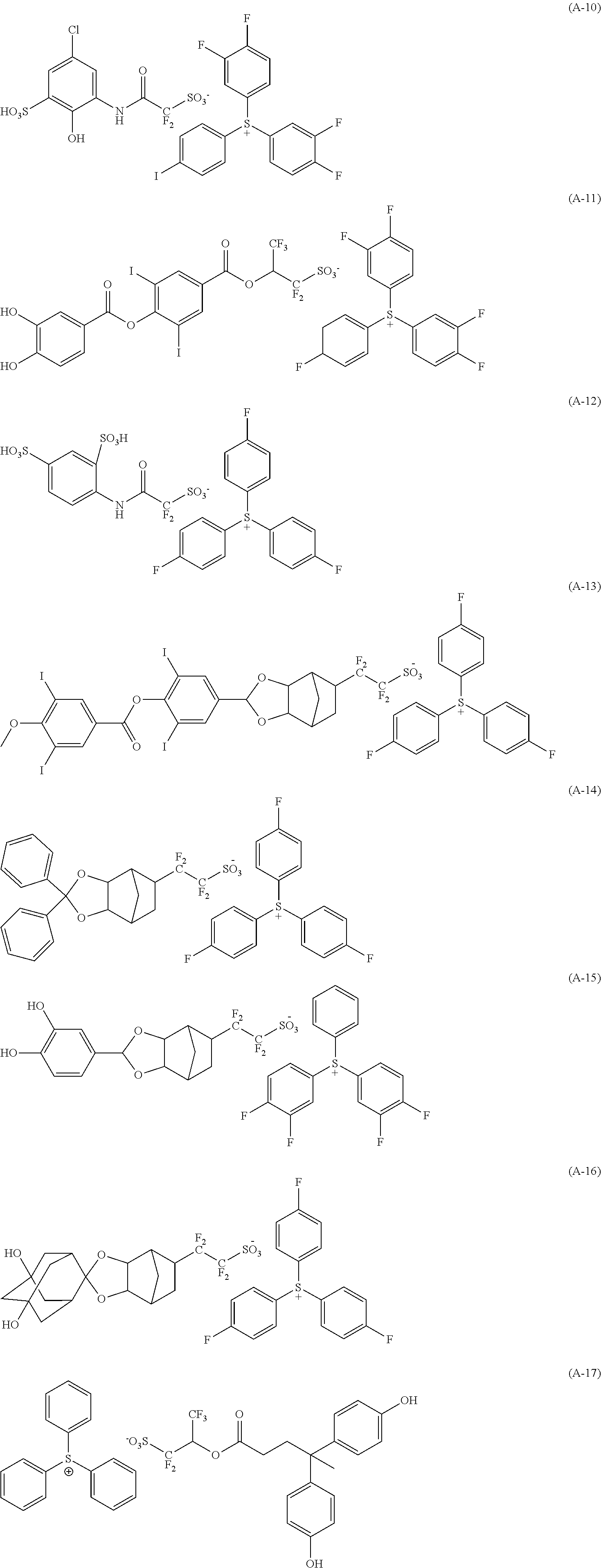

Among the radiation-sensitive acid generators represented by the above formulas, synthesis examples of the radiation-sensitive acid generators used in Examples are described below.

### <Synthesis (1) of Radiation-Sensitive Acid Generator>

### [Synthesis Example 24](Synthesis of Radiation-Sensitive Acid Generator (A-1))

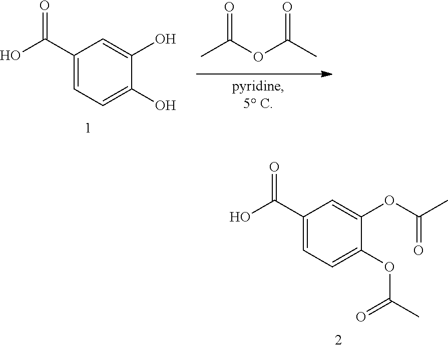

Compound 1 (5.00 g, 1.0 eq.) was dissolved in 15 mL of pyridine, and then the solution was cooled to 5° C. Thereafter, acetic anhydride (7.10 g, 2.145 eq.) was added dropwise, and the mixture was stirred at 5° C. for 2 hours. After completion of the reaction, 200 mL of water was added to quench the reaction mixture. Extraction with 50 mL of dichloromethane was conducted five times, and then the organic layer was washed with 100 mL of a 2 N aqueous HCl solution. The organic layer was dried over anhydrous sodium sulfate and filtered, then concentrated and dried, affording compound 2 in a yield of 84%.

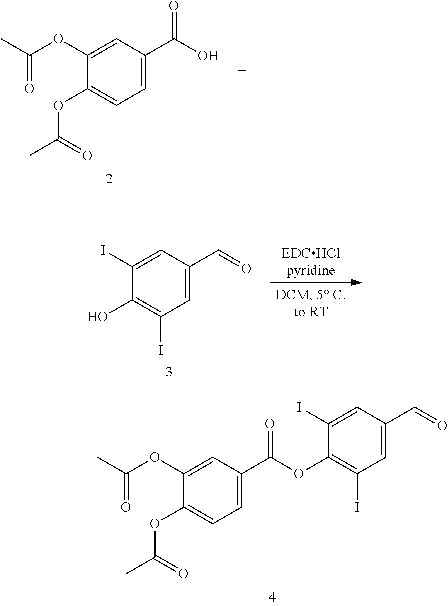 [SMILES: CC(=O)Oc1ccc(C(=O)O)cc1OC(C)=O ; O=Cc1cc(I)c(O)c(I)c1 ; CC(=O)Oc1ccc(C(=O)Oc2c(I)cc(C=O)cc2I)cc1OC(C)=O]

Compound 2 (3.50 g, 1.1 eq) was dissolved in dichloromethane (DCM) (30 mL) in a reaction vessel, and then the solution was cooled to 5° C. While the solution was kept cooled at 5° C., 1-(3-dimethylaminopropyl)-3-ethylcarbodiimide hydrochloride (EDC-HCl) (2.82 g, 1.1 eq), pyridine (2.12 g, 2.0 eq), and compound 3 (5.00 g, 1.0 eq.) were added, and then the resulting solution was stirred at room temperature (RT) for 1 hour. After completion of the reaction, methanol (30 mL) was added to the solution to precipitate a powder, and the mixture was stirred at room temperature for 30 minutes. Filtration and vacuum drying were performed, affording compound 4 in a yield of 79%. The resulting compound was used in a subsequent reaction.

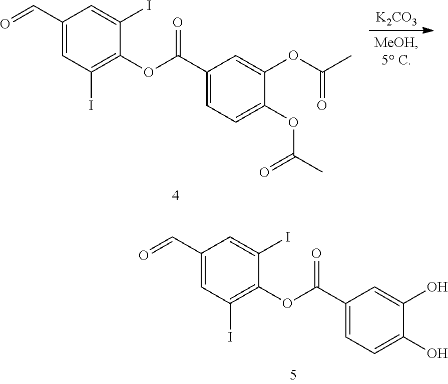 [SMILES: CC(=O)Oc1ccc(C(=O)Oc2c(I)cc(C=O)cc2I)cc1OC(C)=O ; "K2CO3" ; O=Cc1cc(I)c(OC(=O)c2ccc(O)c(O)c2)c(I)c1]

The compound 4 (5.80 g, 1.0 eq.) was added to a reaction vessel and dissolved in methanol (MeOH) (30 mL), and then the solution was cooled to 5° C. After the cooling, potassium carbonate (2.97 g, 2.2 eq.) was added in portions over 0.5 hours, and then the mixture was stirred at 5° C. for 1 hour. After completion of the reaction, the mixture was quenched with 100 mL of a saturated aqueous ammonium chloride solution. Then, ethyl acetate was added, followed by extraction, and the organic layer was separated. The organic layer was dried over anhydrous sodium sulfate, then the solvent was removed, and the residue was dried under vacuum, affording compound 5 in a yield of 98%.

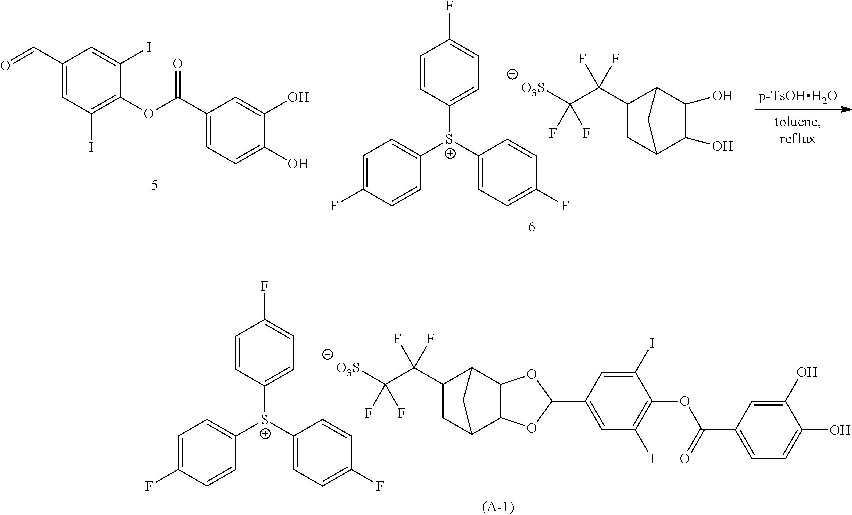

The compound 5 (4.89 g, 1.05 eq.), the compound 6 (5.70 g, 1.00 eq.), p-toluenesulfonic acid monohydrate (p-TsOH-H₂O) (0.521 g, 0.3 eq.), and 15 mL of toluene were added to a reaction vessel, and the mixture was stirred at 120° C. for 5 hours. After the cooling, 100 mL of ethyl acetate, 50 mL of acetonitrile, and 50 mL of saturated aqueous sodium bicarbonate solution were added, and then the organic layer was separated. The organic layer was dried over anhydrous sodium sulfate, then the solvent was removed, and the residue was purified by column chromatography, affording compound (A-1) in a yield of 77%.

### [Synthesis Examples 25 to 40](Synthesis of Radiation-Sensitive Acid Generator (A-2) to Radiation-Sensitive Acid Generator (A-17))

Compounds represented by the following formulas (A-2) to (A-17) were synthesized in the same manner as in Synthesis Example 24 except that the precursors and the intermediates were appropriately changed.

### [Acid Diffusion Controlling Agent]

B-1 to B-6: Compounds represented by the following formulas (B-1) to (B-6)

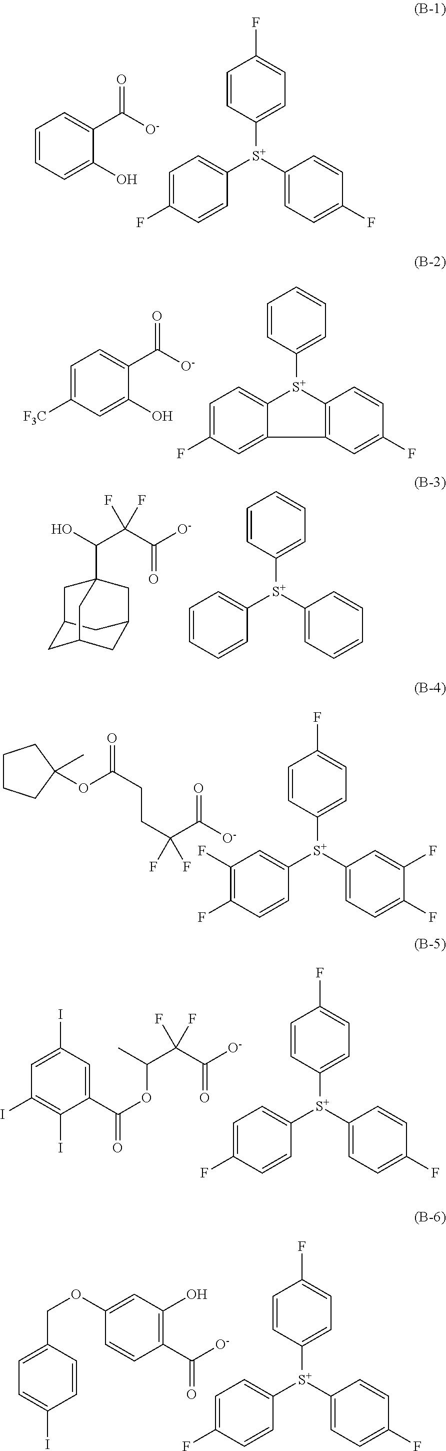

### [Solvent]F-1 to F-2: Solvents of the Following F-1 to F-2

F-1: Propylene glycol monomethyl ether acetate
F-2: Propylene glycol monomethyl ether

### [Preparation of Radiation-Sensitive Composition for Extreme Ultraviolet Ray (EUV) Exposure]

### Example 1

100 parts by mass of (P-1) as the polymer [A], 50 parts by mass of (A-1) as the radiation-sensitive acid generator, 15 parts by mass of (B-6) as the acid diffusion controlling agent, 7.0 parts by mass of (E-2) as the high fluorine-content polymer, and 4280 parts by mass of (F-1) and 1830 parts by mass of (F-2) as the solvent were mixed, and the mixture was filtered through a membrane filter having a pore size of 0.2 μm. Thus, a radiation-sensitive composition (J-1) was prepared.

### Examples 2 to 36 and Comparative Examples 1 to 3

Radiation-sensitive compositions (J-2) to (J-36) and (CJ-1) to (CJ-3) were prepared in the same manner as in Example 1 except that the components of the types and contents shown in the following Table 3 were used.

TABLE 3

| | | | | RADIATION- | | ACID | | HIGH | | | |
|---|---|---|---|---|---|---|---|---|---|---|---|
| | | | | SENSITIVE | | DIFFUSION | | FLUORINE- | | | |
| | | | | ACID | | CONTROLLING | | CONTENT | | | |
| | | BASE POLYMER | | GENERATOR | | AGENT | | POLYMER | | SOLVENT | |
| | RADIATION- | | CON- | | CON- | | CON- | | CON- | | CON- |
| | SENSITIVE | | TENT | | TENT | | TENT | | TENT | | TENT |
| | COMPOSI- | | (parts | | (parts | | (parts | | (parts | | (parts |
| | TION | TYPE | by mass) | TYPE | by mass) | TYPE | by mass) | TYPE | by mass) | TYPE | by mass) |
| EXAMPLE 1 | J-1 | P-1 | 100 | A-1 | 50 | B-6 | 15 | E-2 | 7 | F-1/F-2 | 4,280/1,830 |
| EXAMPLE 2 | J-2 | P-1 | 100 | A-2 | 55 | B-6 | 16.5 | E-2 | 7 | F-1/F-2 | 4,280/1,830 |
| EXAMPLE 3 | J-3 | P-1 | 100 | A-3 | 50 | B-6 | 15 | E-2 | 7 | F-1/F-2 | 4,280/1,830 |
| EXAMPLE 4 | J-4 | P-1 | 100 | A-4 | 40 | B-6 | 12 | E-2 | 7 | F-1/F-2 | 4,280/1,830 |
| EXAMPLE 5 | J-5 | P-1 | 100 | A-5 | 50 | B-6 | 15 | E-2 | 7 | F-1/F-2 | 4,280/1,830 |
| EXAMPLE 6 | J-6 | P-1 | 100 | A-6 | 35 | B-6 | 10.5 | E-2 | 7 | F-1/F-2 | 4,280/1,830 |
| EXAMPLE 7 | J-7 | P-1 | 100 | A-7 | 60 | B-6 | 18 | E-2 | 7 | F-1/F-2 | 4,280/1,830 |
| EXAMPLE 8 | J-8 | P-1 | 100 | A-8 | 70 | B-6 | 21 | E-2 | 7 | F-1/F-2 | 4,280/1,830 |
| EXAMPLE 9 | J-9 | P-1 | 100 | A-9 | 30 | B-6 | 9 | E-2 | 7 | F-1/F-2 | 4,280/1,830 |
| EXAMPLE 10 | J-10 | P-1 | 100 | A-10 | 35 | B-6 | 10.5 | E-2 | 7 | F-1/F-2 | 4,280/1,830 |
| EXAMPLE 11 | J-11 | P-1 | 100 | A-11 | 45 | B-6 | 13.5 | E-2 | 7 | F-1/F-2 | 4,280/1,830 |
| EXAMPLE 12 | J-12 | P-1 | 100 | A-2/A-12 | 40/10 | B-6 | 15 | E-2 | 7 | F-1/F-2 | 4,280/1,830 |
| EXAMPLE 13 | J-13 | P-1 | 100 | A-6/A-13 | 25/25 | B-6 | 15 | E-2 | 7 | F-1/F-2 | 4,280/1,830 |
| EXAMPLE 14 | J-14 | P-1 | 100 | A-7/A-14 | 35/20 | B-6 | 16.5 | E-2 | 7 | F-1/F-2 | 4,280/1,830 |
| EXAMPLE 15 | J-15 | P-1 | 100 | A-13/A-15 | 30/30 | B-3 | 18 | E-2 | 7 | F-1/F-2 | 4,280/1,830 |
| EXAMPLE 16 | J-16 | P-2 | 100 | A-1 | 50 | B-5 | 15 | E-2 | 7 | F-1/F-2 | 4,280/1,830 |
| EXAMPLE 17 | J-17 | P-3 | 100 | A-1 | 50 | B-6 | 15 | E-2 | 7 | F-1/F-2 | 4,280/1,830 |
| EXAMPLE 18 | J-18 | P-4 | 100 | A-1 | 50 | B-1 | 15 | E-2 | 7 | F-1/F-2 | 4,280/1,830 |
| EXAMPLE 19 | J-19 | P-5 | 100 | A-1 | 50 | B-2 | 15 | E-2 | 7 | F-1/F-2 | 4,280/1,830 |
| EXAMPLE 20 | J-20 | P-6 | 100 | A-1 | 50 | B-3 | 15 | E-2 | 7 | F-1/F-2 | 4,280/1,830 |
| EXAMPLE 21 | J-21 | P-7 | 100 | A-1 | 50 | B-4 | 15 | E-2 | 7 | F-1/F-2 | 4,280/1,830 |
| EXAMPLE 22 | J-22 | P-8 | 100 | A-1 | 50 | B-2 | 15 | E-2 | 7 | F-1/F-2 | 4,280/1,830 |
| EXAMPLE 23 | J-23 | P-9 | 100 | A-1 | 50 | B-2 | 15 | E-1 | 7 | F-1/F-2 | 4,280/1,830 |
| EXAMPLE 24 | J-24 | P-10 | 100 | A-1 | 50 | B-2 | 15 | E-1 | 7 | F-1/F-2 | 4,280/1,830 |
| EXAMPLE 25 | J-25 | P-11 | 100 | A-1 | 50 | B-1 | 15 | E-1 | 7 | F-1/F-2 | 4,280/1,830 |
| EXAMPLE 26 | J-26 | P-12 | 100 | A-2 | 60 | B-5 | 18 | E-1 | 7 | F-1/F-2 | 4,280/1,830 |
| EXAMPLE 27 | J-27 | P-13 | 100 | A-2 | 60 | B-3 | 18 | E-1 | 7 | F-1/F-2 | 4,280/1,830 |
| EXAMPLE 28 | J-28 | P-14 | 100 | A-2 | 60 | B-1 | 18 | E-1 | 7 | F-1/F-2 | 4,280/1,830 |
| EXAMPLE 29 | J-29 | P-15 | 100 | A-1 | 55 | B-3 | 16.5 | E-1 | 7 | F-1/F-2 | 4,280/1,830 |
| EXAMPLE 30 | J-30 | P-16 | 100 | A-2 | 65 | B-4 | 19.5 | E-1 | 7 | F-1/F-2 | 4,280/1,830 |
| EXAMPLE 31 | J-31 | P-17 | 100 | A-1 | 55 | B-2 | 16.5 | E-1 | 7 | F-1/F-2 | 4,280/1,830 |
| EXAMPLE 32 | J-32 | P-18 | 100 | A-1 | 10 | B-6 | 20 | E-1 | 7 | F-1/F-2 | 4,280/1,830 |
| EXAMPLE 33 | J-33 | P-19 | 100 | A-1 | 10 | B-6 | 20 | E-1 | 7 | F-1/F-2 | 4,280/1,830 |
| EXAMPLE 34 | J-34 | P-1/P-20 | 80/20 | A-1 | 50 | — | — | E-1 | 7 | F-1/F-2 | 4,280/1,830 |
| EXAMPLE 35 | J-35 | P-1/P-21 | 80/20 | A-1 | 50 | — | — | E-1 | 7 | F-1/F-2 | 4,280/1,830 |
| EXAMPLE 36 | J-36 | P-18/20 | 80/20 | A-1 | 10 | — | — | E-1 | 7 | F-1/F-2 | 4,280/1,830 |
| COMPARATIVE | CJ-1 | P-1 | 100 | A-15 | 40 | B-2 | 12 | E-2 | 7 | F-1/F-2 | 4,280/1,830 |
| EXAMPLE 1 | | | | | | | | | | | |
| COMPARATIVE | CJ-2 | P-1 | 100 | A-16 | 40 | B-2 | 12 | E-2 | 7 | F-1/F-2 | 4,280/1,830 |
| EXAMPLE 2 | | | | | | | | | | | |
| COMPARATIVE | CJ-3 | P-1 | 100 | A-17 | 40 | B-2 | 12 | E-2 | 7 | F-1/F-2 | 4,280/1,830 |
| EXAMPLE 3 | | | | | | | | | | | |

### <Formation of Resist Pattern Using Radiation-Sensitive Composition for EUV Exposure>

Onto a 12-inch silicon wafer, an underlayer antireflection film forming composition (“ARC66” manufactured by Brewer Science Incorporated.) was applied with use of a spin coater (“CLEAN TRACK ACT12” manufactured by Tokyo Electron Limited.). The wafer was then heated at 205° C. for 60 seconds to form an underlayer antireflection film having an average thickness of 105 nm. The radiation-sensitive composition for EUV exposure prepared above was applied onto the underlayer antireflection film with use of the spin coater, followed by performing PB at 130° C. for 60 seconds. Thereafter, cooling was performed at 23° C. for 30 seconds to form a resist film having an average thickness of 55 nm. Next, the resist film was exposed by an EUV exposure apparatus (“NXE3300”, manufactured by ASML) with NA of 0.33 under a lighting condition of Conventional s=0.89 and with a mask of imecDEFECT32FFR02. After the exposure, PEB was performed at 120° C. for 60 seconds. Thereafter, the resist film was developed with an alkali with use of a 2.38% by mass aqueous TMAH solution as an alkaline developer, followed by washing with water and further drying to form a positive resist pattern (32 nm line-and-space pattern).

### <Evaluation>

The resist patterns formed using the radiation-sensitive compositions for EUV exposure were evaluated on sensitivity, CDU performance, and LWR performance according to the following methods. The results are shown in the following Table 4. It is to be noted that a scanning electron microscope (“CG-5000” manufactured by Hitachi High-Tech Corporation) was used for measurement of the resist pattern.

### [Sensitivity]

In formation of the resist pattern using the radiation-sensitive composition for EUV exposure, an exposure dose at which a 32 nm line-and-space pattern was formed was defined as an optimum exposure dose Eop, and this optimum exposure dose was defined as sensitivity (mJ/cm²). In a case of being 35 mJ/cm² or less, the sensitivity was evaluated as “good”, and in a case of being more than 35 mJ/cm², the sensitivity was evaluated as “poor”.

### [CDU Performance]

A resist pattern was formed by adjusting a mask size such that a 25-nm contact hole pattern would be formed by irradiation with light having the exposure dose Eop determined above. The formed resist pattern was observed from above the pattern using the scanning electron microscope. The hole diameter was measured at 16 points in a range of 500 nm to determine the average value of the measurements. In this way, the average value was measured at 500 arbitrary points in total, and 1 sigma value was determined from the distribution of the measured values, and was defined as CDU performance (nm). The smaller the value of CDU performance is, the smaller the dispersion of hole diameter in a long period is and the better the CDU performance is. When the value is 2.0 nm or less, the CDU performance can be evaluated as “good”, and when the value exceeds 2.0 nm, the CDU performance can be evaluated as “poor”.

### [LWR Performance]

A resist pattern was formed by adjusting a mask size so as to form a 32 nm line-and-space pattern by irradiation with light at the optimum exposure dose Eop determined in the evaluation of the sensitivity. The formed resist pattern was observed from above the pattern using the scanning electron microscope. The variation in the line width was measured at a total of 50 points. The 3 sigma value was obtained from the distribution of the measurement values, and defined as LWR performance (nm). The smaller the value of the LWR is, the smaller the wobble of the line is and the better the LWR is. The LWR performance was evaluated as “good” when the LWR was 2.5 nm or less, and was evaluated as “poor” when the LWR exceeded 2.5 nm.

TABLE 4

| | RADIATION- | | | |
|---|---|---|---|---|
| | SENSITIVE | SENSITIVITY | CDU | LWR |
| | COMPOSITION | (mJ/cm²) | (nm) | (nm) |
| EXAMPLE 1 | J-1 | 33.5 | 1.80 | 2.25 |
| EXAMPLE 2 | J-2 | 32.5 | 1.72 | 2.17 |
| EXAMPLE 3 | J-3 | 34.5 | 1.82 | 2.31 |
| EXAMPLE 4 | J-4 | 33.2 | 1.85 | 2.29 |
| EXAMPLE 5 | J-5 | 34.0 | 1.75 | 2.22 |
| EXAMPLE 6 | J-6 | 32.5 | 1.94 | 2.48 |
| EXAMPLE 7 | J-7 | 34.8 | 1.72 | 2.13 |
| EXAMPLE 8 | J-8 | 34.0 | 1.73 | 2.18 |
| EXAMPLE 9 | J-9 | 33.4 | 1.96 | 2.45 |
| EXAMPLE 10 | J-10 | 33.1 | 1.94 | 2.46 |
| EXAMPLE 11 | J-11 | 33.7 | 1.80 | 2.23 |
| EXAMPLE 12 | J-12 | 32.0 | 1.98 | 2.44 |
| EXAMPLE 13 | J-13 | 34.5 | 1.80 | 2.25 |
| EXAMPLE 14 | J-14 | 34.5 | 1.94 | 2.43 |
| EXAMPLE 15 | J-15 | 33.9 | 1.91 | 2.39 |
| EXAMPLE 16 | J-16 | 33.0 | 1.85 | 2.31 |
| EXAMPLE 17 | J-17 | 33.5 | 1.82 | 2.28 |
| EXAMPLE 18 | J-18 | 33.5 | 1.86 | 2.33 |
| EXAMPLE 19 | J-19 | 34.0 | 1.80 | 2.25 |
| EXAMPLE 20 | J-20 | 34.0 | 1.83 | 2.31 |
| EXAMPLE 21 | J-21 | 33.5 | 1.85 | 2.35 |
| EXAMPLE 22 | J-22 | 34.5 | 1.80 | 2.23 |
| EXAMPLE 23 | J-23 | 34.0 | 1.79 | 2.27 |
| EXAMPLE 24 | J-24 | 33.8 | 1.86 | 2.38 |
| EXAMPLE 25 | J-25 | 34.0 | 1.82 | 2.26 |
| EXAMPLE 26 | J-26 | 32.0 | 1.67 | 2.10 |
| EXAMPLE 27 | J-27 | 31.5 | 1.72 | 2.15 |
| EXAMPLE 28 | J-28 | 31.2 | 1.7 | 2.16 |
| EXAMPLE 29 | J-29 | 32.5 | 1.72 | 2.13 |
| EXAMPLE 30 | J-30 | 31.5 | 1.78 | 2.19 |
| EXAMPLE 31 | J-31 | 32.0 | 1.7 | 2.13 |
| EXAMPLE 32 | J-32 | 34.5 | 1.81 | 2.34 |
| EXAMPLE 33 | J-33 | 33.2 | 1.83 | 2.32 |
| EXAMPLE 34 | J-34 | 33.6 | 1.93 | 2.41 |
| EXAMPLE 35 | J-35 | 32.9 | 1.92 | 2.44 |
| EXAMPLE 36 | J-36 | 36.1 | 1.86 | 2.35 |
| COMPARATIVE | CJ-1 | 43.2 | 2.89 | 3.61 |
| EXAMPLE 1 | | | | |
| COMPARATIVE | CJ-2 | 40.5 | 3.00 | 3.75 |
| EXAMPLE 2 | | | | |
| COMPARATIVE | CJ-3 | 38.5 | 3.20 | 4.00 |
| EXAMPLE 3 | | | | |

As is apparent from the results in Table 4, all the radiation-sensitive compositions of Examples were good in sensitivity, CDU performance, and LWR performance.

According to the radiation-sensitive composition and the pattern formation method of the present disclosure, a resist pattern superior in CDU performance and LWR performance can be formed at high sensitivity. Therefore, the composition and method can be suitably used for a machining process and the like of a semiconductor device that is expected to be further miniaturized in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
a polymer comprising a structural unit which comprises an acid-dissociable group;
a radiation-sensitive acid generator comprising a first organic acid anion and a first onium cation;
an acid diffusion controlling agent which comprises a second organic acid anion and a second onium cation and capable of generating an acid having a pKa higher than a pKa of an acid to be generated from the radiation-sensitive acid generator by irradiation with radiation; and
a solvent,
wherein
the first organic acid anion comprises an acid anion moiety and an aromatic ring comprising a first substituent and a second substituent, and the first substituent and the second substituent are each independently a hydroxy group, a sulfo group, or a sulfanyl group, and
at least one selected from the group consisting of the polymer, the radiation-sensitive acid generator, and the acid diffusion controlling agent comprises an iodo group.

2. The radiation-sensitive composition according to claim 1, wherein at least one of the first substituent and the second substituent is a hydroxy group.

3. The radiation-sensitive composition according to claim 1, wherein the first substituent and the second substituent are each present at ortho positions of the aromatic ring.

4. The radiation-sensitive composition according to claim 1, wherein the aromatic ring is a benzene ring.

5. The radiation-sensitive composition according to claim 1, wherein at least one selected from the group consisting of the polymer, the radiation-sensitive acid generator, and the acid diffusion controlling agent comprises an iodo group-containing aromatic ring structure.

6. The radiation-sensitive composition according to claim 1, wherein at least one selected from the group consisting of the acid-dissociable group, the first organic acid anion, and the second organic acid anion comprises an iodo group-containing aromatic ring structure.

7. The radiation-sensitive composition according to claim 5, wherein a number of iodo groups in the iodo group-containing aromatic ring structure is 1, 2, or 3.

8. The radiation-sensitive composition according to claim 5, wherein an aromatic ring in the iodo group-containing aromatic ring structure is a benzene ring.

9. The radiation-sensitive composition according to claim 1,
wherein the acid anion moiety is a sulfonate anion, and
a fluorine atom or a fluorinated hydrocarbon group is bonded to a carbon atom adjacent to a sulfur atom of the sulfonate anion.

10. The radiation-sensitive composition according to claim 1, wherein the second organic acid anion comprises a sulfonate anion or a carboxylate anion, provided that when the second organic acid anion comprises the sulfonate anion, neither a fluorine atom nor a fluorinated hydrocarbon group is bonded to a carbon atom adjacent to a sulfur atom of the sulfonate anion.

11. The radiation-sensitive composition according to claim 1, wherein the first organic acid anion and the second organic acid anion each independently comprise —O—, —CO—, a cyclic structure, or a combination thereof.

12. The radiation-sensitive composition according to claim 1, wherein the first onium cation and the second onium cation each independently comprise at least one selected from the group consisting of a fluoro group and an iodo group.

13. The radiation-sensitive composition according to claim 1, wherein the first onium cation and the second onium cation are each a sulfonium cation.

14. The radiation-sensitive composition according to claim 1, wherein the polymer further comprises a structural unit comprising a phenolic hydroxy group.

15. A pattern formation method comprising:
applying the radiation-sensitive composition according to claim 1 directly or indirectly to a substrate to form a resist film;
exposing the resist film to light; and
developing the exposed resist film with a developer.

16. The pattern formation method according to claim 15, wherein exposing comprises exposing the resist film to an extreme ultraviolet ray or an electron beam.

17. The radiation-sensitive composition according to claim 1, wherein the acid-dissociable group comprises an iodo group-containing aromatic ring structure.

18. The radiation-sensitive composition according to claim 1, wherein the structural unit which comprises the acid-dissociable group is a structural unit represented by formula (3-4), 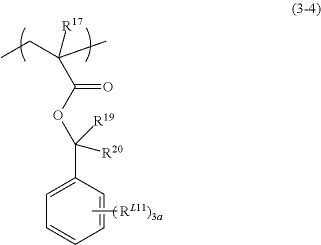
wherein,
R¹⁷ is a hydrogen atom, a fluorine atom, a methyl group, or a trifluoromethyl group,
R¹⁹ and R²⁰ are each independently a substituted or unsubstituted monovalent chain hydrocarbon group having 1 to 10 carbon atoms or a substituted or unsubstituted monovalent alicyclic hydrocarbon group having 3 to 20 carbon atoms, or R¹⁹ and R²⁰ taken together represent a divalent alicyclic group having 3 to 20 carbon atoms together with the carbon atom to which R¹⁹ and R²⁰ are bonded,
3a is an integer of 1 to 3, when 3a is 2 or more, the plurality of R^{L11}s are the same or different from each other, and
R^{L11} is a halogen atom, a carboxy group, a cyano group, a nitro group, an alkyl group, a fluorinated alkyl group, an alkoxycarbonyloxy group, an acyl group, an acyloxy group, or an alkoxy group, provided that at least one R^{L11} is an iodine atom.

19. The radiation-sensitive composition according to claim 1, wherein the radiation-sensitive acid generator is represented by formula (G-1), 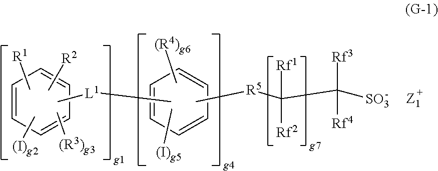
wherein,
L¹ is a single bond, an ether linkage, an ester linkage, or an alkylene group having 1 to 6 carbon atoms optionally comprising an ether linkage or an ester linkage,
R¹ and R² are each independently a hydroxy group, a sulfo group, or a sulfanyl group,
R³ and R⁴ are each independently a hydroxy group, a carboxy group, a fluorine atom, a chlorine atom, a bromine atom, an amino group, an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, an alkylsulfonyloxy group having 1 to 20 carbon atoms, —NR⁸—C(═O)—R⁹ or —NR⁸—C(═O)—O—R⁹, wherein the alkyl group, the alkcoxy group, the alkoxycarbonyl group, the acyloxy group, and the alkylsulfonyloxy group optionally each independently comprises a fluorine atom, a chlorine atom, a bromine atom, a hydroxy group, an amino group, or an alkoxy group having 1 to 10 carbon atoms, and wherein R⁸ is a hydrogen atom or an alkyl group having 1 to 6 carbon atoms, optionally comprising a halogen atom, a hydroxy group, an alkoxy group having 1 to 6 carbon atoms, an acyl group having 2 to 6 carbon atoms, or an acyloxy group having 2 to 6 carbon atoms, and R⁹ is an alkyl group having 1 to 16 carbon atoms, an alkenyl group having 2 to 16 carbon atoms, or an aryl group having 6 to 12 carbon atoms provided that the alkyl group, the alkenyl group, and the aryl group optionally comprises a halogen atom, a hydroxy group, an alkoxy group having 1 to 6 carbon atoms, an acyl group having 2 to 6 carbon atoms, or an acyloxy group having 2 to 6 carbon atoms,
R⁵ is a single bond or a divalent linking group having 1 to 20 carbon atoms when g₄ is 1, and is a (g₁+1)-valent linking group having 1 to 20 carbon atoms when g₄ is 0,
Rf¹ to Rf⁴ are each independently a hydrogen atom, a fluorine atom, or a trifluoromethyl group, and at least one of
Rf¹ to Rf⁴ is a fluorine atom or a trifluoromethyl group, provided that Rf¹ and Rf² are optionally combined to form a carbonyl group,
g₁ is an integer of 1 to 3, g₂ and g₃ are each independently an integer of 0 to 2, g₄ is 0 or 1, g₅ is an integer of 0 to 3, g₆ is an integer of 0 to 2, g₇ is 0 or 1, provided that g₂+g₅ is an integer of 1 to 5.

20. The radiation-sensitive composition according to claim 19, wherein, in the formula (G-1), g₄ is 1.

21. The radiation-sensitive composition according to claim 19, wherein, in the formula (G-1), g₄ is 1, g₂ is 0, and g₅ is an integer of 1 to 3.

22. A radiation-sensitive acid generator represented by formula (G-1), 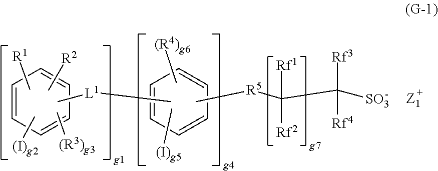
wherein,
L¹ is a single bond, an ether linkage, an ester linkage, or an alkylene group having 1 to 6 carbon atoms optionally comprising an ether linkage or an ester linkage,
R¹ and R² are each independently a hydroxy group, a sulfo group, or a sulfanyl group,
R³ and R⁴ are each independently a hydroxy group, a carboxy group, a fluorine atom, a chlorine atom, a bromine atom, an amino group, an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, an alkylsulfonyloxy group having 1 to 20 carbon atoms, —NR⁸—C(═O)—R⁹ or —NR⁸—C(═O)—O—R⁹, wherein the alkyl group, the alkcoxy group, the alkoxycarbonyl group, the acyloxy group, and the alkylsulfonyloxy group optionally each independently comprises a fluorine atom, a chlorine atom, a bromine atom, a hydroxy group, an amino group, or an alkoxy group having 1 to 10 carbon atoms, and wherein R⁸ is a hydrogen atom or an alkyl group having 1 to 6 carbon atoms, optionally comprising a halogen atom, a hydroxy group, an alkoxy group having 1 to 6 carbon atoms, an acyl group having 2 to 6 carbon atoms, or an acyloxy group having 2 to 6 carbon atoms, and R⁹ is an alkyl group having 1 to 16 carbon atoms, an alkenyl group having 2 to 16 carbon atoms, or an aryl group having 6 to 12 carbon atoms provided that the alkyl group, the alkenyl group, and the aryl group optionally comprises a halogen atom, a hydroxy group, an alkoxy group having 1 to 6 carbon atoms, an acyl group having 2 to 6 carbon atoms, or an acyloxy group having 2 to 6 carbon atoms,
R⁵ is a single bond or a divalent linking group having 1 to 20 carbon atoms when g₄ is 1, and is a (g₁+1)-valent linking group having 1 to 20 carbon atoms when g₄ is 0,
Rf¹ to Rf⁴ are each independently a hydrogen atom, a fluorine atom, or a trifluoromethyl group, and at least one of
Rf¹ to Rf⁴ is a fluorine atom or a trifluoromethyl group, provided that Rf¹ and Rf² are optionally combined to form a carbonyl group,
g₁ is an integer of 1 to 3, g₂ and g₃ are each independently an integer of 0 to 2, g₄ is 0 or 1, g₅ is an integer of 0 to 3, g₆ is an integer of 0 to 2, g₇ is 0 or 1, provided that g₂+g₅ is an integer of 1 to 5.
